(19) United States
(12) Patent Application Publication
(10) Pub. No.: US 2026/0096122 A1
(43) Pub. Date: Apr. 2, 2026

(54) SEMICONDUCTOR STRUCTURE INCLUDING SOURCE/DRAIN PORTIONS WITH REDUCED CRYSTAL DEFECTS AND METHODS FOR MANUFACTURING THE SAME

(71) Applicant: TAIWAN SEMICONDUCTOR MANUFACTURING COMPANY, LTD., Hsinchu (TW)

(72) Inventors: Sean MA, Hsinchu (TW); Chung-I YANG, Hsinchu (TW); Chih-Ching WANG, Hsinchu (TW); Zhiqiang WU, Hsinchu (TW); Kuo-Cheng CHIANG, Hsinchu (TW)

(73) Assignee: TAIWAN SEMICONDUCTOR MANUFACTURING COMPANY, LTD., Hsinchu (TW)

(21) Appl. No.: 18/903,913

(22) Filed: Oct. 1, 2024

(51) Int. Cl. H01L 29/66; H01L 29/06; H01L 29/08; H01L 29/423; H01L 29/49; H01L 29/775; H01L 29/786

(52) U.S. Cl. CPC H10D 30/014; H10D 30/43; H10D 30/6735; H10D 30/6757; H10D 62/121; H10D 62/151; H10D 64/017; H10D 64/018; H10D 64/679

(57) ABSTRACT

A method for manufacturing a semiconductor structure includes: forming a patterned structure which includes a stacking portion that includes a first layer and a second layer disposed on the first layer, the first layer including an inner part and two outer parts respectively located at two opposite sides of the inner part, the two outer parts being made of a first semiconductor material, the second layer being made of a second semiconductor material that is different from the first semiconductor material, the inner part being made of a material that is different from the first semiconductor material and the second semiconductor material, and a dummy structure disposed on the stacking portion; and epitaxially forming two source/drain portions respectively at two opposite sides of the stacking portion so that each of the two source/drain portions is connected to the second layer and a respective one of the two outer parts.

### BACKGROUND

At present, integrated circuits (ICs) are widely used in consumer electronics products (such as mobile phones), high performance computing applications, and automotive electronics products. With the advancement of IC manufacturing technologies, electronics products are designed to have relatively small and complex circuits. Transistors are key active components in modern ICs. There is a trade-off between low power consumption and high performance (e.g., high computing speed) in the transistors. In order for the electronics products to have both low power consumption and high performance, various approaches are being continuously developed for optimizing the transistors in the ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 15 and 33 are each a flow diagram illustrating a method for manufacturing a semiconductor structure in accordance with some embodiments.

FIGS. 2A to 14B, 16A to 32, and 34A to 42 illustrate schematic views of intermediate stages of the methods depicted in FIGS. 1, 15 and 33 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the terms “about” and “substantially” even if the terms “about” and “substantially” are not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the terms “about” and “substantially,” when used with a value, can capture variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The term “source/drain portion(s)” may refer to a source or a drain, individually or collectively dependent upon the context.

A gate-all-around (GAA) device is one of three-dimensional transistor structures in advanced technology nodes of semiconductor fabrication. The GAA device includes multiple semiconductor channels spaced apart from each other, two source/drain portions disposed respectively at two opposite sides of each of the semiconductor channels, and a control gate wrapping around each of the semiconductor channels so that the current flowing in each of the semiconductor channels can be well controlled by the control gate, thereby reducing short channel effects in the GAA device. In common practice, the control gate is separated from the two source/drain portions by inner spacers which are made of a dielectric material. Furthermore, the two source/drain portions are formed after formation of the inner spacers. In such case, each of the two source/drain portions is formed on a discontinuous semiconductor surface which is provided by the semiconductor channels and corresponding ones of the inner spacers disposed to alternate with the semiconductor channels. The source/drain portions thus obtained are usually formed with crystal defects (such as stacking faults, dislocations, etc.), thereby adversely affecting the electrical performance of the GAA device. Therefore, the present disclosure is directed to methods for manufacturing a semiconductor structure which includes source/drain portions with reduced crystal defects, and the semiconductor structure obtained by the same.

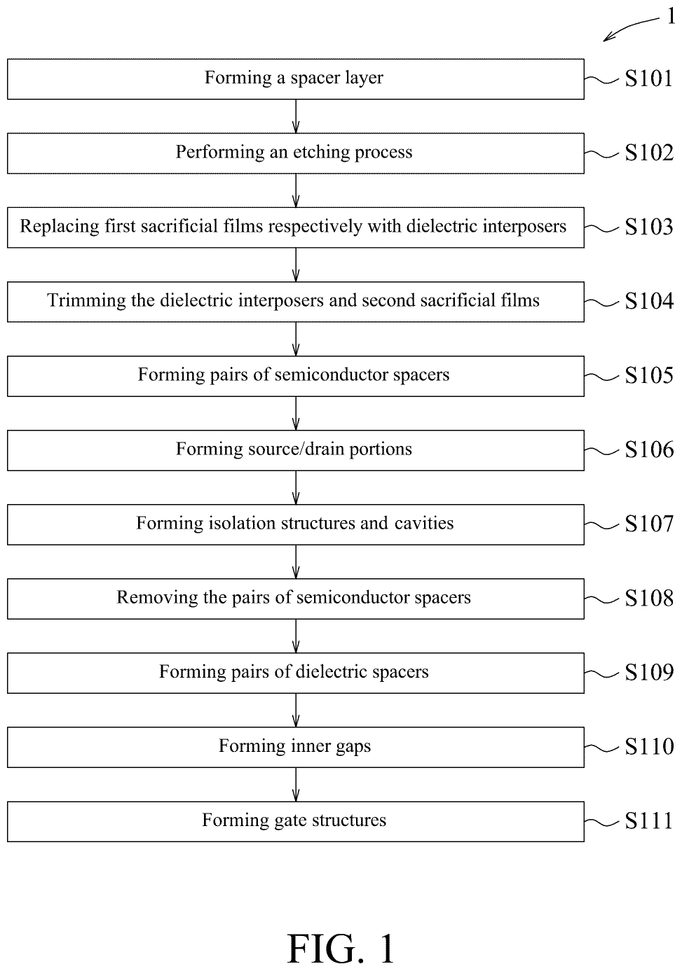

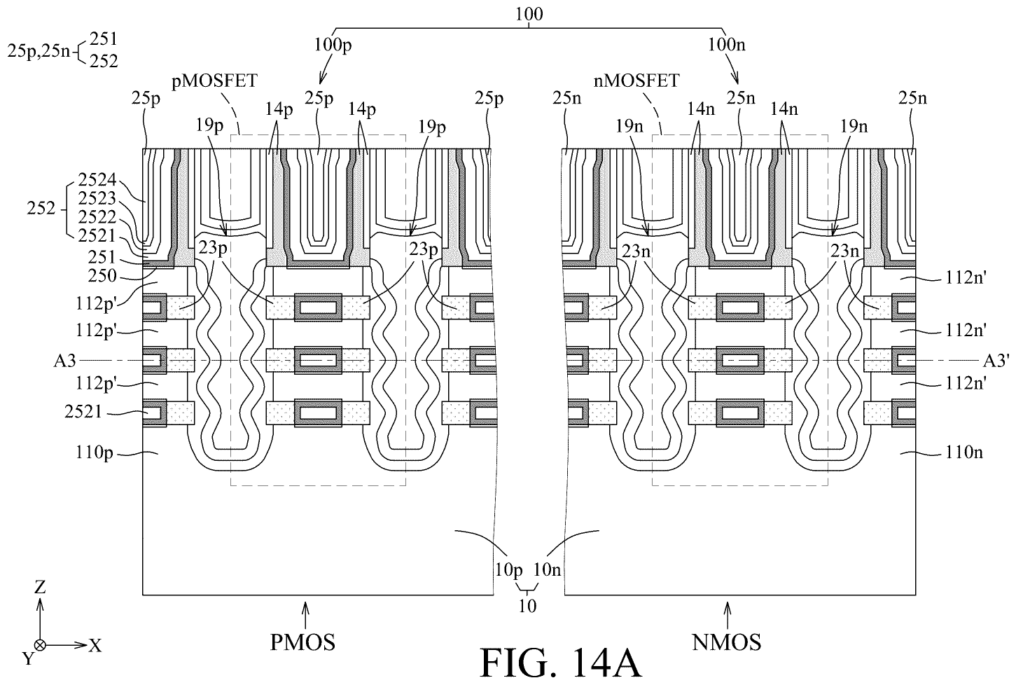

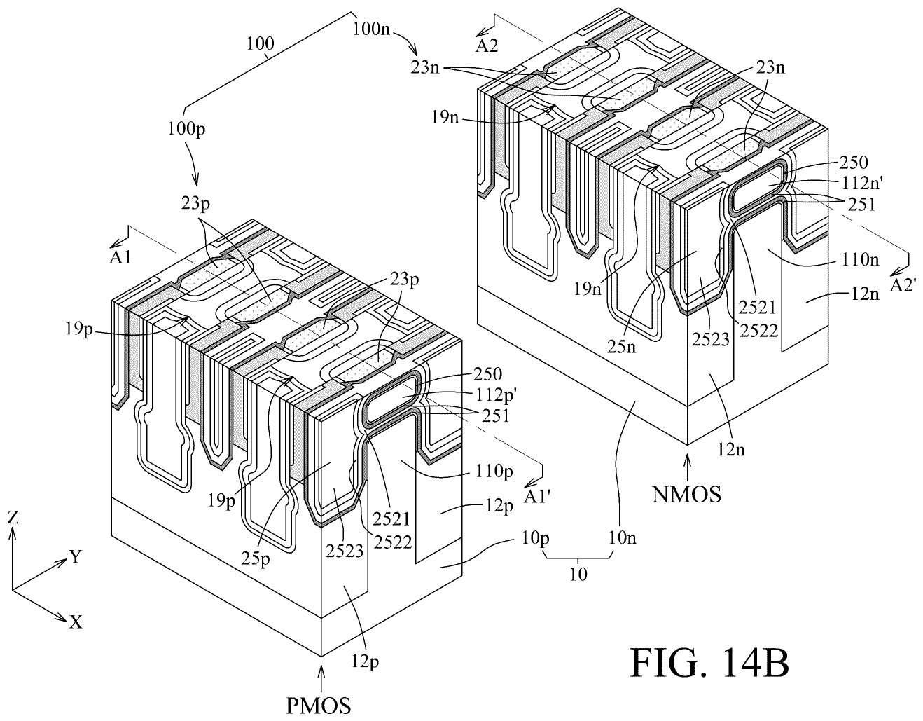

FIG. 1 is a flow diagram illustrating a method 1 for manufacturing a semiconductor structure (for example, but not limited to, a semiconductor structure 100 shown in FIGS. 14A and 14B) in accordance with some embodiments. The semiconductor structure 100 includes a device structure 100p located in a PMOS region, and a device structure 100n located in an NMOS region. It is noted that the device structures 100p, 100n are formed on the same substrate. The structures between the device structures 100p, 100n are omitted for the sake of brevity, and thus the device structures 100p, 100n are shown as being separated in the figure. Each of the device structures 100p, 100n is configured as a gate-all-around structure, and includes multiple gate-all-around field-effect transistors (GAAFETs). The GAAFETs in the device structure 100p are p-channel metal-oxide-semiconductor field-effect transistors (pMOSFETs, one of which is fully shown in FIG. 14A), and the GAAFETs in the device structure 100n are n-channel metal-oxide-semiconductor field-effect transistors (nMOSFETs, one of which is fully shown in FIG. 14A). In some embodiments not shown herein, the semiconductor structure 100 may be configured as a complementary field-effect transistor (CFET) structure which includes a lower GAAFET and an upper GAAFET sequentially formed over a substrate, a fork-sheet structure which includes two GAAFETs which are formed on different fins and which are spaced apart from each other through a wall portion that is formed on an trench isolation, or other suitable three-dimensional structures. The semiconductor structure 100 may function as memory devices, logic devices, power devices, or other suitable devices.

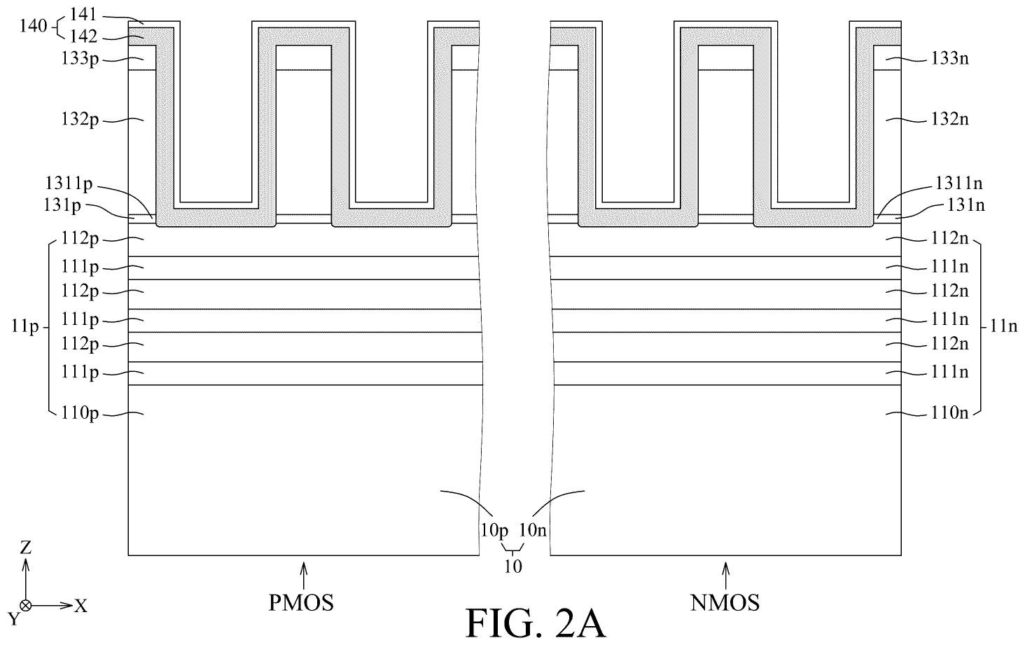

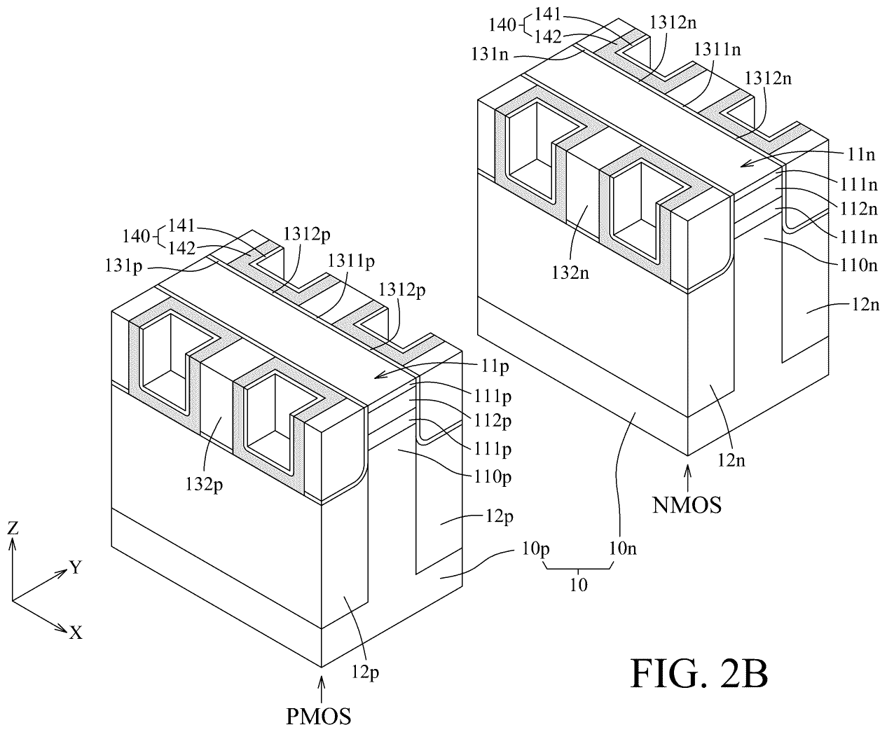

The method 1 may include steps S101 to S111. FIGS. 2A to 14B illustrate schematic views of intermediate stages of the method 1 in accordance with some embodiments. FIG. 14A is a schematic sectional view illustrating the device structures 100p, 100n in accordance with some embodiments. FIG. 14B is a fragmentary perspective view illustrating portions of the device structures 100p, 100n in accordance with some embodiments. The schematic sectional views of the device structures 100p, 100n shown in FIG. 14A are respectively taken along lines A1-A1′ and A2-A2′ of FIG. 14B, and further illustrate the components that are omitted in FIG. 14B. In other words, the fragmentary perspective view shown in FIG. 14B merely illustrates the components of the device structures 100p, 100n positioned below dotted line A3-A3′ of FIG. 14A, but omitting the components of the device structures 100p, 100n positioned above dotted line A3-A3′ of FIG. 14A.

FIGS. 2A, 3A, 4A, 5A, 6A, 7A, 8A, 9A, 10A, 11A, 12A and 13A are each a schematic sectional view similar to that of FIG. 14A, and FIGS. 2B, 3B, 4B, 4B, 5B, 6B, 7B, 8B, 9B, 10B, 11B, 12B, and 13B are each a schematic perspective view similar to that of FIG. 14B, but illustrating formation of the device structures 100p, 100n at different intermediate stages of the method 1.

Referring to FIG. 1 and the examples illustrated in FIGS. 2A and 2B, the method 1 begins at step S101, where a spacer layer 140 is formed on an intermediate structure. The intermediate structure includes a substrate 10, a fin structure 11p, a fin structure 11n, two trench isolations 12p, two trench isolations 12n, dummy gates 132p, and dummy gates 132n.

The substrate 10 includes a first substrate region 10p and a second substrate region 10n respectively located in the PMOS region and the NMOS region.

In some embodiments, the substrate 10 may include elemental semiconductor materials (such as crystalline silicon, diamond, or germanium), compound semiconductor materials (such as silicon carbide, gallium arsenide, indium arsenide, or indium phosphide), alloy semiconductor materials (such as silicon germanium, silicon germanium carbide, gallium arsenide phosphide, or gallium indium phosphide), or combinations thereof. In some embodiments, the substrate 10 may be a bulk semiconductor substrate, for example, but not limited to, a bulk substrate of silicon, germanium, silicon germanium, or other suitable semiconductor materials (such as the examples described earlier in the same paragraph). In some embodiments, the first substrate region 10p may be formed with an n-type well having an n-type conductivity, and the second substrate region 10n may be formed with a p-type well having a p-type conductivity. Each of the n-type well and the p-type well may be formed by introducing an n-type impurity or a p-type impurity into the substrate 10 by an implantation process. In some embodiments, the n-type impurity may include phosphorous (P, ³¹P), arsenic (As), antimony (Sb), or combinations thereof. In some embodiments, the p-type impurities may include boron or boron compound (for example, B, ¹¹B, BF₂), aluminum (Al), indium (In), gallium (Ga), or combinations thereof. In some other embodiments not shown herein, the substrate 10 may be configured as a semiconductor-on-insulator substrate. Other suitable materials and configurations for the substrate 10 are within the contemplated scope of the present disclosure.

The fin structure 11p and the fin structure 11n are respectively formed on the first substrate region 10p and the second substrate region 10n, and are each elongated in an X direction. The trench isolations 12p are formed on the first substrate region 10p at two opposite sides of the fin structure 11p in a Y direction transverse to the X direction. The trench isolations 12n are formed on the second substrate region 10n at two opposite sides of the fin structure 11n in the Y direction.

The fin structure 11p includes a fin 110p disposed on the first substrate region 10p, sacrificial layers 111p disposed on the fin 110p opposite to the first substrate region 10p, and channel layers 112p disposed to alternate with the sacrificial layers 111p in a Z direction transverse the X and Y directions. In some embodiments, the X, Y and Z directions are perpendicular to each other. In some embodiments, an uppermost one of the channel layers 112p is disposed over an uppermost one of the sacrificial layers 111p opposite to the fin 110p. In some embodiments, a lowermost one of the channel layers 112p is spaced apart from the fin 110p by a lowermost one of the sacrificial layers 111p.

The fin structure 11n includes a fin 110n disposed on the second substrate region 10n, sacrificial layers 111n disposed on the fin 110n opposite to the second substrate region 10n, and channel layers 112n disposed to alternate with the sacrificial layers 111n in the Z direction. In some embodiments, an uppermost one of the channel layers 112n is disposed over an uppermost one of the sacrificial layers 111n opposite to the fin 110n. In some embodiments, a lowermost one of the channel layers 112n is spaced apart from the fin 110n by a lowermost one of the sacrificial layers 111n.

In some embodiments, the fin 110p may be implanted with an n-type impurity to serve as an n-type well, and the fin 110n may be implanted with a p-type impurity to serve as a p-type well. The examples of the p-type impurity and the n-type impurity are similar to those as described in the previous paragraph.

Each of the sacrificial layers 111p, 111n is made of a semiconductor material that is different from a semiconductor material of each of the channel layers 112p, 112n, so that in subsequent step(s), the sacrificial layers 111p, 111n are able to be selectively removed while the channel layers 112p, 112n are substantially intact due to different etching selectivity ratios. Possible semiconductor materials suitable for forming the sacrificial layers 111p, 111n and the channel layers 112p, 112n are similar to those for forming the substrate 10, and thus the details thereof are omitted for the sake of brevity. some embodiments, the sacrificial layers 111p, 111n are made of silicon germanium. In some embodiments, the channel layers 112p, 112n are made of silicon. Other materials suitable for the sacrificial layers 111p, 111n and the channel layers 112p, 112n are within the contemplated scope of the present disclosure. In some embodiments, each of the sacrificial layers 111p, 111n has a thickness ranging from about 4 nm to about 14 nm. In some embodiments, each of the channel layers 112p, 112n has a thickness ranging from about 3 nm to about 9 nm.

In some embodiments, formation of the fin structures 11p, 11n may include (i) forming a lamination structure (not shown) on a starting substrate (not shown) by chemical vapor deposition (CVD), atomic layer deposition (ALD), an epitaxial growth process (such as molecular-beam epitaxy (MBE), selective area epitaxy (SAE), etc.), or other suitable deposition techniques, and (ii) patterning the lamination structure and the starting substrate using a photolithography process followed by an etching process. As a result, the lamination structure is patterned into the sacrificial layers 111p, 111n and the channel layers 112p, 112n each having a predetermined dimension in the Y direction, and the starting substrate is patterned into the fins 110p, 110n and the substrate regions 10p, 10n.

In some embodiments, the trench isolations 12p, 12n may each be a shallow trench isolation (STI), a deep trench isolation (DTI), or other suitable structures. In some embodiments, the trench isolations 12p, 12n may include silicon oxide, silicon nitride, silicon oxynitride, other low-k dielectric materials, or combinations thereof. Other insulating materials suitable for the trench isolations 12p, 12n are within the contemplated scope of the present disclosure.

In some embodiments, formation of the trench isolations 12p, 12n may include (i) forming an isolation layer over the substrate regions 10p, 10n and the fin structures 11p, 11n followed by a planarization process (for example, but not limited to, chemical mechanism polishing (CMP)) to expose the fin structures 11p, 11n, thereby obtaining two pairs of isolation regions (not shown), each pair of which are respectively located at the two opposite sides of a respective one of the fin structures 11p, 11n in the Y direction, and (ii) recessing the two pairs of isolation regions to expose the sacrificial layers 111p, 111n and the channel layers 112p, 112n and an upper portion of each of the fins 110p, 110n, such that the two pairs of isolation regions are respectively formed into the trench isolations 12p and the trench isolations 12n.

The dummy gates 132p are each formed over the fin structure 11p and the trench isolations 12p. The dummy gates 132p are each elongated in the Y direction and are spaced apart from each other in the X direction. The dummy gates 132n are each formed over the fin structure 11n and the trench isolations 12n. The dummy gates 132n are each elongated in the Y direction and are spaced apart from each other in the X direction. In some embodiments, each of the dummy gates 132p, 132n may include polycrystalline silicon, single crystalline silicon, amorphous silicon, or combinations thereof. In some embodiments, each of the dummy gates 132p, 132n has a planar upper surface opposite to the substrate 10.

In some embodiments, the intermediate structure further includes a dummy dielectric layer 131p and a dummy dielectric layer 131n which are respectively formed on the fin structure 11p and the fin structure 11n.

The dummy dielectric layer 131p includes first portions 1311p which are respectively located beneath the dummy gates 132p, and second portions 1312p which are not covered by the dummy gates 132p and which are disposed to alternate with the first portions 1311p in the X direction. In some embodiments, each of the first portions 1311p is disposed to cover two lateral surfaces of the fin structure 11p which are opposite to each other in the Y direction and to cover an upper surface of the fin structure 11p, while each of the second portions 1312p is disposed to cover the two lateral surfaces of the fin structure 11p, without covering the upper surface of the fin structure 11p (in other words, the second portions 1312p cannot be observed in FIG. 2A).

The dummy dielectric layer 131n includes first portions 1311n which are respectively located beneath the dummy gates 132n, and second portions 1312n which are not covered by the dummy gates 132n and which are disposed to alternate with the first portions 1311n in the X direction. In some embodiments, each of the first portions 1311n is disposed to cover two lateral surfaces of the fin structure 11n which are opposite to each other in the Y direction and to cover an upper surface of the fin structure 11n, while each of the second portions 1312n is disposed to cover the two lateral surfaces of the fin structure 11n, without covering the upper surface of the fin structure 11n (in other words, the second portions 1312n cannot be observed in FIG. 2A).

In some embodiments, each of the dummy dielectric layers 131p, 131n, may include silicon oxide, silicon nitride, silicon oxynitride, other suitable dielectric materials, or combinations thereof.

In some embodiments, formation of the dummy dielectric layers 131p, 131n and the dummy gates 132p, 132n may include (i) sequentially forming a first dummy layer (not shown) for forming the dummy dielectric layers 131p, 131n and a second dummy layer (not shown) for forming the dummy gates 132p, 132n over the fin structures 11p, 11n and the trench isolations 12p, 12n by CVD, ALD, physical vapor deposition (PVD), or other suitable deposition techniques, (ii) performing a planarization process (e.g., chemical mechanical polishing) to obtain a planar upper surface of the second dummy layer, (iii) forming cap portions 133p, 133n on the planarized second dummy layer using a photolithography process followed by an etching process, (iv) patterning the planarized second dummy layer into the dummy gates 132p, 132n by an anisotropic etching process using the cap portions 133p, 133n as a hard mask, thereby exposing portions of the first dummy layer, and (v) trimming the exposed portions of the first dummy layer by an anisotropic etching process to expose the upper surface of each of the fin structures 11p, 11n and the trench isolations 12p, 12n, while leaving the material of the first dummy layer on the lateral surfaces of the fin structures 11p, 11n, so that the exposed portions of the first dummy layer is formed into the second portions 1312p, 1312n of the dummy dielectric layers 131p, 131n, and portions of the first dummy layer which are respectively covered by the dummy gates 132p, 132n serve as the first portions 1311p, 1311n of the dummy dielectric layers 131p, 131n.

In some embodiments, each of the cap portions 133p, 133n may include silicon nitride, silicon oxide, silicon oxynitride, other suitable dielectric materials, or combinations thereof.

The spacer layer 140 is formed to cover the fin structures 11p, 11n, the trench isolations 12p, 12n, the dummy dielectric layers 131p, 131n, the dummy gates 132p, 132n, and the cap portions 133p, 133n of the intermediate structure. The spacer layer 140 may be configured as a single layer structure or a multi-layered structure. In some embodiments, as shown in FIGS. 2A and 2B, the spacer layer 140 is formed as a bi-layer structure, and includes an outer sub-layer 141 and an inner sub-layer 142 which is disposed between the outer sub-layer 141 and the intermediate structure.

The outer and inner sub-layers 141, 142 are made of different dielectric materials. In some embodiments, possible dielectric materials suitable for the outer and inner sub-layers 141, 142 may include, for example, but not limited to, silicon oxide, silicon nitride, carbon-doped silicon oxide (which may be referred to as silicon oxycarbide), nitride-doped silicon oxide (which may be referred to as silicon oxynitride), silicon oxycarbon nitride, silicon carbon nitride, other suitable low dielectric constant (low-k) materials, or combinations thereof. The outer sub-layer 141 has a dielectric constant value (k value) that is greater than a k value of the inner sub-layer 142. The k value of each of the outer and inner sub-layers 141, 142 may be adjusted by varying the proportions of silicon, oxygen, carbon, nitrogen, and/or other elements (such as hydrogen) in the dielectric material thereof.

In some embodiments, formation of the spacer layer 140 includes conformally depositing material(s) of the spacer layer 140 to cover the intermediate structure by CVD, ALD, PVD, or other suitable deposition techniques.

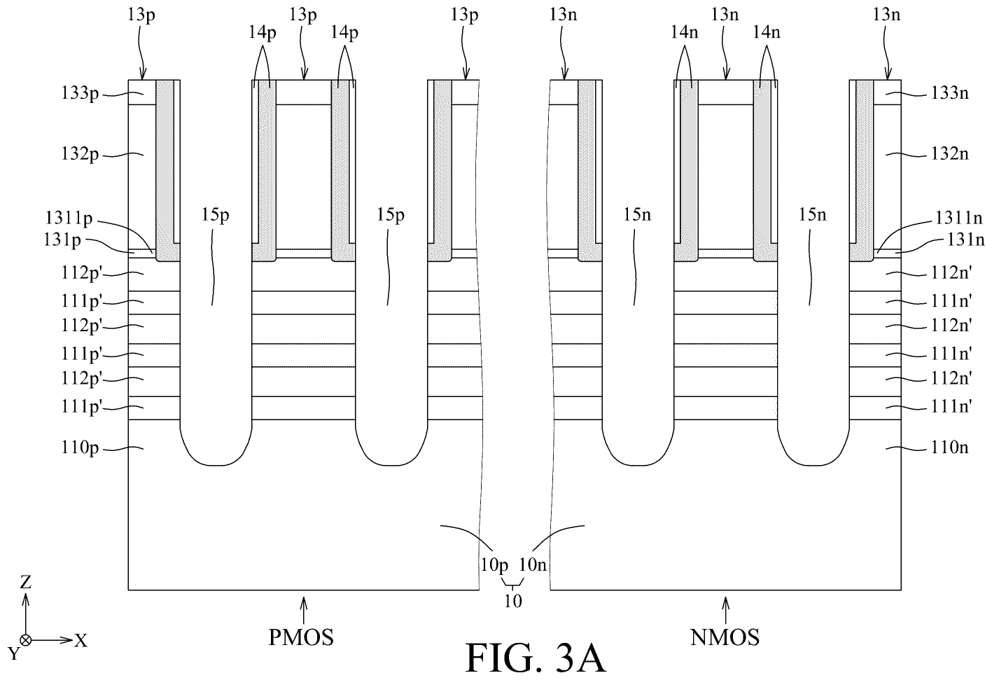

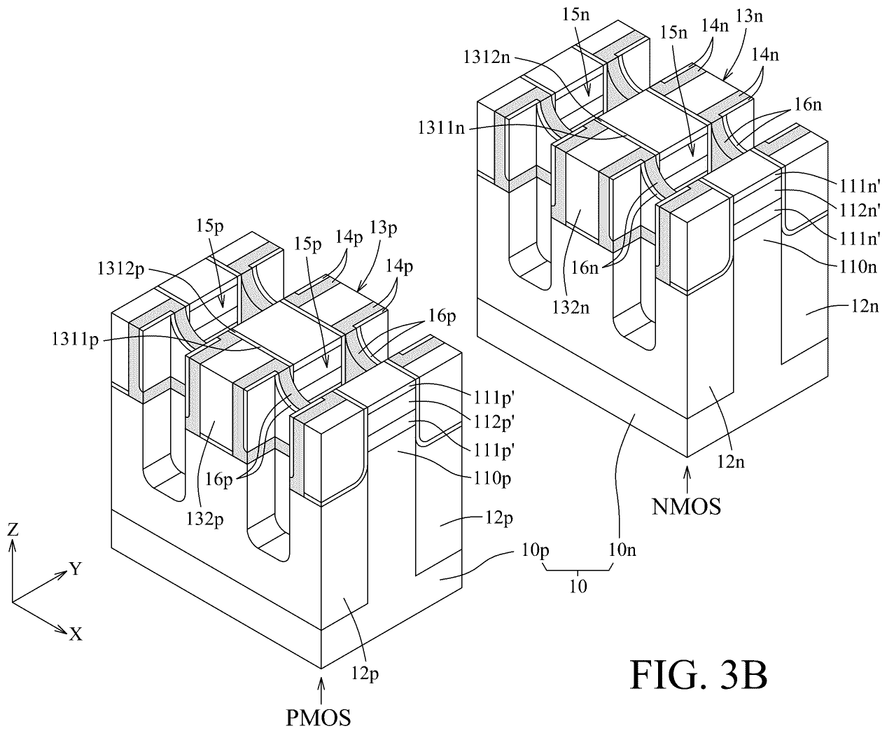

Referring to FIG. 1 and the examples illustrated in FIGS. 3A and 3B, the method 1 proceeds to step S102, where an isotropic etching process is performed on the spacer layer 140 (see FIGS. 2A and 2B) to remove horizontal portions of the spacer layer 140, while leaving vertical portions of the spacer layer 140, thereby exposing the cap portions 133p, 133n, portions of the fin structures 11p, 11n and the isolation trenches 12. Then, source/drain recesses 15p are formed in the exposed portions of the fin structure 11p, and source/drain recesses 15n are formed in the exposed portions of the fin structure 11n. FIGS. 3A and 3B are schematic views respectively similar to those of FIGS. 2A and 2B, but illustrating the structures after step S102.

The spacer layer 140 shown in FIGS. 2A and 2B is formed into pairs of gate spacers 14p and pairs of gate spacers 14n. Each pair of gate spacers 14p are respectively disposed at two opposite sides of a respective one of the dummy gates 132p in the X direction and at two opposite sides of a respective one of the cap portions 133p in the X direction. Each pair of gate spacers 14n are respectively disposed at two opposite sides of the dummy gates 132n in the X direction and at two opposite sides of the cap portions 133n in the X direction. Each of the gate spacers 14p, 14n is configured as a bi-layer structure.

Accordingly, dummy structures 13p and dummy structures 13n are thus obtained. Each of the dummy structures 13p includes one pair of the gate spacers 14p, a respective one of the dummy gates 132p, a respective one of the cap portion 133p which are disposed between the one pair of gate spacers 14p, and a respective one of the first portions 1311p of the dummy dielectric layer 131p which is disposed beneath the respective dummy gate 132p. Each of the dummy structures 13n includes one pair of the gate spacers 14n, a respective one of the dummy gates 132n, a respective one of the cap portion 133n which are disposed between the one pair of gate spacers 14n, and a respective one of the first portions 1311n of the dummy dielectric layer 131n which is disposed beneath the respective dummy gate 132n.

It is noted that the spacer layer 14 is also formed into pairs of fin spacers 16p and pairs of fin spacers 16n. Each pair of the fin spacers 16p, 16n are formed at two opposite sides of a respective one of the exposed portions of the fin structures 11p, 11n in the Y direction. In some embodiments, each pair of the fin spacers 16p, 16n are disposed on a respective one of the second portions 1312p, 1312n of the dummy dielectric layers 131p, 131n.

The source/drain recesses 15p, 15n are formed by selectively etching the exposed portions of the fin structures 11p, 11n, which are exposed from the dummy structures 13p, 13n, to expose the fins 110p, 110n. The sacrificial layers 111p and the channel layers 112p (see FIG. 2A) are patterned into first film stacks which are respectively located beneath the dummy structures 13p, and each of the first film stacks includes sacrificial films 111p′ and channel films 112p′. The sacrificial layers 111n and the channel layers 112n (see FIG. 2A) are patterned into second film stacks which are respectively located beneath the dummy structures 13n, and each of the second film stacks includes sacrificial films 111n′ and channel films 112n′. In some embodiments, the exposed portions of the fins 110p, 110n are etched to form the source/drain recesses 15p, 15n.

During formation of the source/drain recesses 15p, 15n, the pairs of fin spacers 16p, 16n are also etched to have a reduced height in the Z direction, and a middle part of each of the second portions 1312p, 1312n of the dummy dielectric layers 131p, 131n (see FIG. 2B) is also etched to have a reduced height in the Z direction or removed, and end parts of the second portions 1312p, 1312n of the dummy dielectric layers 131p, 131n each remain between one of the two lateral surfaces of the fin structure 11p, 11n, and a respective one of the gate spacers 14p, 14n. In FIG. 3B and subsequent figures, the end parts are also denoted by 1312p, 1312n.

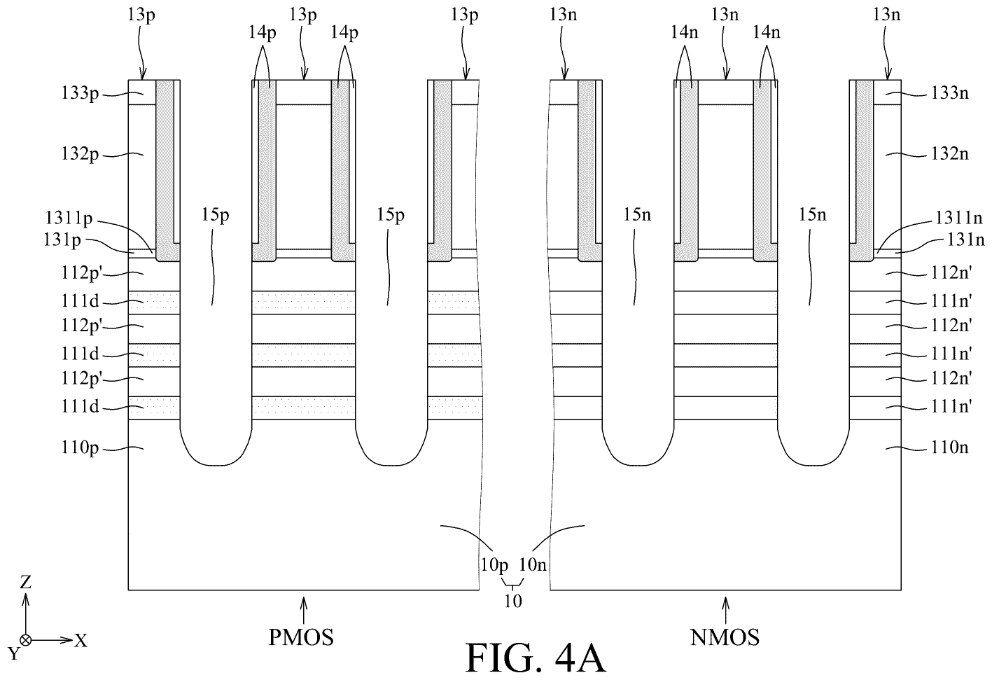

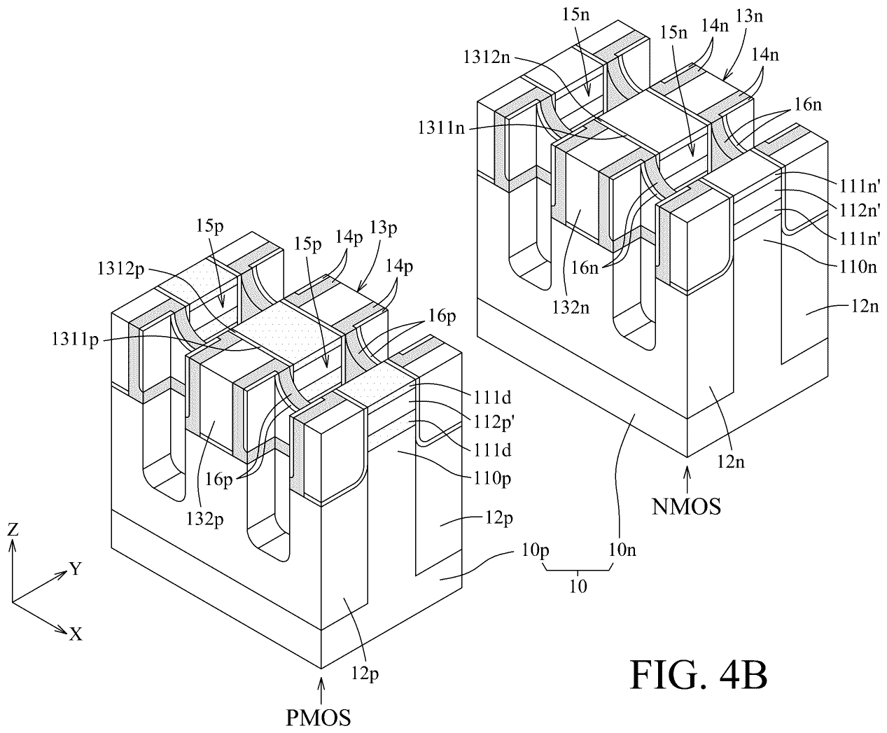

Referring to FIG. 1 and the examples illustrated in FIGS. 4A and 4B, the method 1 proceeds to step S103, where the sacrificial films 111p′ (see FIG. 3A) are replaced with dielectric interposers 111d. FIGS. 4A and 4B are schematic views respectively similar to those of FIGS. 3A and 3B, but illustrating the structures after step S103.

In some embodiments, the dielectric interposers 111d may include silicon oxide, silicon oxynitride, silicon oxycarbide, silicon oxycarbon nitride, or other suitable removable dielectric materials.

In some embodiments, step S103 may include multiple sub-steps as described in the following.

First, the sacrificial films 111p′ (see FIG. 3A) are removed to form gaps (not shown) by a selective etching process with the use of etchant(s) having a relatively high etching selectivity to the sacrificial films 111p′ and thus the channel films 112p′ and the dummy structures 13p are substantially intact. In some embodiments, the selective etching process may include dry etching, wet etching, other suitable etching techniques, or combinations thereof. In some embodiments, the etchant(s) may be gas-phase, liquid-phase, or other suitable states.

Then, the dielectric material for forming the dielectric interposers 111d is deposited to fill the gaps by CVD, ALD, or other suitable deposition techniques, and excess portions of the dielectric material for forming the dielectric interposers 111d are removed by a suitable etching process, so that the dielectric interposers 111d are respectively formed in the gaps.

During the removal of the sacrificial films 111p′ and formation of the dielectric interposers 111d, the structure at the NMOS region is protected by a protection layer (not shown). In some embodiments, the patterned mask may include a photoresist, a hard mask layer (which may be made of, for example, but not limited thereto, silicon oxide, silicon nitride, aluminum oxide, aluminum nitride, titanium nitride, or combinations thereof), or a combination thereof. The patterned mask will be removed after formation of the dielectric interposers 111d and before proceeding to the next step.

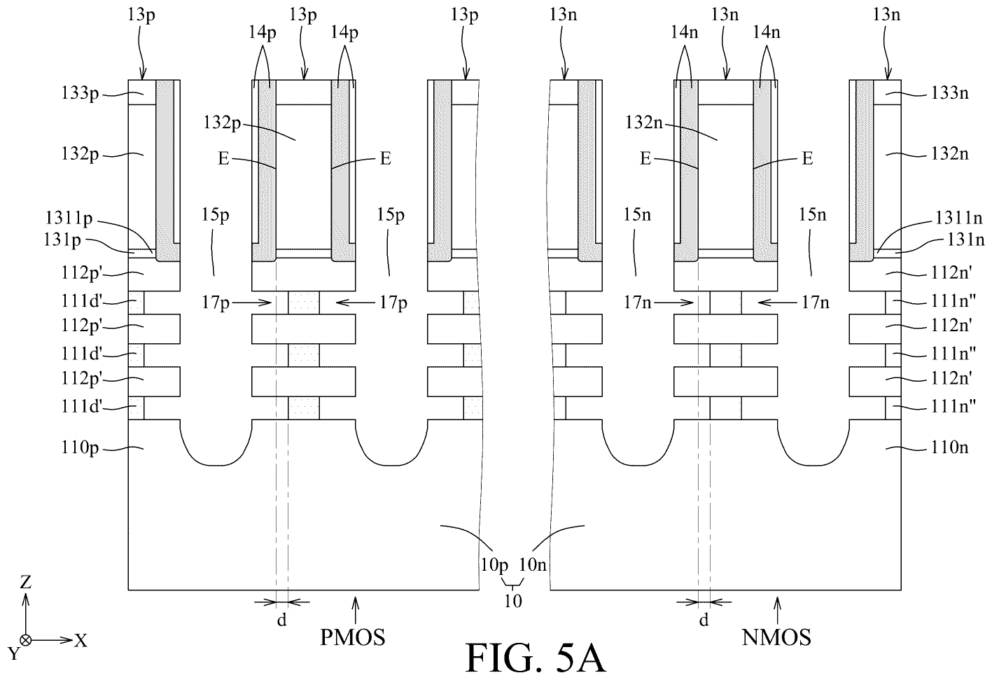

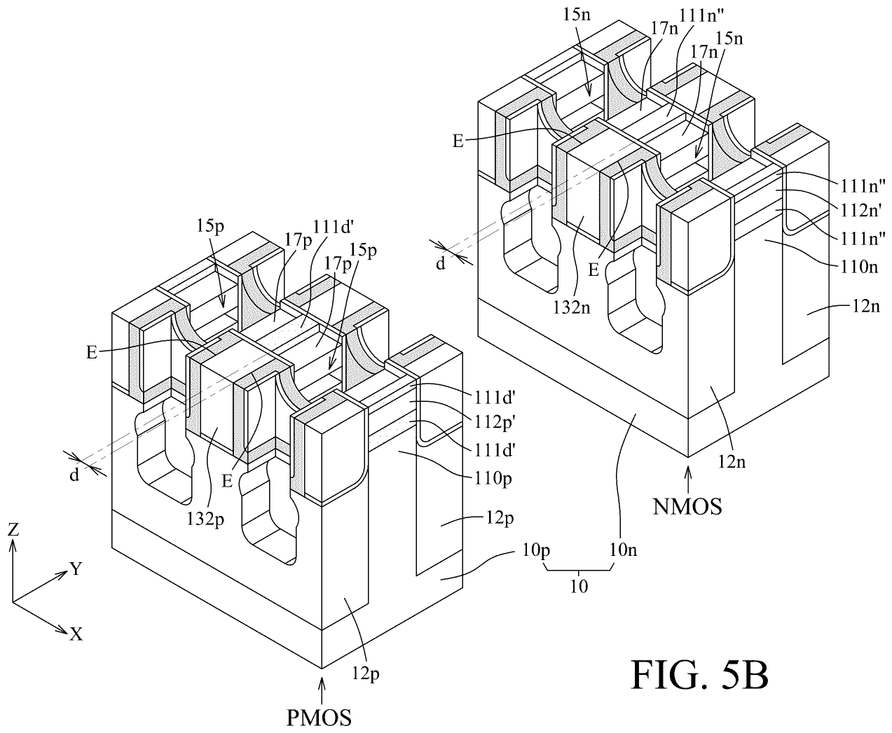

Referring to FIG. 1 and the examples illustrated in FIG. 5A and 5B, the method 1 proceeds to step S104, where the dielectric interposers 111d and the sacrificial films 111n′ are trimmed to form pairs of grooves 17p, 17n. FIGS. 5A and 5B are schematic views respectively similar to those of FIGS. 4A and 4B, but illustrating the structures after step S104.

To be specific, as shown in FIGS. 4A and 4B, each of the dielectric interposers 111d and the sacrificial films 111n′ has two side surfaces which are respectively exposed to two corresponding adjacent one of the source/drain recesses 15p, 15n, so that etchant(s) are accessible to the dielectric interposers 111d and the sacrificial films 111n′ so as to permit the dielectric interposers 111d and the sacrificial films 111n′ to be trimmed in step S104.

Each of the dielectric interposers 111d and the sacrificial films 111n′ are trimmed to have a reduced width in the X direction. The recessed dielectric interposers are denoted by 111d′, and the recessed sacrificial films are denoted by 111n″. Each pair of grooves 17p, 17n are respectively located beneath two end portions of a respective one of the channel films 112p′, 112n′.

It is noted that each pair of the grooves 17p, 17n is deepened in the X direction until, under the same cross-section in an XY plane, each pair of the grooves 17p, 17n respectively extend over two edges (E) of a respective one of the dummy gates 132p, 132n by a distance (d) of at least 2 nm. When the distance (d) is less than about 2 nm, step S108 (to be described later) may be difficult to perform. As shown in FIGS. 5A and 5B, the recessed dielectric interposers 111d′ and the recessed sacrificial films 111n″ each has a maximum width in the X direction that is less than a width of a respective one of the dummy gates 132p, 132n in the X direction. The distance (d) has a maximum value that is less than half the width of each of the dielectric interposers 111d and the sacrificial films 111n′ in the X direction, so that the dielectric interposers 111d and the sacrificial films 111n′ are prevented from being completely removed. In some embodiments, the distance (d) ranges from about 2 nm to about 6 nm.

The dielectric interposers 111d and the sacrificial films 111n′ are each trimmed by a selective etching process with the use of etchant(s) having a relatively high etching selectivity to the dielectric interposers 111d (or the sacrificial films 111n′), and thus the channel films 112n′, 112p′ and the dummy structures 13p, 13n are substantially intact.

In some embodiments, the trimming of the dielectric interposers 111d may be performed before or after the trimming of the sacrificial films 111n′. To be specific, during the trimming of the dielectric interposers 111d, the structure at the NMOS region will be protected by a protection layer (not shown). During the trimming of the sacrificial films 111n′, the structure at the PMOS region will be protected by another protection layer (not shown).

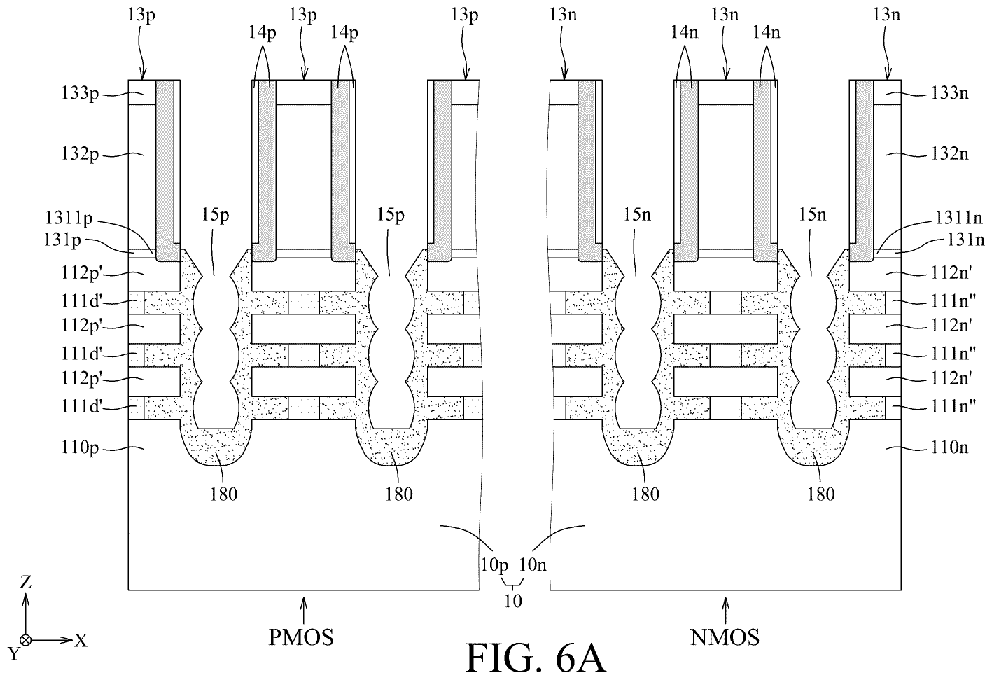

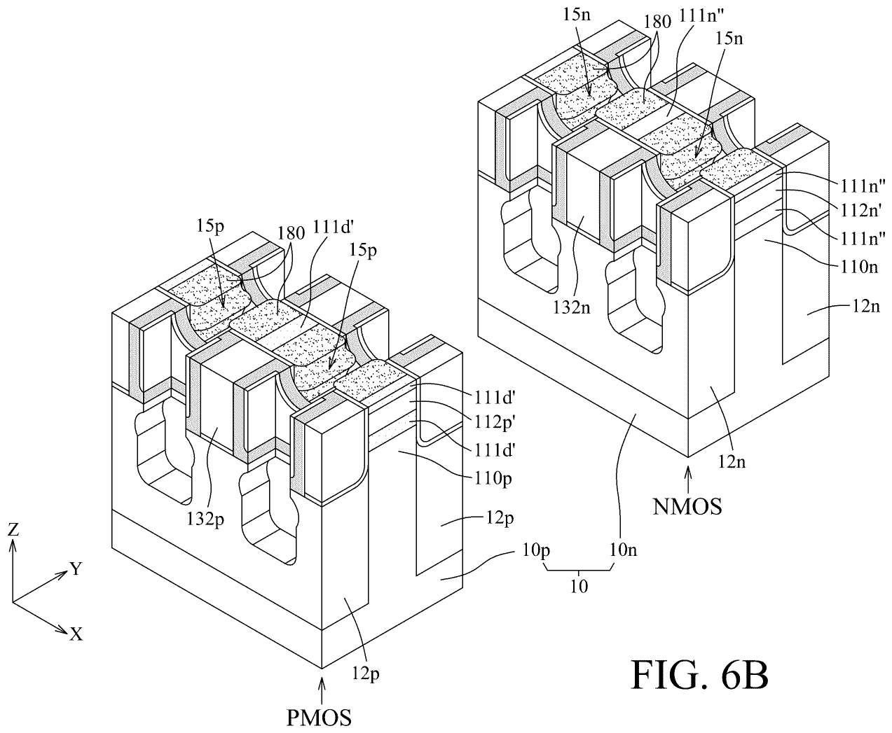

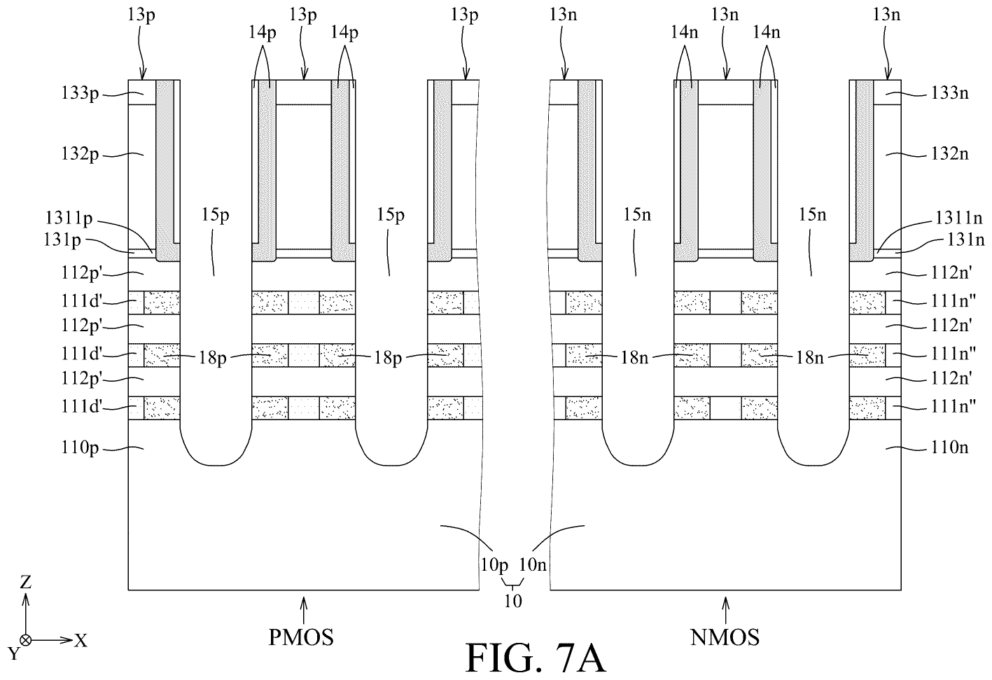

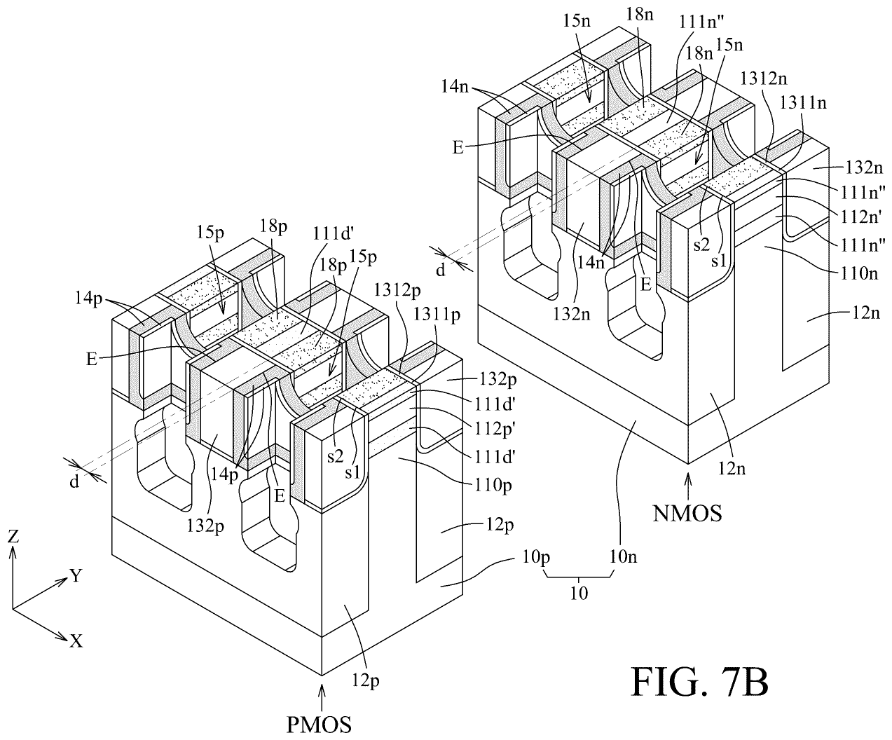

Referring to FIG. 1 and the examples illustrated in FIGS. 7A and 7B, the method 1 proceeds to step S105, where pairs of semiconductor spacers 18p, 18n (which may also referred to as pairs of semiconductor inner spacers) are respectively formed in the pairs of grooves 17p, 17n (see FIGS. 5A and 5B), so that each pair of the semiconductor spacers 18p, 18n are respectively disposed at two opposite sides of a respective one of the recessed dielectric interposers 111d′ and the recessed sacrificial films 111n″ in the X direction. FIGS. 7A and 7B are schematic views respectively similar to those of FIGS. 5A and 5B, but illustrating the structures after step S105. FIGS. 6A and 6B illustrate one possible intermediate state in step S105 in accordance with some embodiments.

In some embodiments, the pairs of semiconductor spacers 18p, 18n are each made of a semiconductor material that is different from each of the semiconductor material of the channel films 112p′, 112n′ and the semiconductor material of the recessed sacrificial films 111n″, so that in a subsequent step, the pairs of semiconductor spacers 18p, 18n are able to be selectively removed while the channel films 112p′, 112n′ and the recessed sacrificial films 111n″ are substantially intact due to different etching selectivity ratios. Possible semiconductor materials suitable for forming the pairs of semiconductor spacers 18p, 18n are similar to those for forming the substrate 10, and thus the details thereof are omitted for the sake of brevity. In some embodiments, in the same stack of channel films 112p′ or 112n′, the semiconductor spacers 18p, 18n may be grouped into first left inner spacers and first right inner spacers which are respectively opposite the first left inner spacers in the X direction. Each of the first left inner spacers is located beneath a left end region of a respective one of the channel films 112p′ or 112n′, and each of the first right inner spacers is located beneath a right end region of the respective one of the channel films 112p′ or 112n′. Each of the channel films 112p′, 112n′ has a middle region between the left end region and the right end region.

In some embodiments, the recessed sacrificial films 111n″ and the pairs of semiconductor spacers 18p, 18n are made of silicon germanium. The recessed sacrificial films 111n″ each includes germanium atoms in a first germanium concentration, and the pairs of semiconductor spacers 18p, 18n each includes germanium atoms in a second germanium concentration. The first germanium concentration is greater than the second germanium concentration. In some embodiments, the first germanium concentration ranges from about 25 atomic percentage (%) to about 50 atomic percentage (%). In some embodiments, the second germanium concentration ranges from about 10 atomic percentage (%) to about 20 atomic percentage (%). When the second germanium concentration is too large (e.g., greater than about 20 atomic percentage (%)), a tensile strain in the channel films 112p′ may adversely affect the device performance of the pMOSFETs at the PMOS region.

In some embodiments, step S105 may include multiple sub-steps as shown in FIGS. 6A and 6B and FIGS. 7A and 7B.

Firstly, as shown in FIGS. 6A and 6B, a semiconductor layer 180 is epitaxially formed on the channel films 112p′, 112n′ and the fins 110p, 110n, such that the pairs of grooves 17p, 17n (see FIGS. 5A and 5B) are filled with the semiconductor layer 180. The semiconductor layer 180 is made of the semiconductor material for forming the pairs of semiconductor spacers 18p, 18n.

Then, as shown in FIGS. 7A and 7B, an etching back process is performed to remove excess portions of the semiconductor layer 180 (see FIGS. 6A and 6B), so that the semiconductor layer 180 is formed into the pairs of semiconductor spacers 18p, 18n.

Referring to FIG. 7B, under the same cross-section in the XY plane, each pair of the semiconductor spacers 18p, 18n respectively extend over the two edges (E) of a respective one of the dummy gates 132p, 132n by the distance (d) as described above in step S104 with reference to FIGS. 5A and 5B. That is, each of the semiconductor spacers 18p, 18n has two side surfaces which are opposite to each other in the Y direction, and each of the side surfaces has a first region s1 and a second region s2. The first region s1 is covered by a corresponding one of the first portions 1311p, 1311n and a corresponding one of the dummy gates 132p, 132n, and the second region s2 is covered by a corresponding one of the end parts 1312p, 1312n and a corresponding one of the gate spacers 14p, 14n.

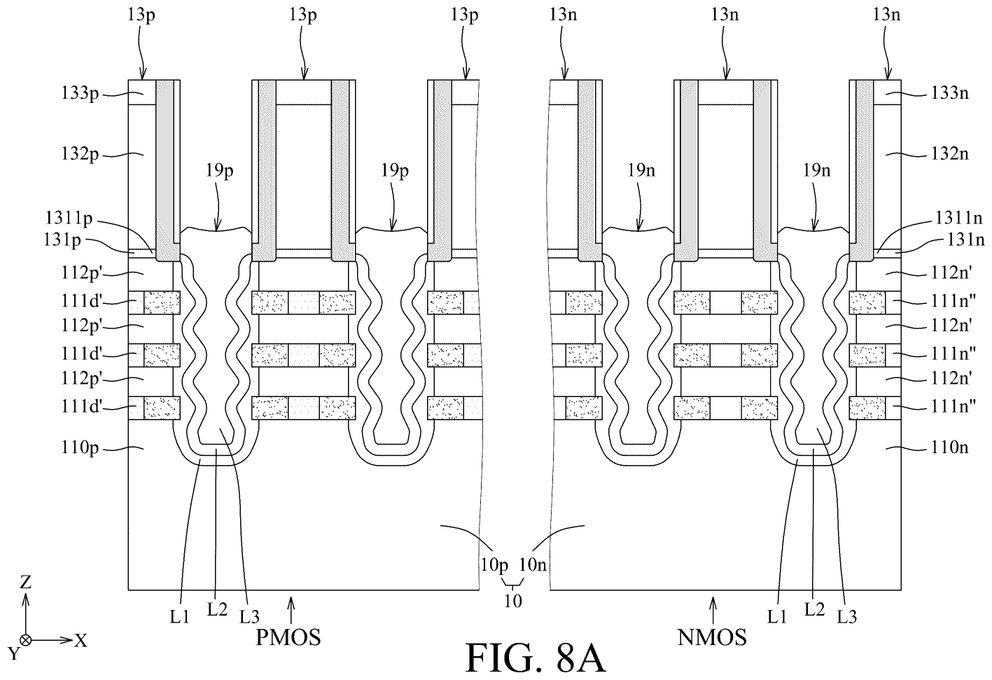

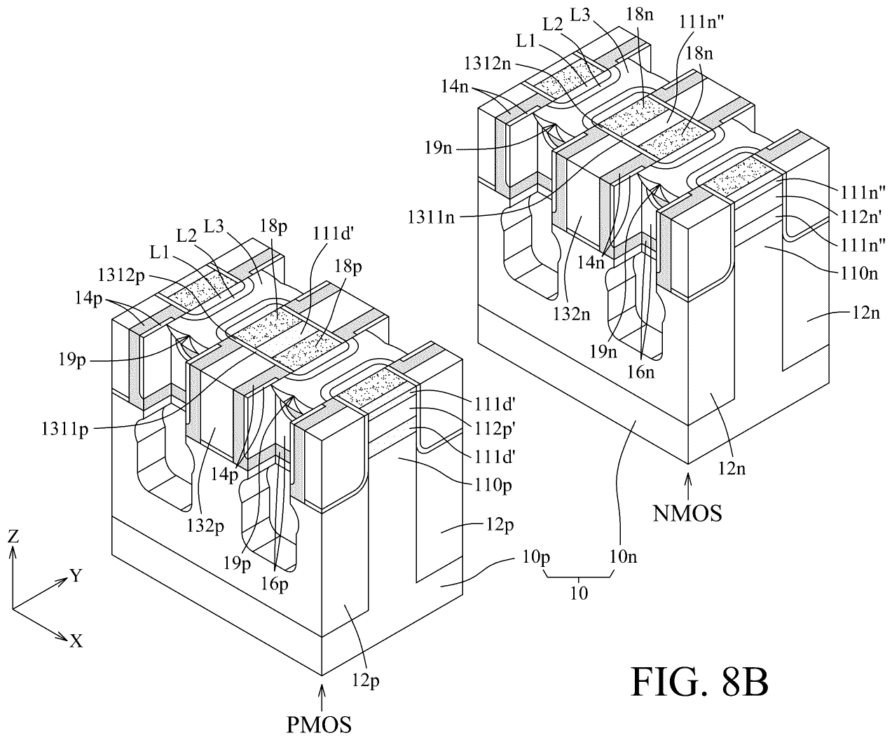

Referring to FIG. 1 and the examples illustrated in FIGS. 8A and 8B, the method 1 proceeds to step S106, where source/drain portions 19p, 19n are formed to fill the source/drain recesses 15p, 15n (see FIGS. 7A and 7B), respectively. FIGS. 8A and 8B are schematic views respectively similar to those of FIGS. 7A and 7B, but illustrating the structures after step S106.

In some embodiments, prior to formation of the source/drain portions 19p, 19n, the channel films 112p′, 112n′ may be trimmed to have a reduced width in the X direction.

Each of the source/drain portions 19p, 19n may include single crystalline silicon, single crystalline silicon germanium alloy, single crystalline silicon carbon alloy, single crystalline silicon carbon germanium alloy, polycrystalline silicon, polycrystalline silicon germanium, polycrystalline silicon carbon alloy, polycrystalline silicon carbon germanium alloy, or other suitable materials. The source/drain portions 19p may be doped with a p-type dopant so as to function as a source or a drain of a p-MOSFET. The source/drain portions 19n may each be doped with an n-type dopant so as to function as a source or a drain of an n-MOSFET. The p-type dopant may be, for example, but not limited to, boron or boron compound (for example, B, ¹¹B, BF₂), aluminum (Al), gallium (Ga), indium (In), other suitable p-type dopants, or combinations thereof. The n-type dopant may be, for example, but not limited to, phosphorous (P, ³¹P), arsenic (As), antimony (Sb), other suitable materials, or combinations thereof. In some embodiments, each of the source/drain portions 19p, 19n includes sub-layers L1, L2, L3. The sub-layers L1, L2, L3 of the source/drain portions 19p are doped with the p-type dopants at different concentrations. The sub-layers L1, L2, L3 of the source/drain portions 19n are doped with the n-type dopants at different concentrations.

In some embodiments, the source/drain portions 19p, 19n may be formed by an epitaxial growth process or other suitable deposition techniques, and an implantation process for introducing dopants (i.e., the n-type dopant or the p-type dopant) into the source/drain portions 19p, 19n.

Referring to FIG. 8A, it is worth noting that each of the source/drain portions 19p, 19n is epitaxially formed along a continuous semiconductor surface which is provided by a corresponding one of the fins 110p, 110n, corresponding adjacent ones of the semiconductor spacers 18p, 18n, and corresponding adjacent ones of the channel films 112p′, 112n′. Therefore, each of the source/drain portions 19p, 19n has a perfect crystal structure with reduced crystal defects or even without crystal defects.

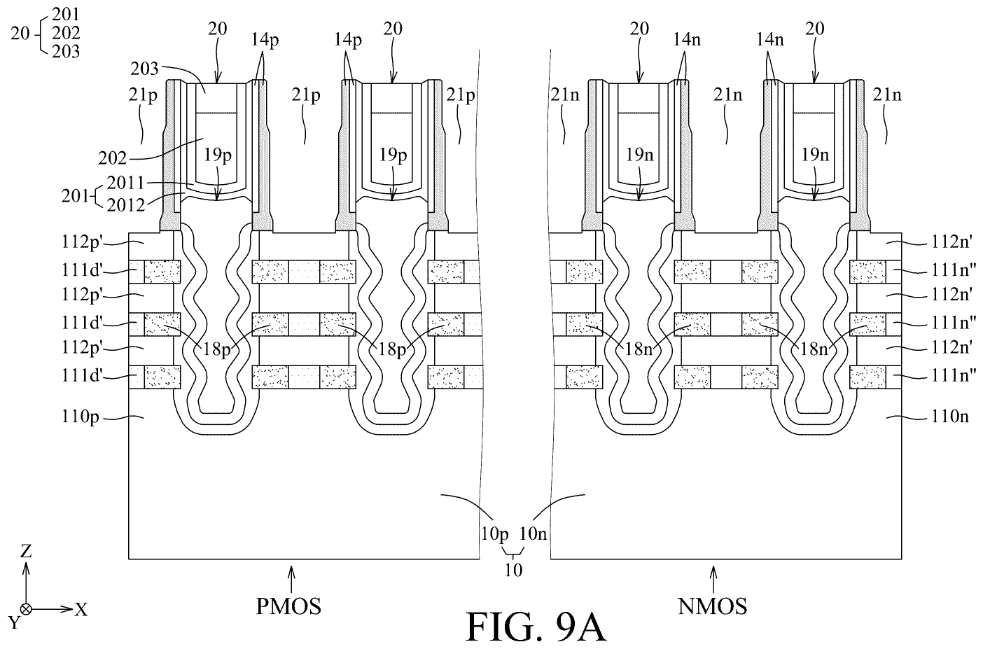

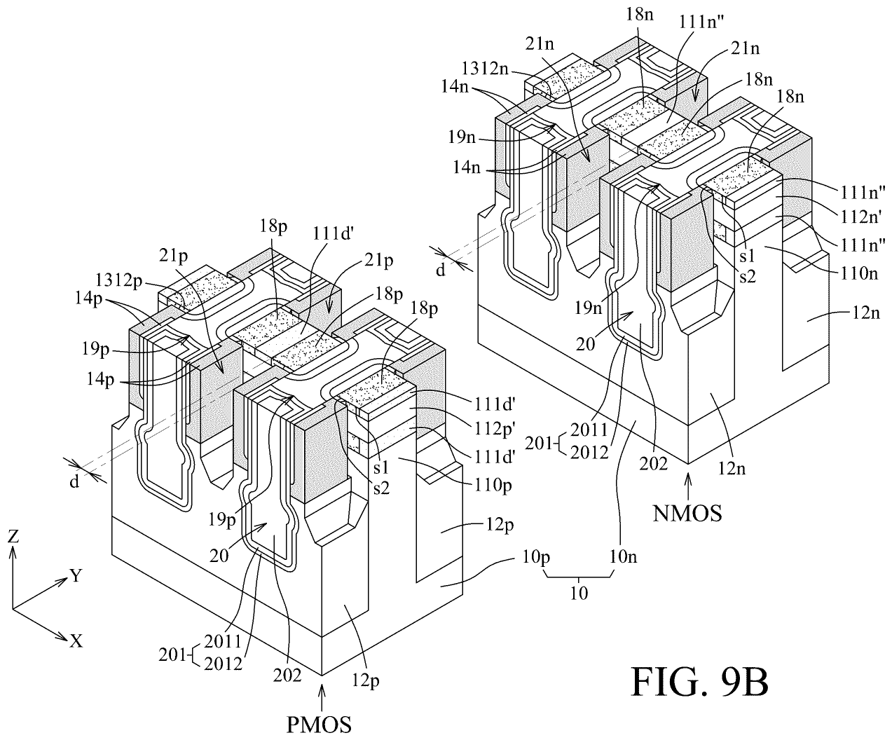

Referring to FIG. 1 and the examples illustrated in FIGS. 9A and 9B, the method 1 proceeds to step S107, where isolation portions 20 are respectively formed over the source/drain portions 19n, 19p, and then the cap portions 133p, 133n, the dummy gates 132p, 132n, and the first portions 1311p, 1311n of the dummy dielectric layers 131p, 131n (see FIG. 8A) are removed to form cavities 21p, 21n, such that the channel films 112p′, 112n′, the recessed dielectric interposers 111d′, the recessed sacrificial films 111n″, and the pairs of semiconductor spacers 18p, 18n are exposed to the cavities 21p, 21n. FIGS. 9A and 9B are schematic views respectively similar to those of FIGS. 8A and 8B, but illustrating the structures after step S107.

In some embodiments, each of the isolation portions 20 includes a contact etch stop layer (CESL) 201, an inter-layer dielectric (ILD) layer 202 and a hard mask 203.

In some embodiments, the ILD layer 202 is disposed on a respective one of the source/drain portions 19p, 19n, and may include silicon oxide, doped silicon oxide (e.g., phospho-silicate glass (PSG), boro-phospho-silicate glass (BPSG), fluoro-silicate glass (FSG), carbon-doped silicon oxide (SiCOH)), other suitable low-k dielectric materials, or combinations thereof. The CESL 201 is disposed to separate the ILD layer 202 from each of the respective source/drain portion 19p or 19n and two adjacent ones of the gate spacers 14p, 14n, and may include silicon nitride, silicon oxynitride, silicon carbonnitride, or other suitable dielectric materials that are different from the dielectric material of the ILD layer 202. In some embodiments, the CESL 201 may be configured as a bi-layered structure, and includes a first sub-layer 2011 and a second sub-layer 2012. The first sub-layer 2011 is disposed between the second sub-layer 2012 and the ILD layer 202. In some embodiments, the second sub-layer 2012 has a k value that is greater than a k value of the first sub-layer 2011. The k value of each of the first and second sub-layers 2011, 2012 may be adjusted by varying the proportions of silicon, oxygen, carbon, nitrogen, and/or other elements (such as hydrogen) in the dielectric material of the same. In some embodiments, the hard mask 203 is disposed on the ILD layer 202, and is made of a material different from that of ILD layer 202, so that the ILD layer 202 may be prevented from being damaged during removal of the first portions 1311p, 1311n of the dummy dielectric layers 131p, 131n (see FIG. 8A) and removal of the recessed dielectric interposers 111d′ (will be described in step S110). In some embodiments, the material of the hard mask 203 may be the same as or different from that of the CESL 201. In some embodiments, the hard mask 203 includes silicon nitride, silicon carbide, silicon oxycarbide, silicon oxynitride, silicon carbonitride, silicon oxycarbonitride, metal oxide (e.g., aluminum oxide, hafnium oxide, zirconium oxide, aluminum nitride, titanium nitride), or combinations thereof.

In some embodiments, formation of each of the isolation portions 20 include multiple sub-steps as described in the following. Firstly, a first layer (not shown) for forming the CESL 201 and a second layer (not shown) for forming the ILD layer 202 are sequentially formed on the source/drain portions 19p, 19n and the dummy structures 13p, 13n using CVD, PVD, ALD or other possible processes, followed by a planarization process (e.g., chemical mechanical polishing) to expose the dummy gates 132p, 132n of the dummy structures 13p, 13n (see FIG. 8A). The first layer is formed into the CESL 201. The second layer is further etched back to have a reduced height in the Z direction by an etching process, thereby obtaining the ILD layer 202. Afterwards, the hard mask 203 is formed on the ILD layer 202 using CVD, PVD, ALD or other possible processes, followed by a planarization process (e.g., CMP) to expose the dummy gates 132p, 132n of the dummy structures 13p, 13n (see FIG. 8A).

Each of the cavities 21p, 21n is located between a respective pair of the gate spacers 14p, 14n.

Referring to FIG. 9B, in some embodiments, the end parts 1312p, 1312n (i.e., the second portions remained in step S102) are not completely removed. The end parts 1312p, 1312n still cover the second regions s2 of the semiconductor spacers 18p, 18n, as shown in FIG. 9B.

After step S107, the first region s1 of each of the two side surfaces of each of the semiconductor spacers 18p, 18n is exposed to a corresponding one of the cavities 21p, 21n, so that etchant(s) used in the next step (e.g., step S108) are accessible to the semiconductor spacers 18p, 18n so as to permit the semiconductor spacers 18p, 18n to be removed in step S108. It is noted that when the distance (d) is less than about 2 nm, the semiconductor spacers 18p, 18n may not be removed or may not be completely removed in step S108.

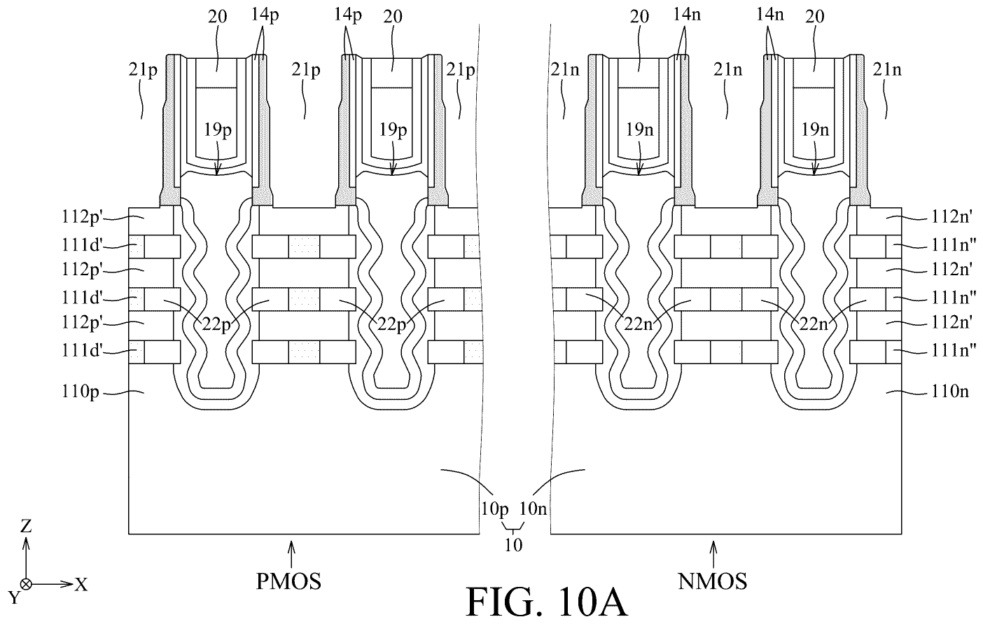

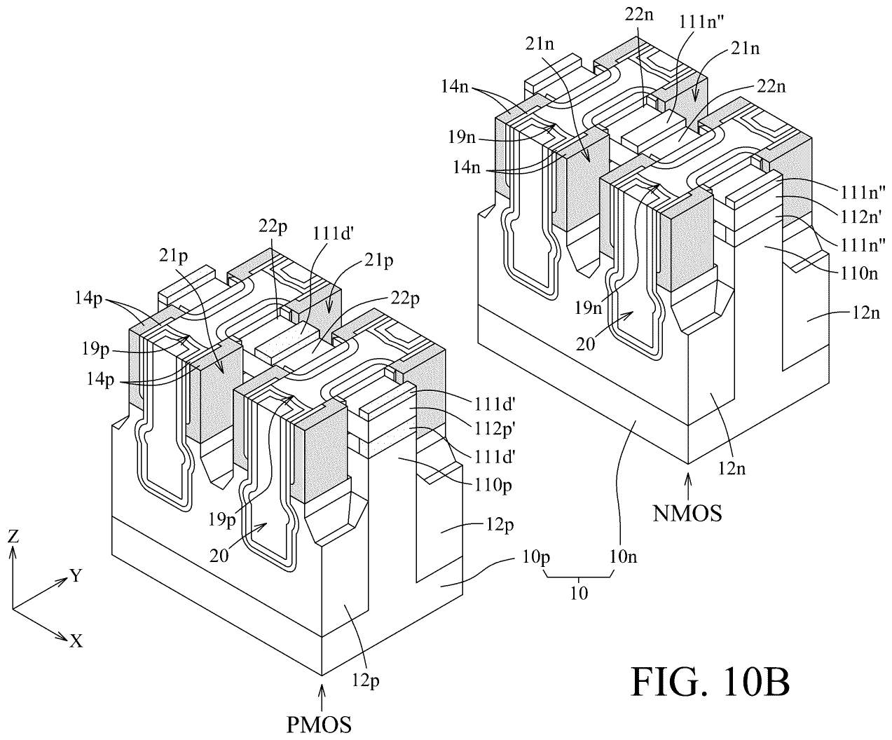

Referring to FIG. 1 and the examples illustrated in FIGS. 10A and 10B, the method 1 proceeds to step S108, where the pairs of semiconductor spacers 18p, 18n (see FIGS. 9A and 9B) are removed to form pairs of outer gaps 22p, 22n, respectively. FIGS. 10A and 10B are schematic views respectively similar to those of FIGS. 9A and 9B, but illustrating the structures after step S108.

Each pair of the outer gaps 22p, 22n is in spatial communication with a corresponding one of the cavities 21p, 21n.

The pairs of semiconductor spacers 18p, 18n are removed by a selective etching process with the use of etchant(s) having a relatively high etching selectivity to the semiconductor spacers 18p, 18n, and thus the channel films 112n′, 112p′, the recessed dielectric interposers 111d′, the recessed sacrificial films 111n″, and other dielectric elements 14p, 14n, 20 are substantially intact.

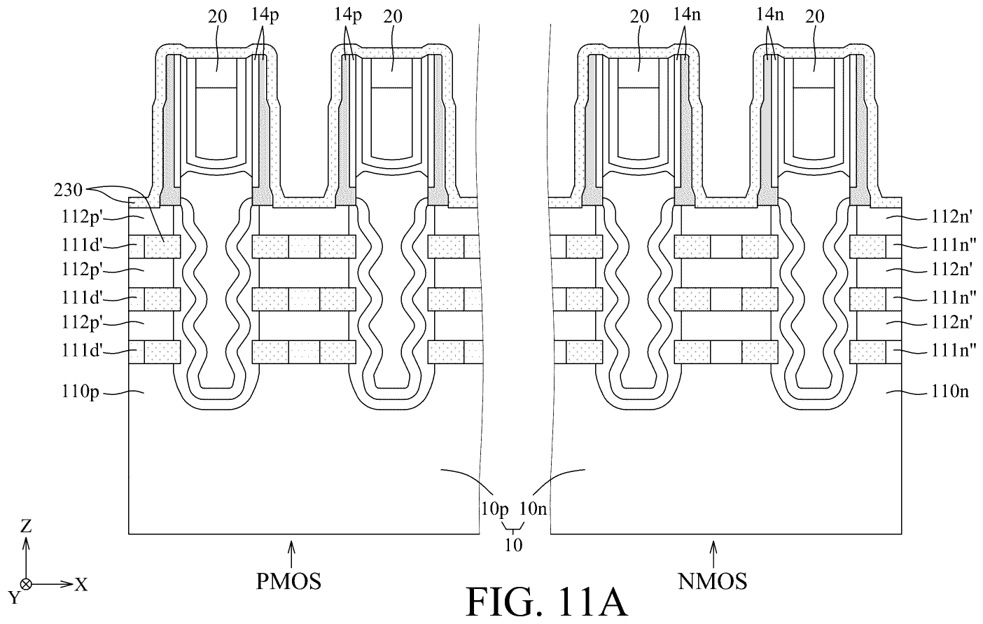

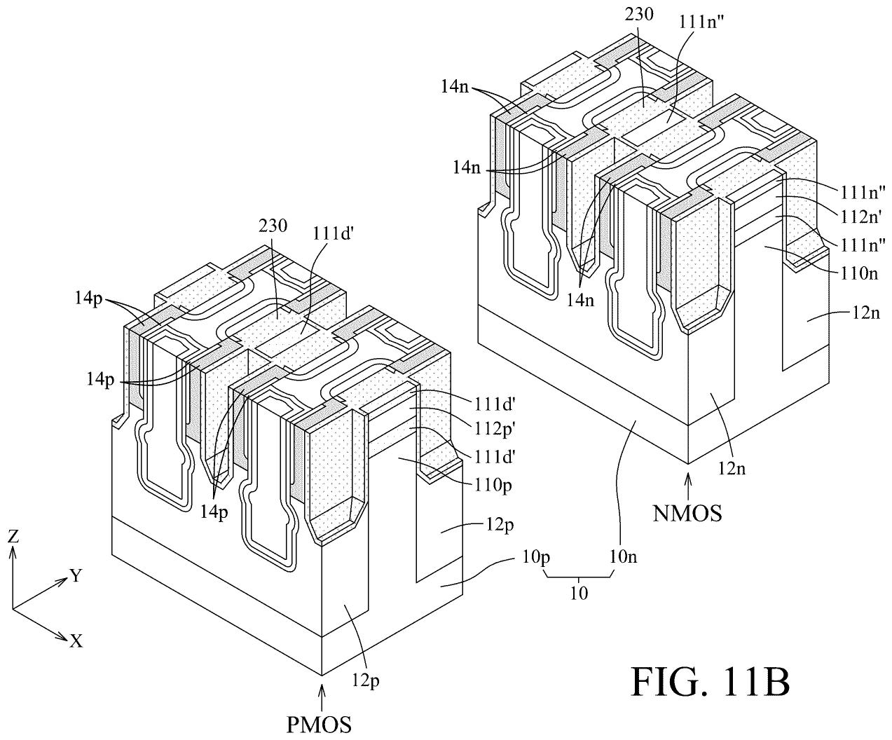

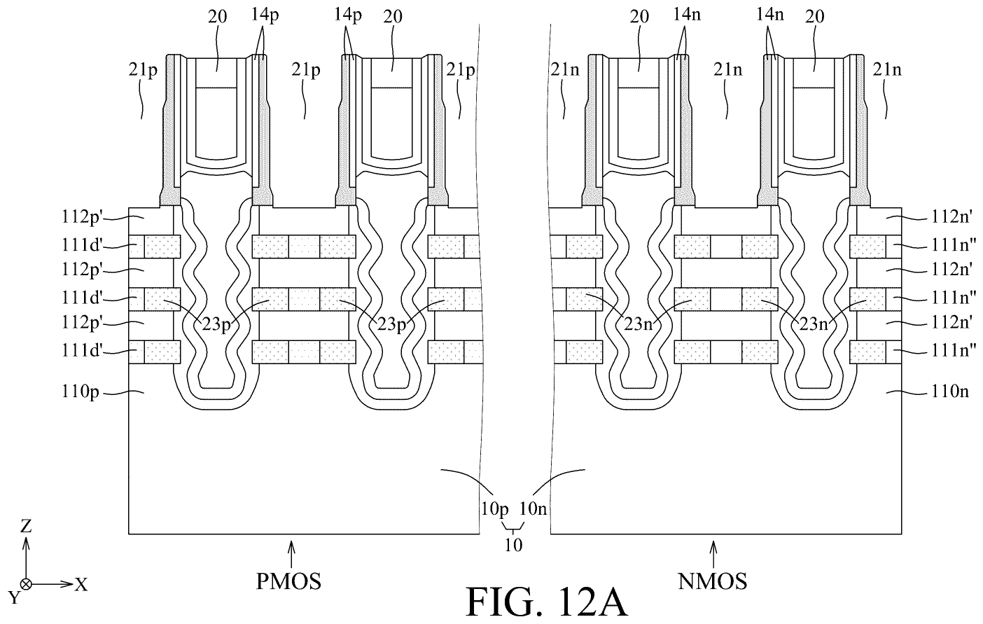

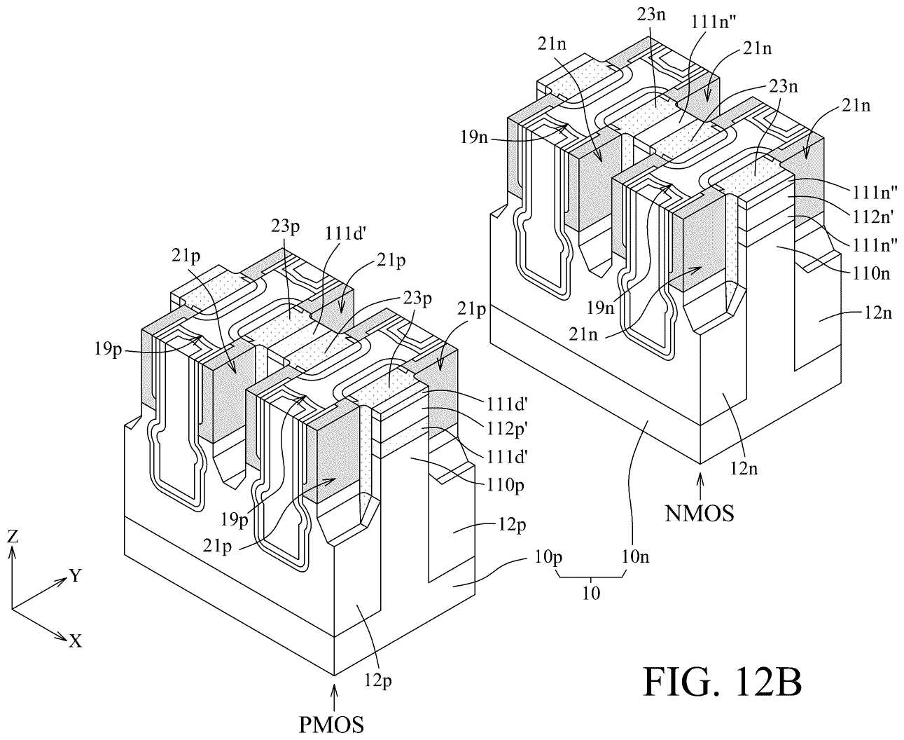

Referring to FIG. 1 and the examples illustrated in FIGS. 12A and 12B, the method 1 proceeds to step S109, where pairs of dielectric spacers 23p, 23n (which may be also referred to as dielectric inner spacers) are respectively formed in the pairs of outer gap 22p, 22n (see FIGS. 10A and 10B). FIGS. 12A and 12B are schematic views respectively similar to those of FIGS. 10A and 10B, but illustrating the structures after step S109. FIGS. 11A and 11B illustrate one possible intermediate state in step S109 in accordance with some embodiments.

Each pair of the dielectric spacers 23p, 23n are respectively disposed at two opposite sides of a respective one of the recessed dielectric interposers 111d′ and the recessed sacrificial films 111n″ in the X direction to separate the respective recessed dielectric interposer 111d′ (or the respective recessed sacrificial films 111n″) from two adjacent ones of the source/drain portions 19p, 19n. In some embodiments, similar to the semiconductor spacers 18n, 18p, in the same stack of channel films 112p′ or 112n′, the dielectric spacers 23p, 23n may be grouped into second left inner spacers and second right inner spacers which are respectively opposite the second left inner spacers in the X direction. Each of the second left inner spacers is located beneath the left end region of the respective one of the channel films 112p′ or 112n′, and each of the second right inner spacers is located beneath the right end region of the respective one of the channel films 112p′ or 112n′.

In some embodiments, the pairs of dielectric spacers 23p, 23n are each made of silicon oxide, silicon oxycarbide, silicon oxynitride, silicon oxycarbonitride, other suitable low-k dielectric materials, or combinations thereof. It is noted that the dielectric material of the pairs of dielectric spacers 23p, 23n is different from the dielectric material of the recessed dielectric interposers 111d′, so that the recessed dielectric interposers 111d′ are able to be selectively removed in the next step S110 with the pairs of dielectric spacers 23p, 23n being substantially intact due to different etching selectivity ratios.

In some embodiments, step S109 may include multiple sub-steps as shown in FIGS. 11A and 11B and FIGS. 12A and 12B.

Firstly, as shown in FIGS. 11A and 11B, a dielectric layer 230 is formed on the structure obtained after step S108 to fill the pairs of outer gaps 22p, 22n (see FIGS. 10A and 10B). The dielectric layer 230 is made of the dielectric material for forming the pairs of dielectric spacers 23p, 23n.

Then, as shown in FIGS. 12A and 12B, an etching back process is performed to remove excess portions of the dielectric layer 230 so as to permit each of the channel films 112p′, 112n′, the recessed dielectric interposers 111d′, and the recessed sacrificial films 111n″ to be exposed to a corresponding one of the cavities 21p, 21n. Accordingly, the dielectric layer 230 is formed into the pairs of dielectric spacers 23p, 23n.

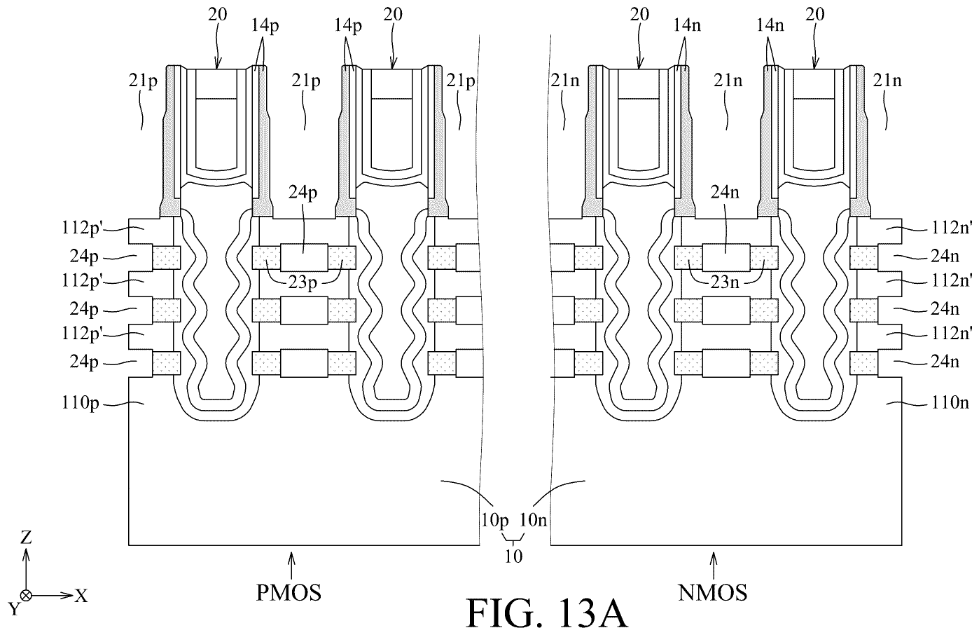

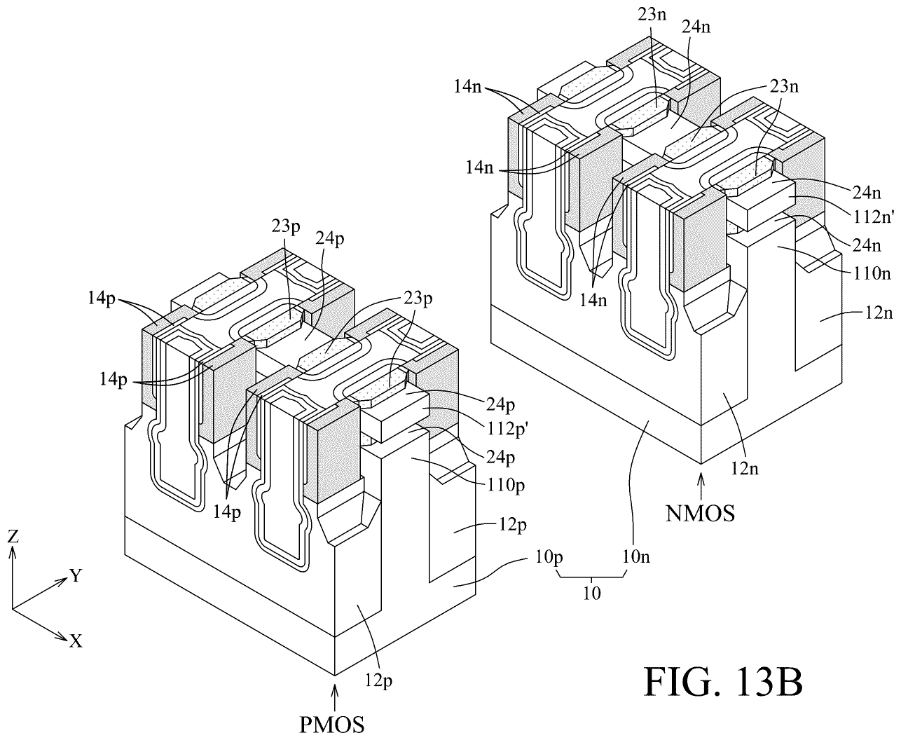

Referring to FIG. 1 and the examples illustrated in FIGS. 13A and 13B, the method 1 proceeds to step S110, where the recessed dielectric interposers 111d′ (see FIGS. 12A and 12B) are removed to form inner gaps 24p, and the recessed sacrificial films 111n″ (see FIGS. 12A and 12B) are removed to form inner gaps 24n. FIGS. 13A and 13B are schematic views respectively similar to those of FIGS. 12A and 12B, but illustrating the structures after step S110.

The recessed dielectric interposers 111d′ and the recessed sacrificial films 111n″ are each removed by a selective etching process with the use of etchant(s) having a relatively high etching selectivity to the recessed dielectric interposers 111d′ (or the recessed sacrificial films 111n″), and thus the channel films 112p′, 112n′, the pairs of dielectric spacers 23p, 23n, the isolation portions 20, and the pairs of gate spacers 14p, 14n are substantially intact.

In some embodiments, the removal of the recessed dielectric interposers 111d′ (see FIGS. 12A and 12B) may be performed before or after the removal of the recessed sacrificial films 111n″ (see FIGS. 12A and 12B). To be specific, during the removal of the recessed dielectric interposers 111d′, the structure at the NMOS region will be protected by a protection layer (not shown). During the removal of the sacrificial films 111n″, the structure at the PMOS region will be protected by another protection layer (not shown).

In some embodiments, after the removal of the recessed dielectric interposers 111d′ and the recessed sacrificial films 111n″, each pair of the dielectric spacers 23p, 23n may be etched back to enlarge a dimension of a respective one of the inner gaps 24p, 24n in the X direction.

Referring to FIG. 1 and the examples illustrated in FIGS. 14A and 14B, the method 1 proceeds to step S111, where gate structures 25p are formed in the cavities 21p and the inner gaps 24p (see FIGS. 13A and 13B), and gate structures 25n are formed in the cavities 21n and the inner gaps 24n (see FIGS. 13A and 13B). The device structures 100p, 100n are thus obtained. FIGS. 14A and 14B are schematic views respectively similar to those of FIGS. 13A and 13B, but illustrating the structures after step S111.

Each of the gate structures 25p is disposed around the middle regions of corresponding ones of the channel films 112p′ (a bottommost one of which is shown in FIG. 14B), and each of the gate structures 25n is disposed around the middle regions of corresponding ones of the channel films 112n′ (a bottommost one of which is shown in FIG. 14B). Each of the gate structures 25p, 25n is separated from two corresponding adjacent ones of the source/drain portions 19p, 19n by corresponding pairs of the dielectric spacers 23p, 23n.

In some embodiments, each of the gate structures 25p, 25n includes a gate dielectric 251 and a gate electrode 252. The gate electrode 252 is separated from the corresponding channel films 112p′, 112n′ by the gate dielectric 251.

In some embodiments, the gate dielectric 251 includes a metal-containing high-k dielectric layer. The metal-containing high-k dielectric layer includes, for example, but not limited to, Hf-containing dielectric oxide materials, Ta-containing dielectric oxide materials (e.g., Ta₂O₅), Ti-containing dielectric oxide materials, Zr-containing dielectric oxide materials, Al-containing dielectric oxide materials (e.g., Al₂O₃), La-containing dielectric materials, other suitable materials (having a dielectric constant not less than about 9 or larger than about 30), or combinations thereof.

The gate electrode 252 may be configured as a multi-layered structure which includes multiple sub-layers 2521, 2522, 2523, 2524. The number of the sub-layers of the gate electrode 252 is exemplarily shown as four, but may vary according to practical applications. In some embodiments not shown herein, the number of the sub-layers of the gate electrode 252 of the gate structure 25p may be the same as or different from the number of the sub-layers of the gate electrode 252 of the gate structure 25n.

The sub-layers 2521, 2522, 2523, 2524 include work-function portion(s) which are provided for adjusting threshold voltage of an n-FET or a p-FET, and electrically conductive filling portion(s) which have a low resistance and which are provided for reducing overall electrical resistance of the gate electrode 252. The materials (e.g. an electrically conductive material and a work function metal material) of the gate electrode 252 may include, for example, but not limited to, a metal (e.g., copper, aluminum, titanium, tantalum, cobalt, tungsten, or the like, or alloys thereof), polysilicon, metal-containing nitrides (e.g., TaN), metal-containing silicides (e.g., NiSi), metal-containing carbides (e.g., TaC), or the like, or combinations thereof. Other suitable materials for forming the gate dielectric 251 and the gate electrode 252 are within the contemplated scope of the present disclosure.

In some embodiments, prior to formation of the gate dielectric 251 of each of the gate structures 25p, 25n, interfacial layers 250 may be respectively formed on the channel films 112p′, 112n′. Each of the interfacial layers 250 serves to provide a good adhesion between the gate dielectric 251 and the respective channel film 112p′ or 112n′. In some embodiments, the interfacial layers 250 are made of silicon oxide, and are formed by an oxidation reaction that happens on a surface portion of each of the channel films 112p′, 112n′.

In some embodiments not shown herein, an interconnect structure may be further formed on the semiconductor structure 100, so as to permit an operating voltage to be applied to each of the source/drain portions 19p, 19n and to be applied to the gate electrode 252 of each of the gate structures 25p, 25n. In some embodiments, the interconnect structure may include an inter-metal dielectric (IMD) portion in which a plurality of electrically conductive elements (for example, metal contacts, metal lines and/or metal vias) are formed so as to permit each of the source/drain portions 19p, 19n and the gate electrode 252 of each of the gate structures 25p, 25n to be electrically connected to a power supply through the electrically conductive elements. The interconnect structure may be formed by a dual damascene process, a single damascene process, or other suitable back-end-of-line (BEOL) techniques.

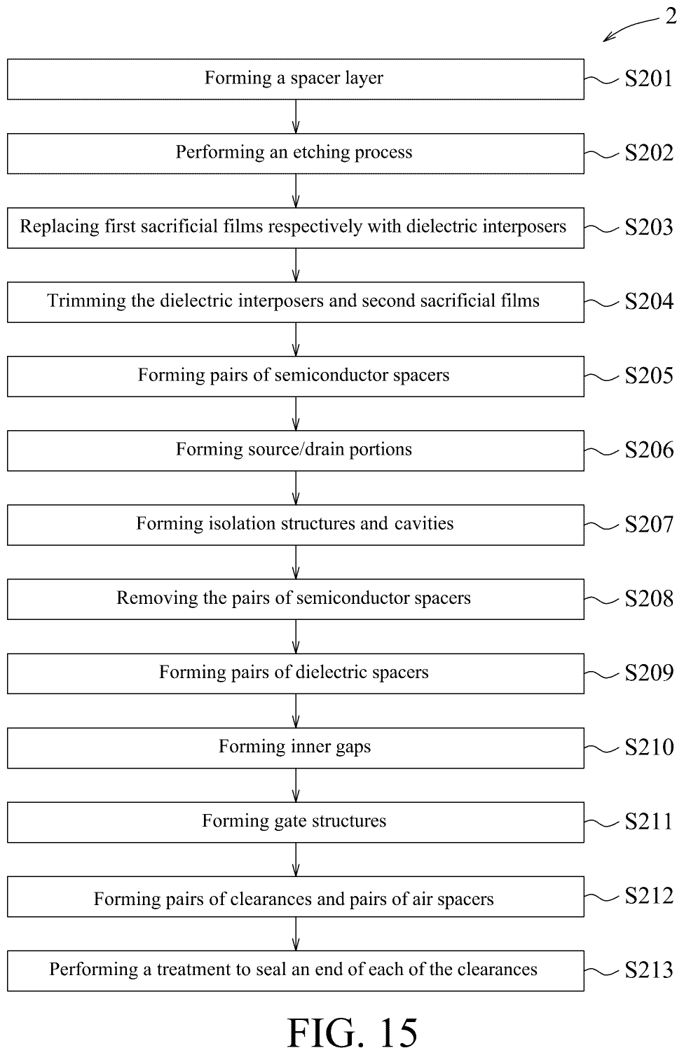

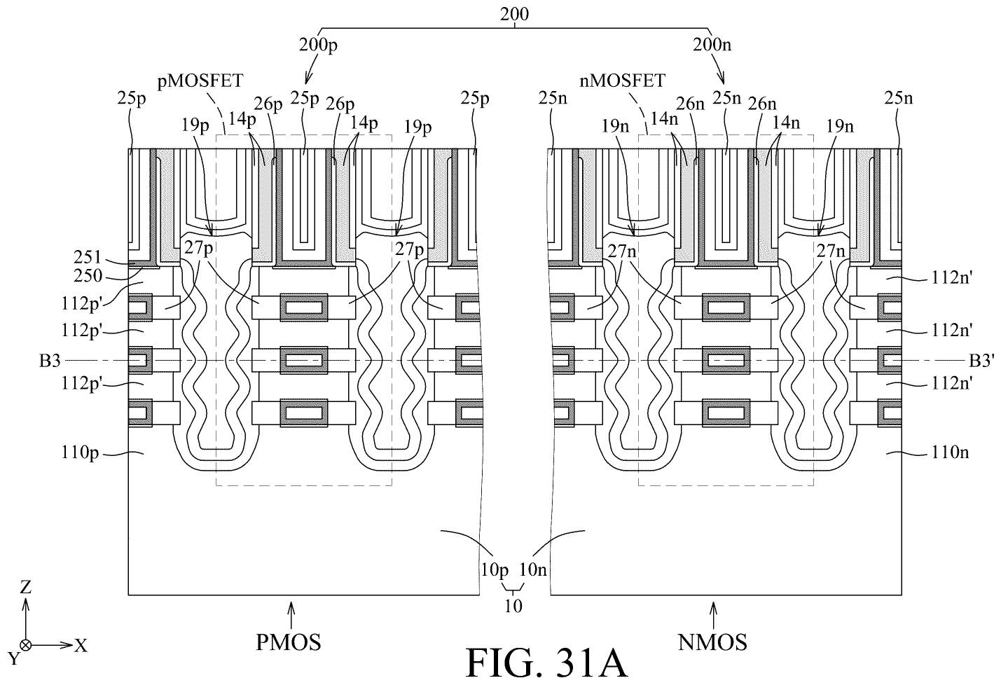

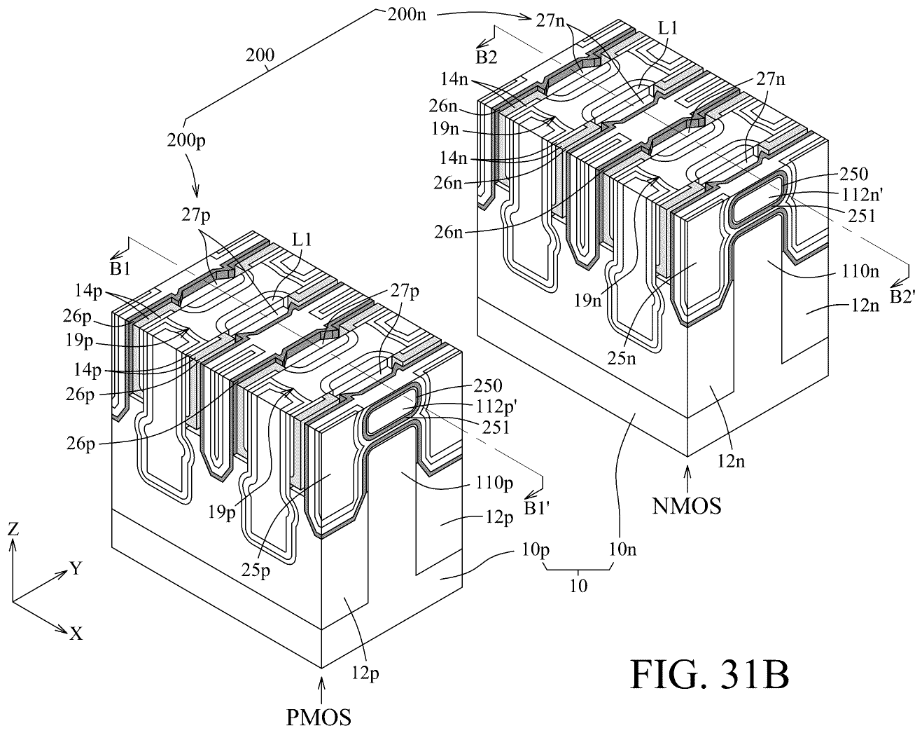

FIG. 15 is a flow diagram illustrating a method 2 for manufacturing a semiconductor structure (for example, but not limited to, a semiconductor structure 200 shown in FIGS. 31A and 31B) in accordance with some embodiments. The semiconductor structure 200 has a structure similar to that of the semiconductor structure 100 shown in FIGS. 14A and 14B, but has the differences in the following. In the semiconductor structure 200, pairs of first clearances 26p, 26n are formed. Each of the first clearances 26p, 26n is formed between one of the gate structures 25p, 25n and a corresponding one of the gate spacers 14p, 14n. In addition, the pairs of dielectric spacers 23p, 23n in the semiconductor structure 100 are removed through the pairs of first clearances 26p, 26n, so that pairs of air spacers 27p, 27n are thus formed. Each of the first clearances 26p, 26n is in spatial communication with corresponding one of the air spacers 27p, 27n.

The method 2 may include steps S201 to S213, in which steps S203, S204, S206, S209 to S211 are respectively similar to steps S103, S104, S106 and S109 to S111 of the method 1, and thus the same details thereof will be not be repeated for the sake of brevity. In addition, since steps S201, S202, S205, S207 and S208 are respectively similar to steps S101, S102, S105, S107 and S108, but with slight differences, only the differences will be described in the following. Besides, steps S212 to S213 (not included in the method 1) will be also described in the following.

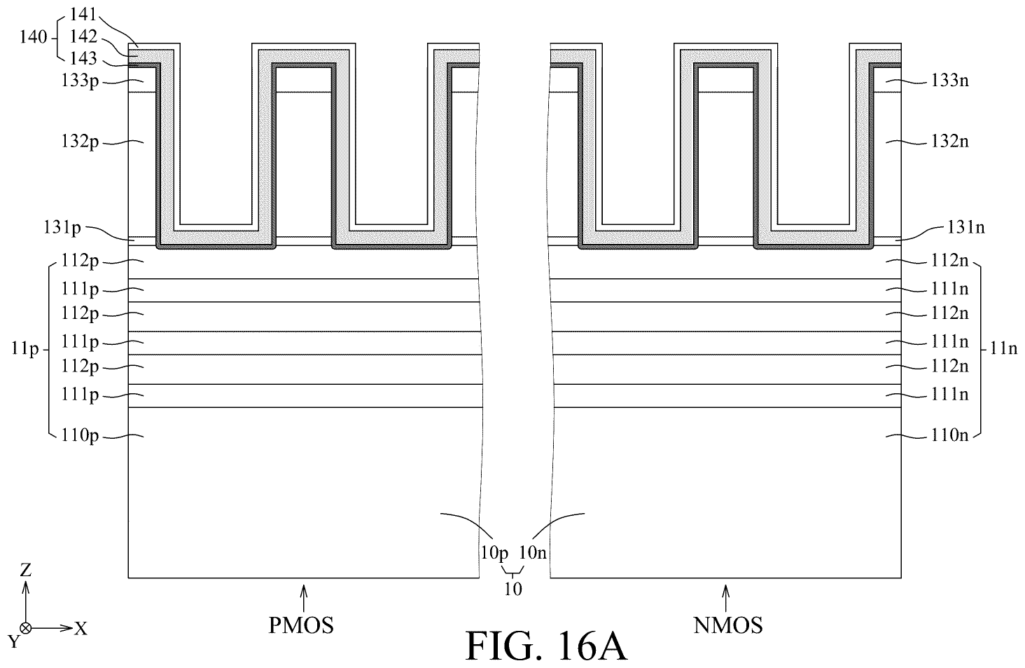

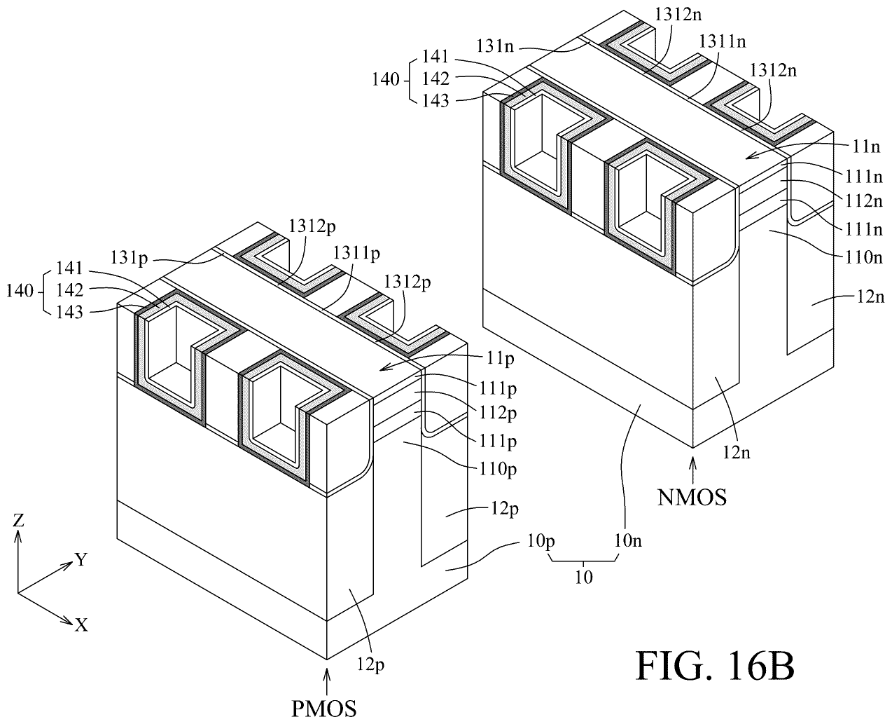

FIGS. 16A to 32 illustrate schematic views of intermediate stages of the method 2 in accordance with some embodiments. FIG. 31A is a schematic sectional view illustrating the device structures 200p, 200n in accordance with some embodiments. FIG. 31B is a fragmentary perspective view illustrating portions of device structures 200p, 200n in the semiconductor structure 200 in accordance with some embodiments. The schematic sectional views of the device structures 200p, 200n shown in FIG. 31A are respectively taken along lines B1-B1′ and B2-B2′ of FIG. 31B, and further illustrate the components that are omitted in FIG. 31B. In other words, the fragmentary perspective view shown in FIG. 31B merely illustrates the components of the device structures 200p, 200n positioned below dotted line B3-B3′ of FIG. 31A, but omitting the components of the device structures 200p, 200n positioned above dotted line B3-B3′ of FIG. 31A.

FIGS. 16A, 17A, 18A, 19A, 20A, 21A, 22A, 23A, 24A, 25A, 26A, 27A, 28A, 29A, and 30A are each a schematic sectional view similar to that of FIG. 31A, and FIGS. 16B, 17B, 18B, 19B, 20B, 21B, 22B, 23B, 24B, 25B, 26B, 27B, 28B, 29B, and 30B are each a schematic perspective view similar to that of FIG. 31B, but illustrating formation of the device structures 200p, 200n at different intermediate stages of the method 2.

Embodiments with regard to formation of the pairs of first clearances 26p, 26n and the pairs of air spacers 27p, 27n are described in the following.

In step S201, referring to the examples illustrated in FIGS. 16A and 16B, the spacer layer 140 further includes a bottom sub-layer 143 which is formed between the inner sub-layer 142 and the intermediate structure described in step S101.

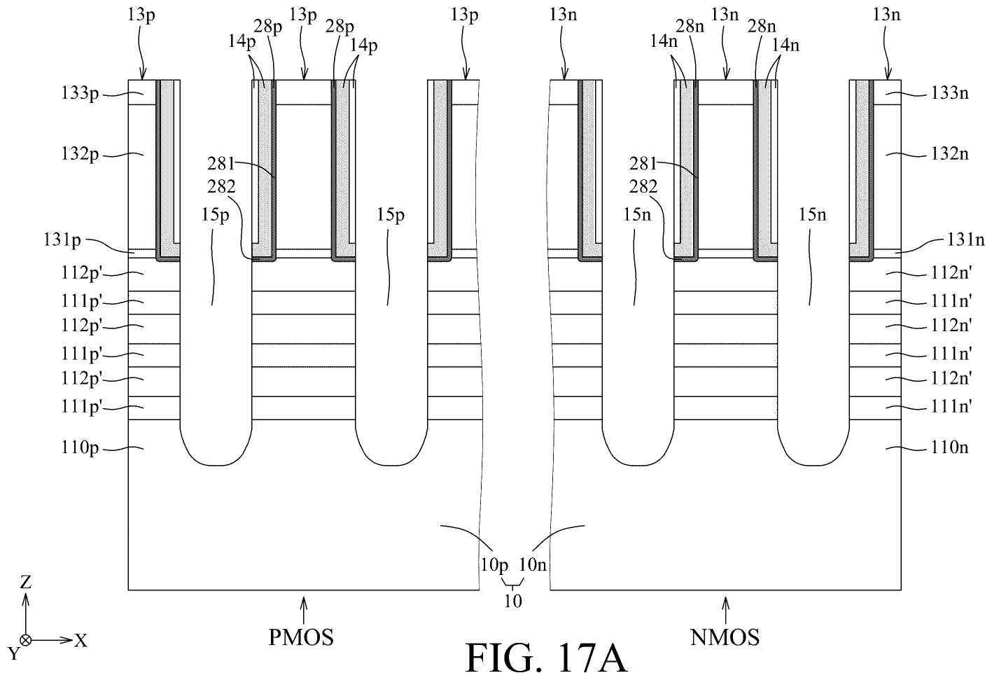

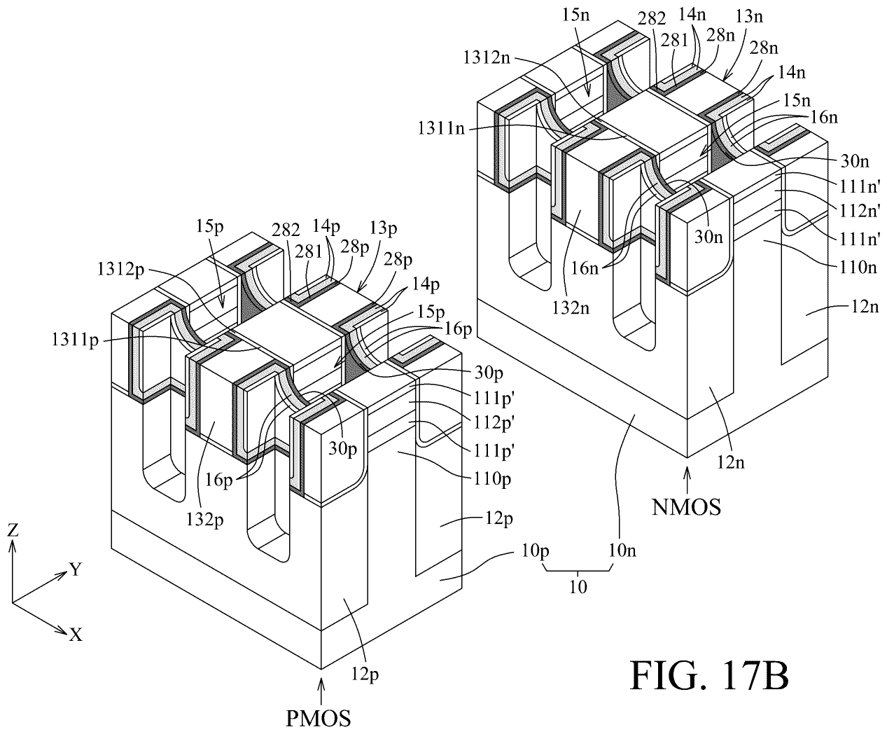

In step S202, referring to the examples illustrated in FIGS. 17A and 17B, the outer and inner sub-layers 141, 142 (see FIGS. 16A and 16B) are formed into the pairs of gate spacers 14p, 14n and the pairs of fin spacers 16p, 16n, and the bottom sub-layer 143 (see FIGS. 16A and 16B) is formed into pairs of first intermediate layers 28p, 28n and pairs of second intermediate layers 30p, 30n.

Each pair of the first intermediate layers 28p, 28n are respectively located at the two opposite sides of a respective one of the dummy gates 132p, 132n in the X direction. Each of the first intermediate layers 28p, 28n has a main portion 281 which is disposed between one of the dummy gates 132p, 132n and a corresponding one of the gate spacers 14p, 14n, and an extending portion 282 disposed between the respective gate spacer 14p or 14n and a corresponding one of the first and second film stacks described in step S102. Accordingly, each of the dummy structures 13p, 13n further includes a respective one pair of the first intermediate layers 28p, 28n which are respectively disposed at the two opposite sides of the respective dummy gate 132p or 132n. In each of the dummy structures 13p, 13n, the respective pair of the gate spacers 14p or 14n are respectively disposed on the respective pair of the first intermediate layers 28p or 28n opposite to the respective dummy gate 132p or 132n.

Each pair of the second intermediate layers 30p, 30n are formed at the two opposite sides of a respective one of the exposed portions of the fin structures 11p, 11n in the Y direction. In some embodiments, each pair of the fin spacers 16p, 16n are disposed on a respective pair of the second intermediate layers 30p, 30n opposite to the respective one of the second portions 1312p, 1312n of the dummy dielectric layers 131p, 131n.

In some embodiments, the bottom sub-layer 143 formed in step S201 (see FIGS. 16A and 16B) has a thickness of at least about 2 nm. In some embodiments, the thickness of the bottom sub-layer 143 ranges from about 2 nm to about 5 nm. When the thickness of the bottom sub-layer 143 is less than about 2 nm, the pairs of first intermediate layers 28p, 28n may not be removed or be completely removed in step S212 to form the pairs of first clearances 26p, 26n (see FIGS. 31A and 31B). When the thickness of the bottom sub-layer 143 is too large (e.g., greater than about 5 nm), it may be not beneficial to the size miniaturization of the transistors.

The bottom sub-layer 143 (for forming the first intermediate layers 28p, 28n and the second intermediate layers 30p, 30n) is made of a dielectric material that is different from the dielectric material of the outer and inner sub-layers 141, 142 (for forming the gate spacers 14p, 14n and the fin spacers 16p, 16n) and that is also different from the dielectric material of the gate dielectric 251 of each of the gate structures 25p, 25n. As such, in a subsequent step, the first intermediate layers 28p, 28n and the second intermediate layers 30p, 30n are able to be selectively removed while the gate spacers 14p, 14n, the fin spacers 16p, 16n and the gate dielectric 251 of each of the gate structures 25p, 25n are substantially intact due to different etching selectivity ratios. In some embodiments, possible dielectric materials suitable for the bottom sub-layer 143 include silicon oxide, silicon oxycarbide, silicon oxynitride, silicon oxycarbonitride, other suitable low-k dielectric materials, or combinations thereof.

Although the bottom sub-layer 143 and the outer and inner sub-layers 141, 142 may include the same kinds of atoms (for example, but not limited to, the sub-layers 141, 142, 143 each includes silicon, oxygen, carbon, and nitrogen elements) in accordance with some embodiments. The bottom sub-layer 143 is considered to be different from the dielectric material of the outer and inner sub-layers 141, 142 as long as the dielectric materials of the sub-layers 141, 142, 143 have different proportions of the silicon, oxygen, carbon, and nitrogen elements.

During formation of the source/drain recesses 15p, 15n, the pairs of second intermediate layers 30p, 30n are also etched to have a reduced height in the Z direction.

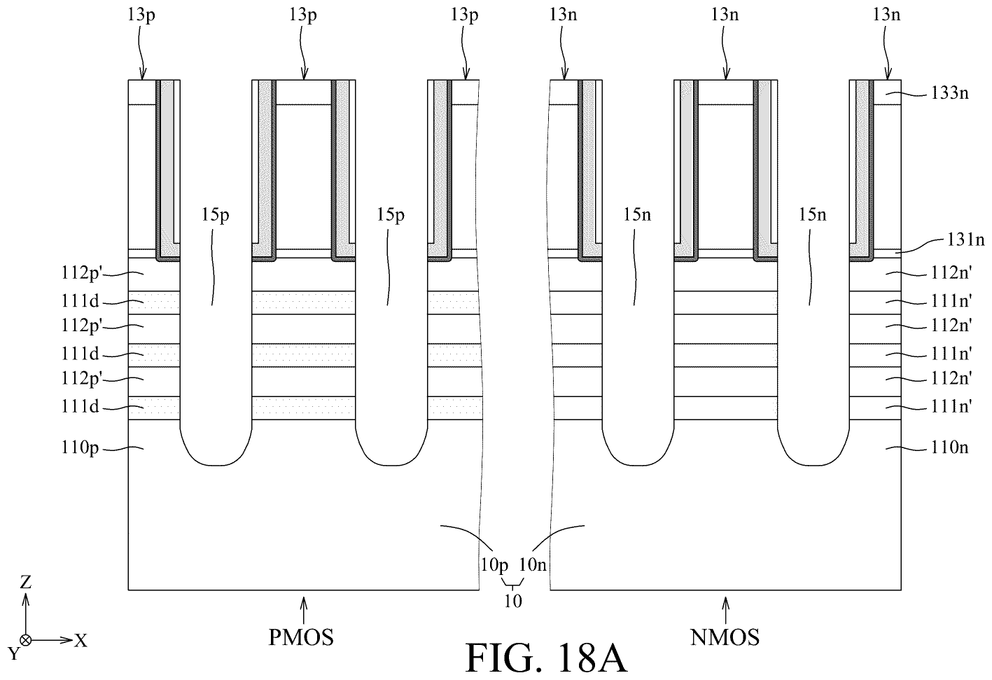

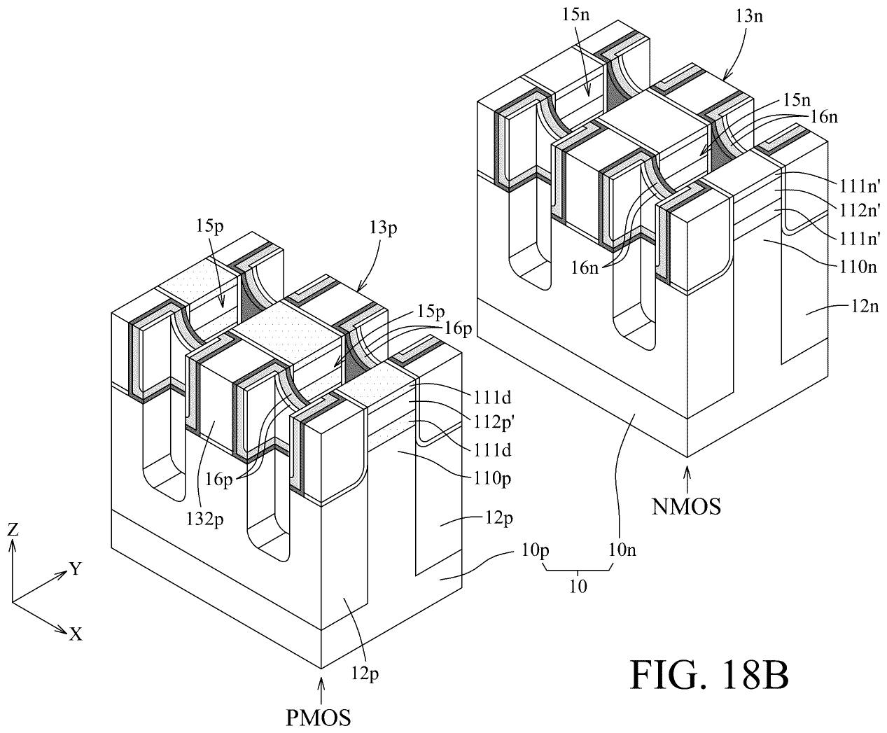

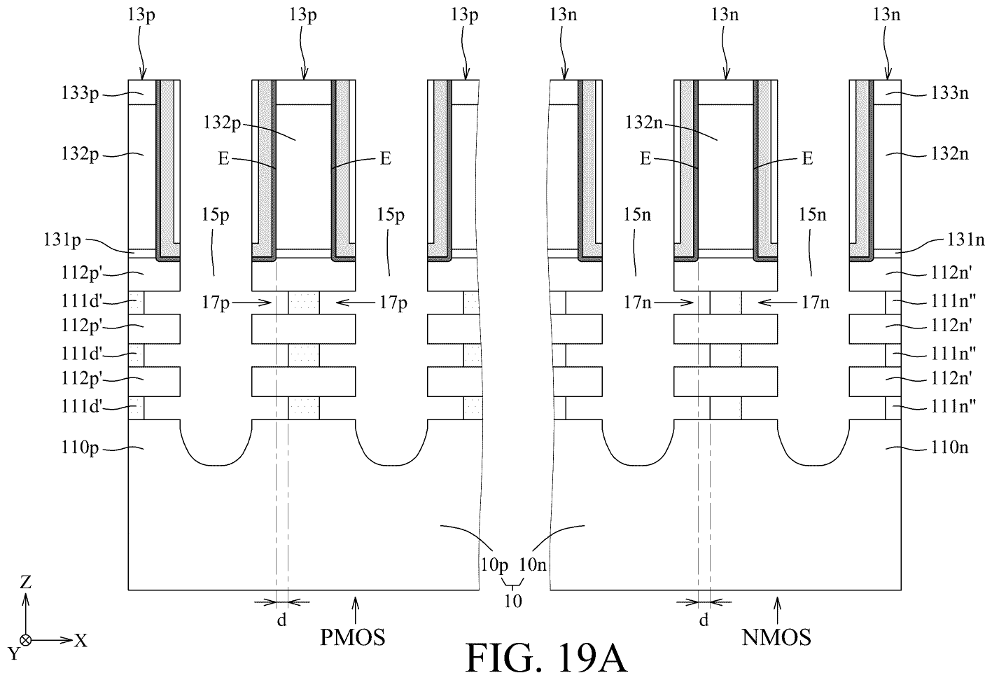

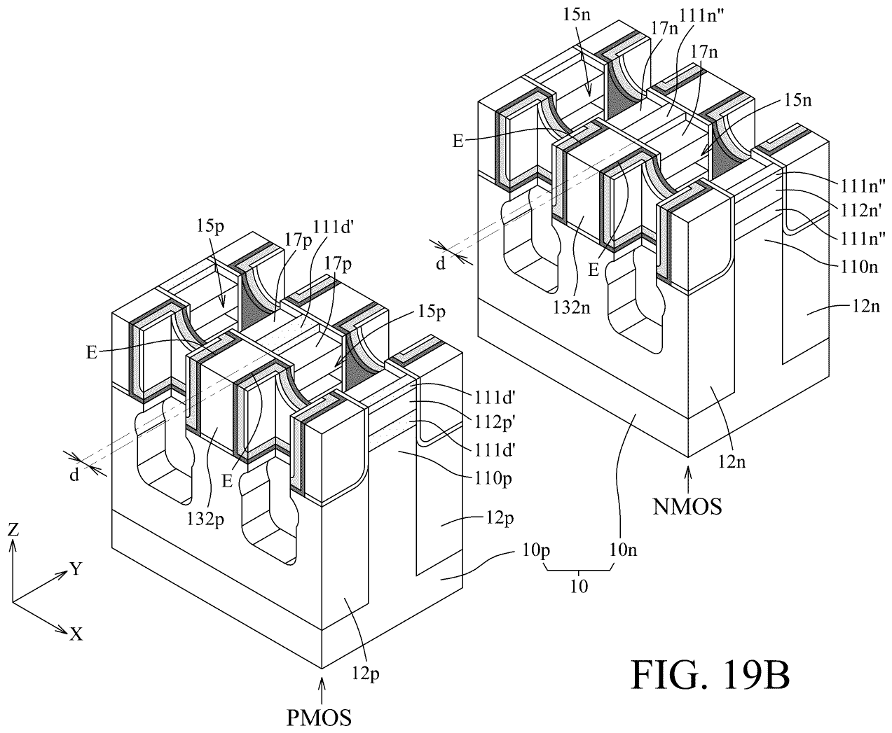

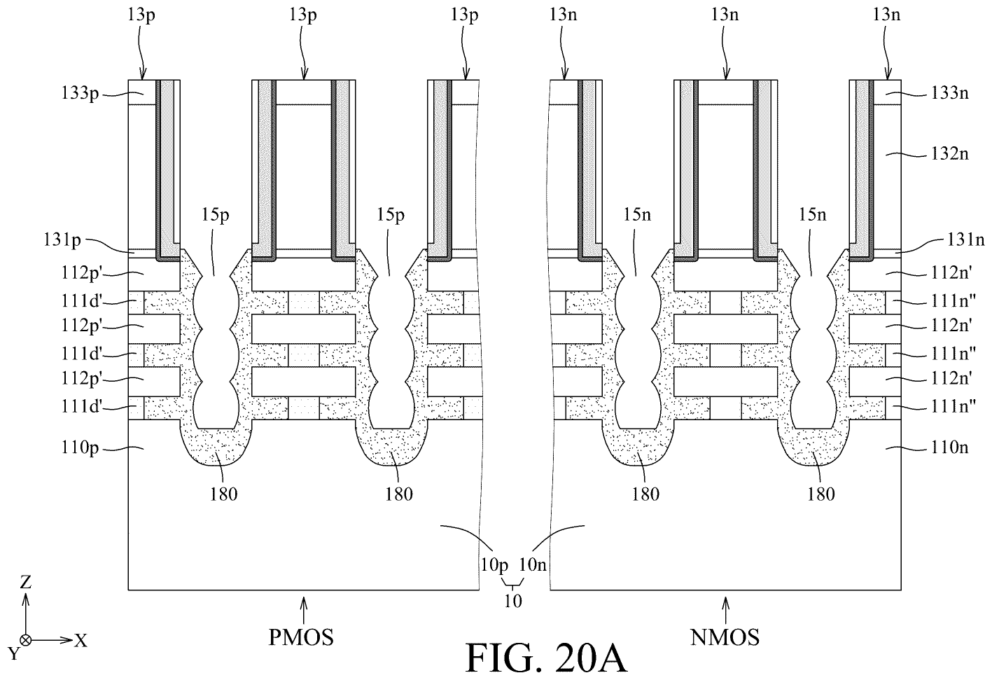

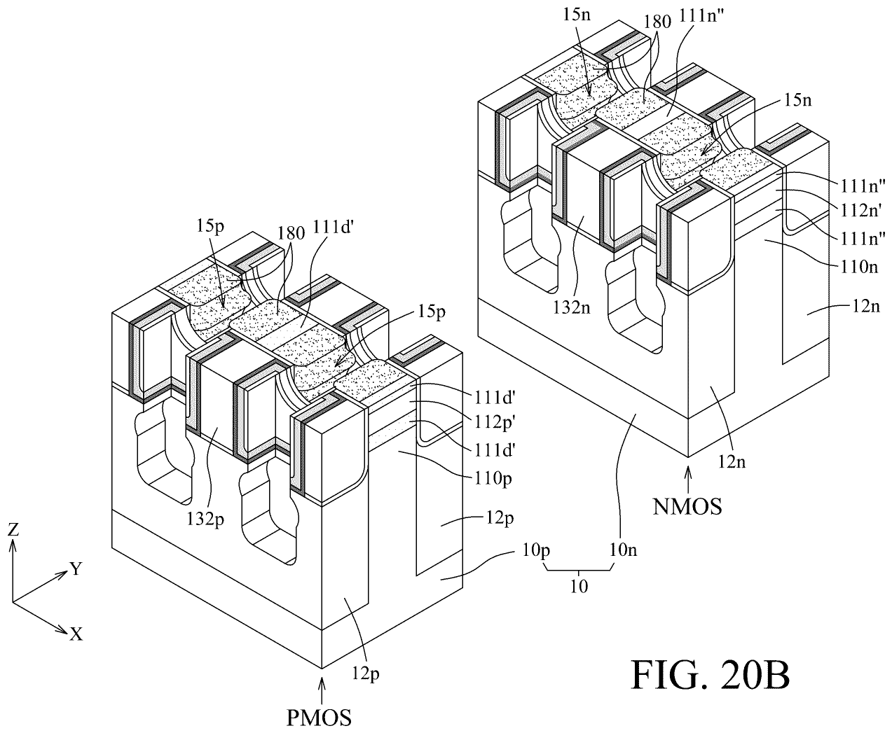

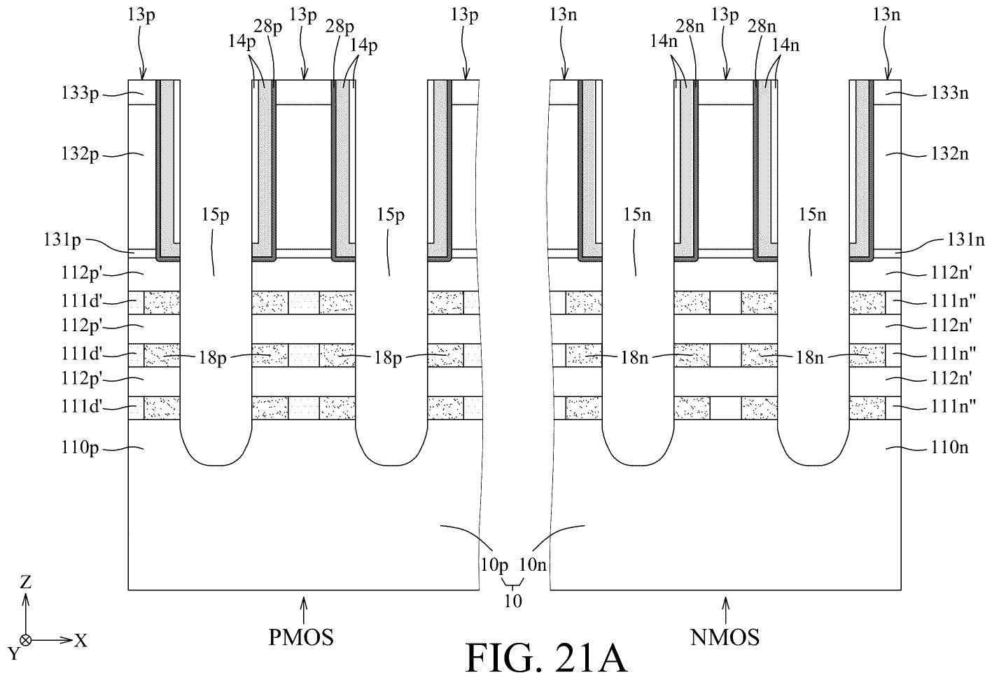

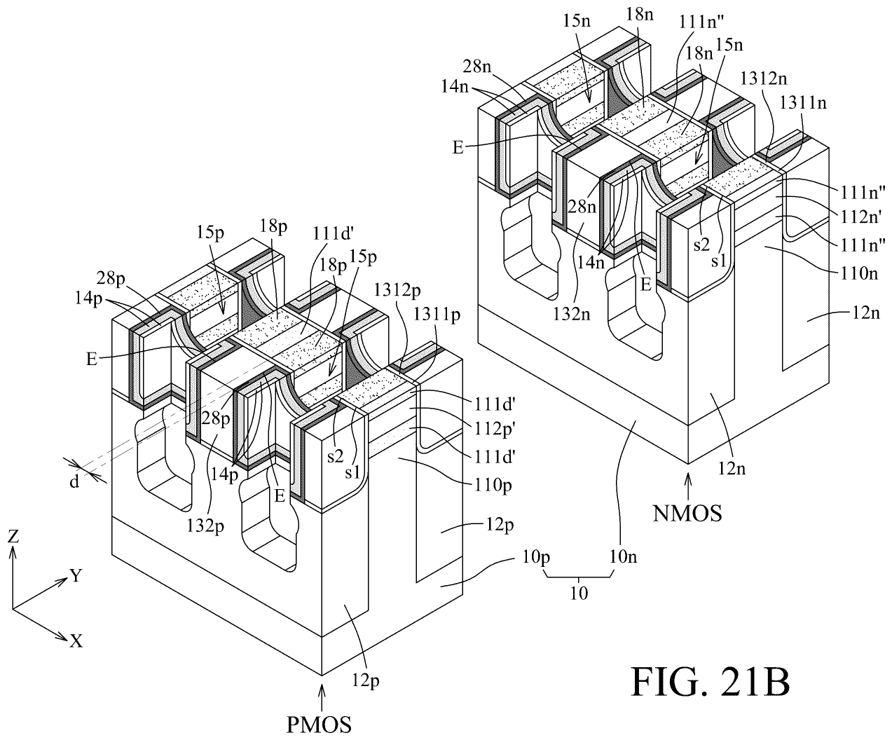

Step S203 (the examples illustrated in FIGS. 18A and 18B), step S204 (the examples illustrated in FIGS. 19A and 19B), and step S205 (the examples illustrated in FIGS. 20A and 20B and the examples illustrated in FIGS. 21A and 21B) are respectively similar to steps S103, S104, S105 of the method 1, and thus the same details thereof are not repeated for the sake of brevity.

It is noted that, as shown in FIG. 21B, as to each of the two side surfaces of each of the semiconductor spacers 18p, 18n, the first region s1 is covered by the corresponding first portion 1311p or 1311n and the corresponding dummy gate 132p or 132n, and the second region s2 is covered by the corresponding end part 1312p or 1312n and a corresponding one of the first intermediate layers 28p, 28n.

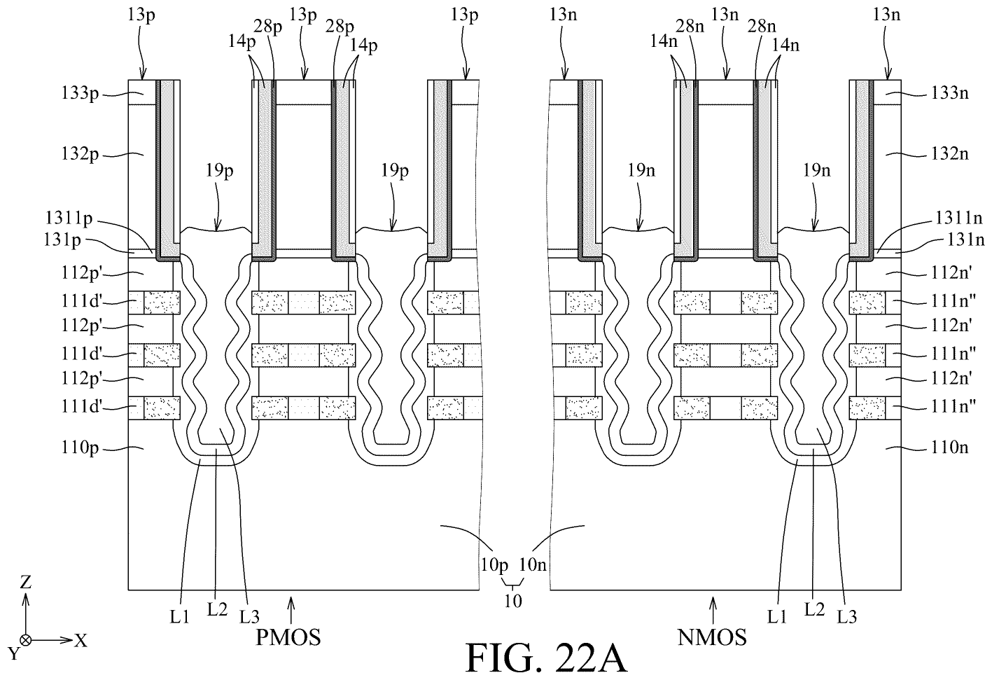

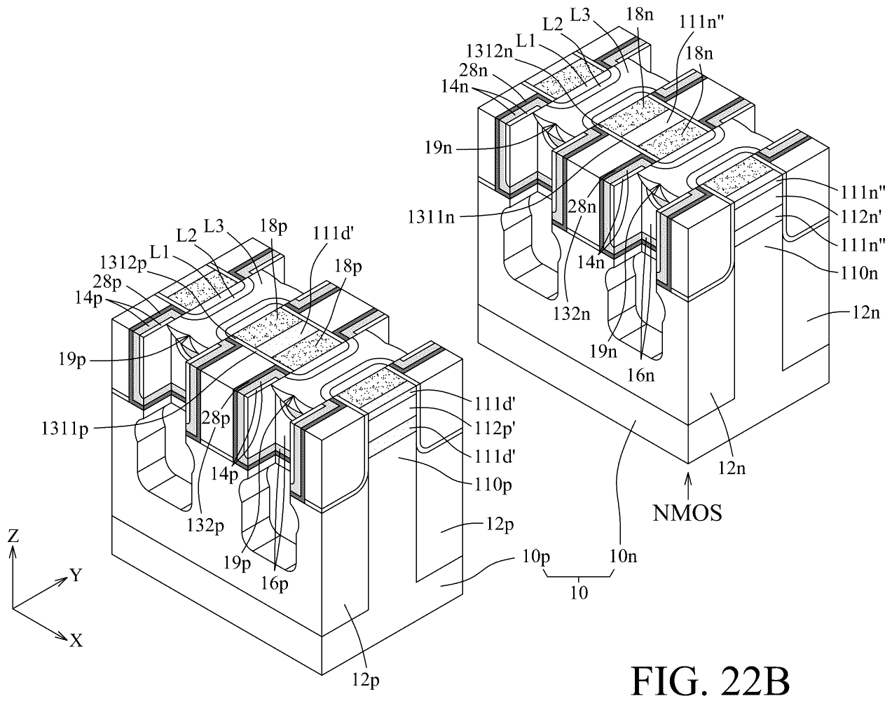

Step S206 (the examples illustrated in FIGS. 22A and 22B) is similar to step S106 of the method 1, and thus the same details thereof are not repeated for the sake of brevity.

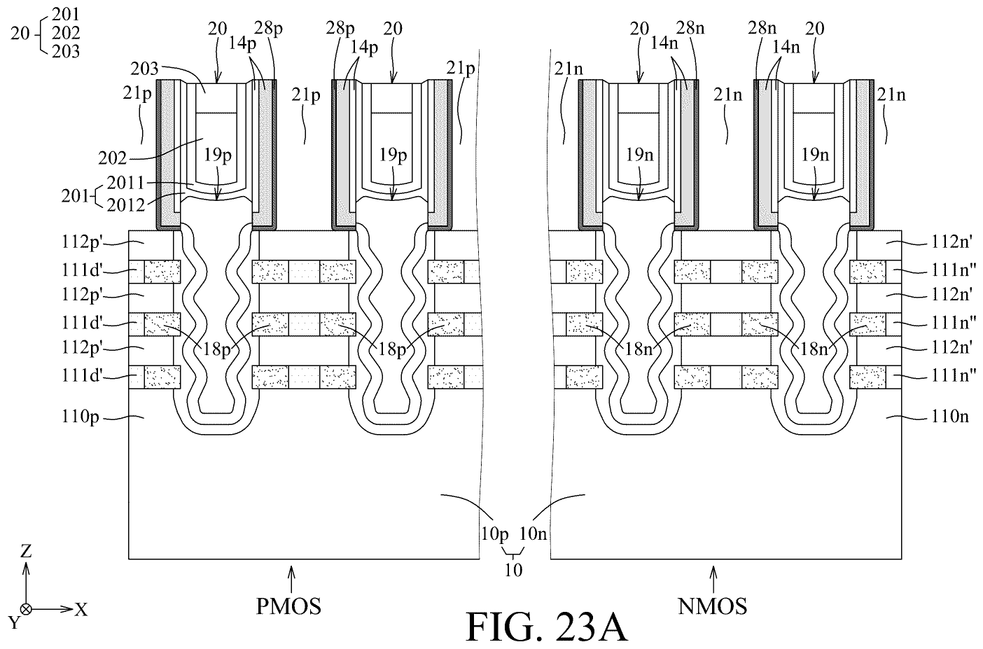

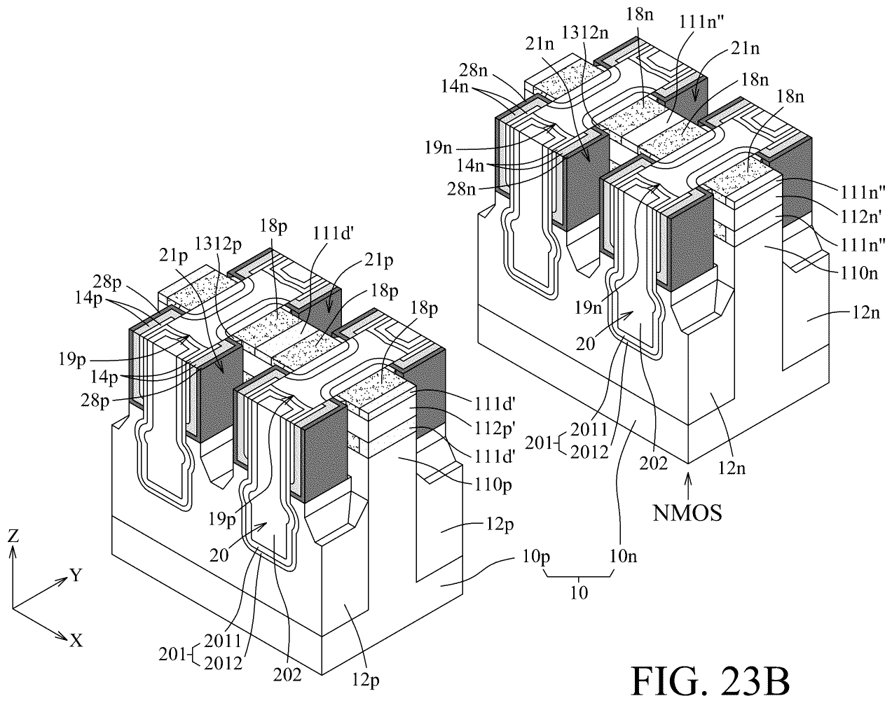

In step S207, referring to the examples illustrated in FIGS. 23A and 23B, each of the cavities 21p, 21n thus obtained is located between a respective pair of the first intermediate layers 28p, 28n. Referring to FIG. 23B, the first region s1 of each of the two side surfaces of each of the semiconductor spacers 18p, 18n is exposed to a corresponding one of the cavities 21p, 21n, so that etchant(s) used in the next step (e.g., step S208) are accessible to the semiconductor spacers 18p, 18n so as to permit the semiconductor spacers 18p, 18n to be removed in step S208.

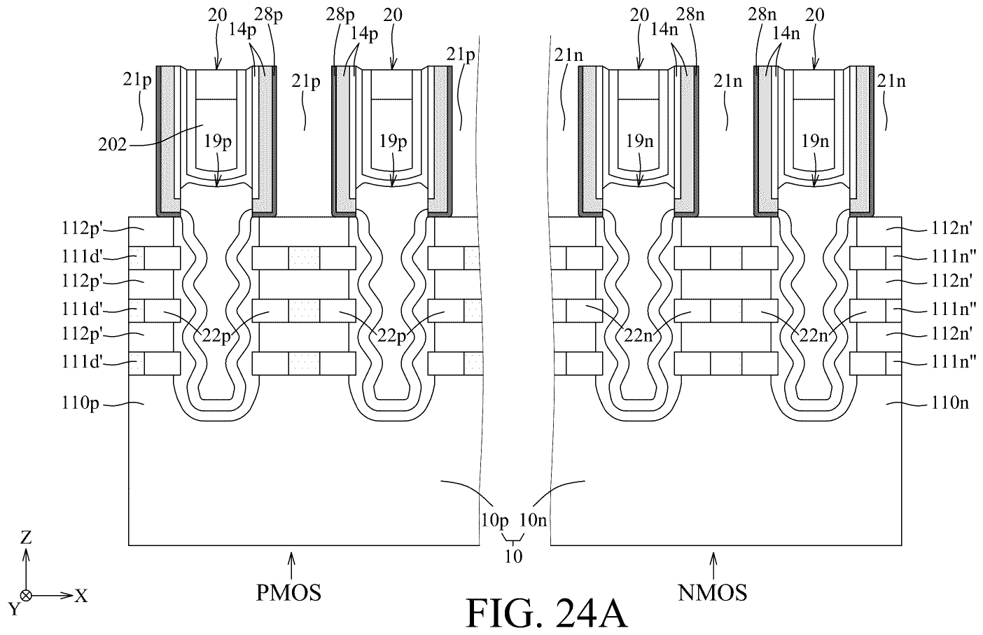

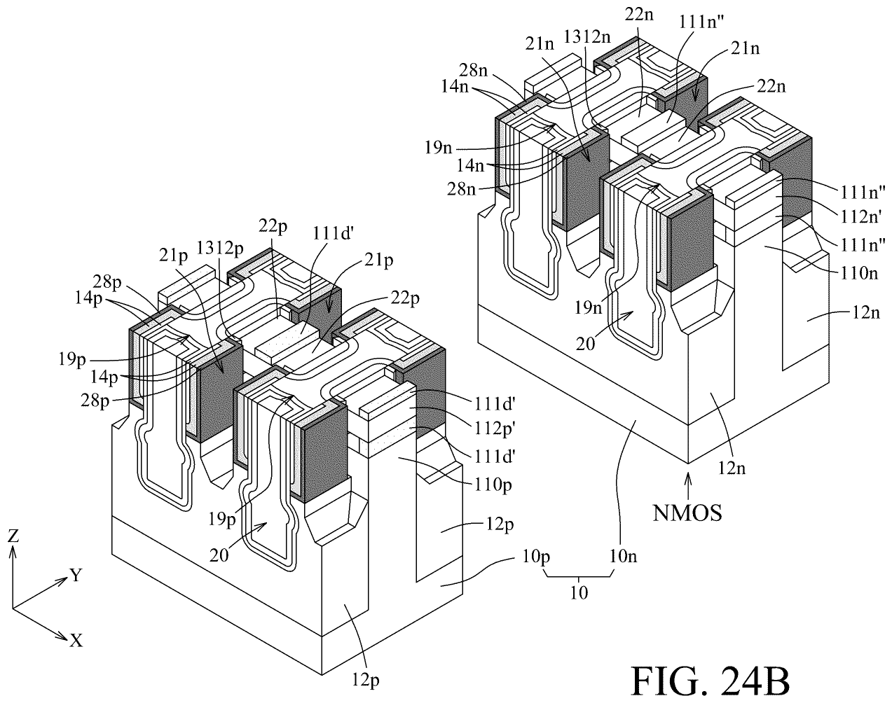

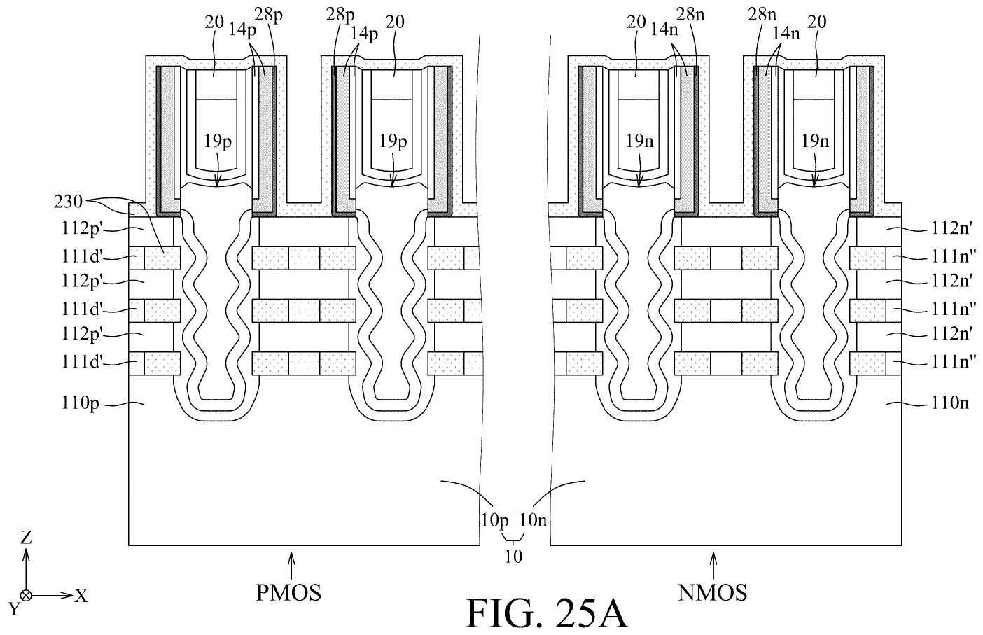

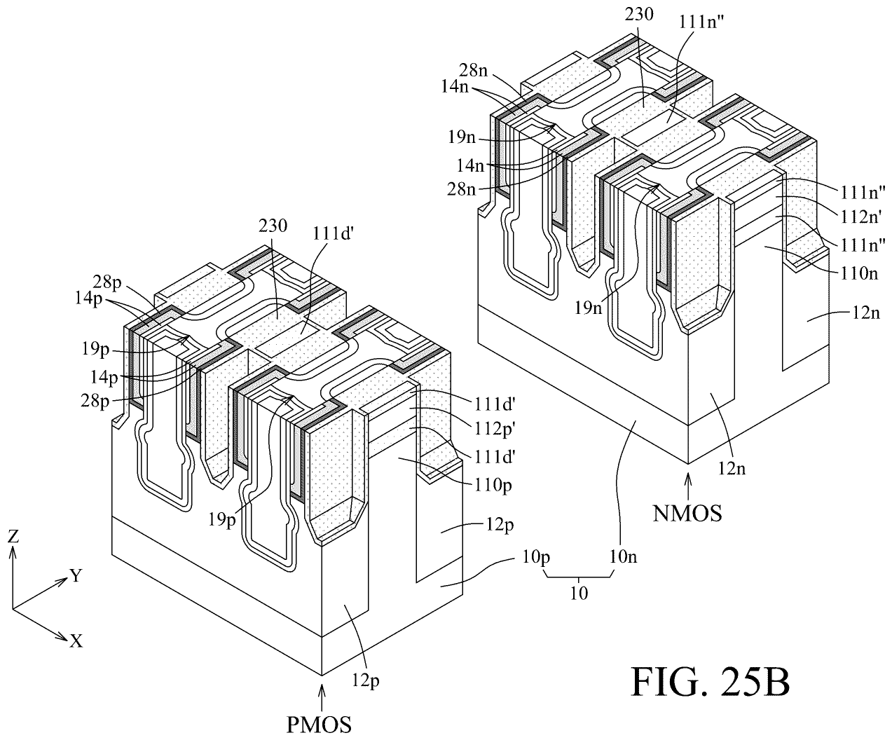

In step S208, referring to the examples illustrated in FIGS. 24A and 24B, in some embodiments, the end parts 1312p, 1312n (i.e., the remaining second portions) will be removed by an etching process before proceeding to the next step (i.e., step S209). In other words, the end parts 1312p, 1312n shown in FIG. 24B are removed in FIG. 25B.

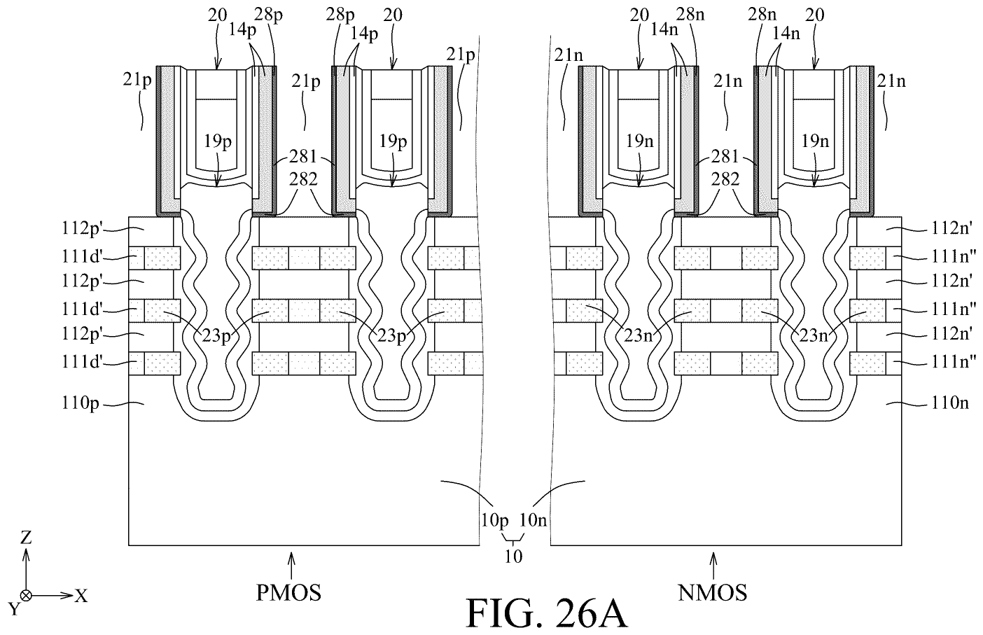

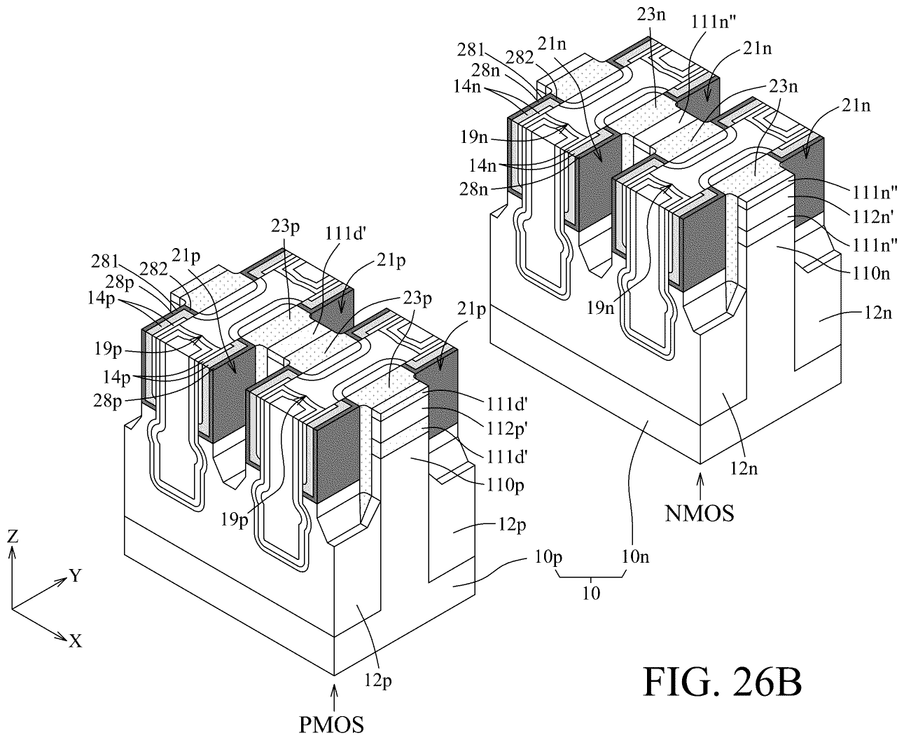

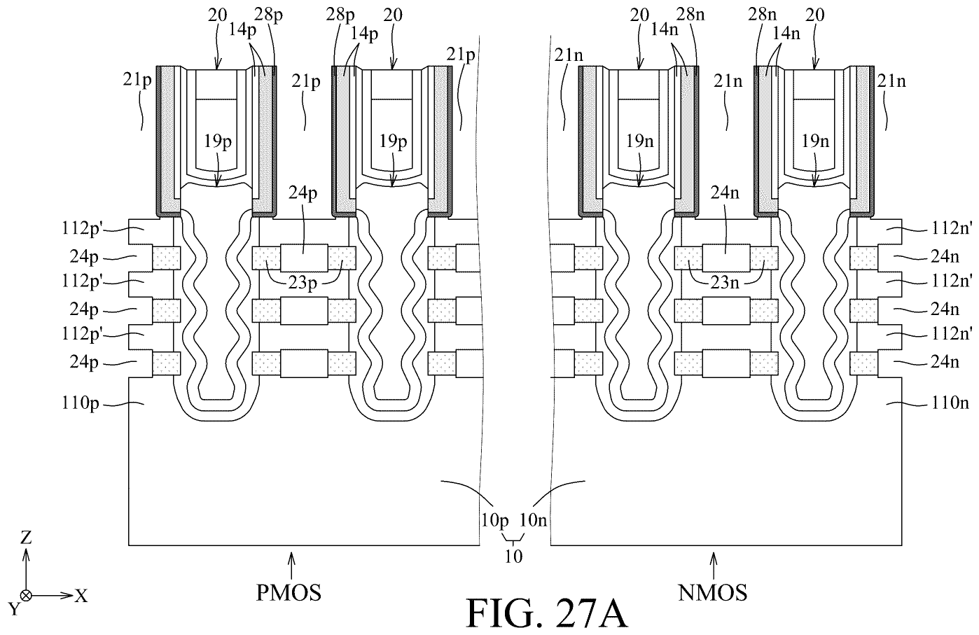

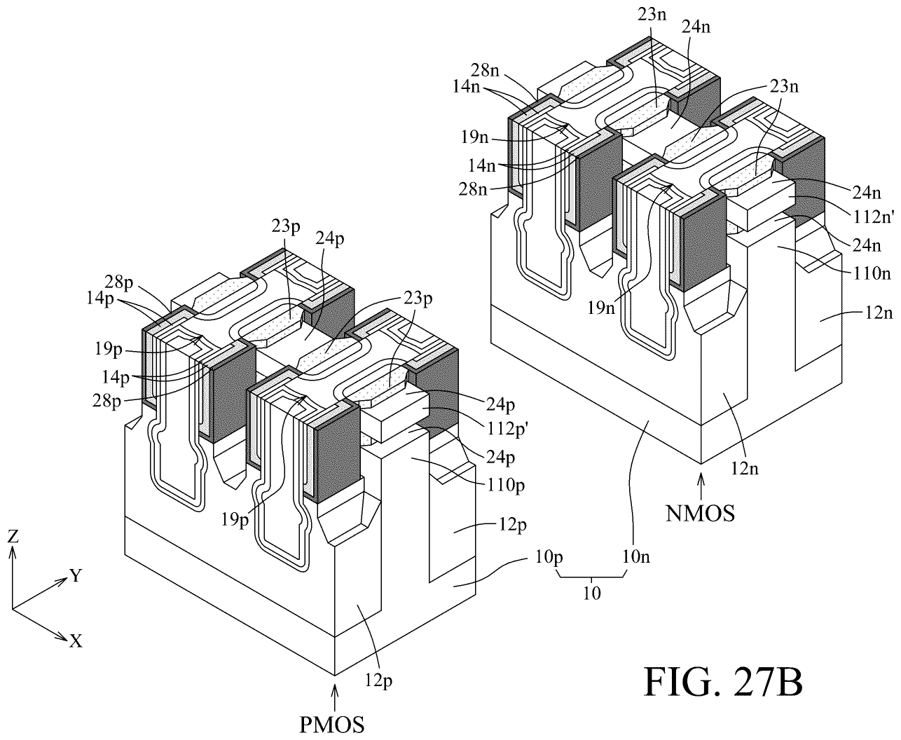

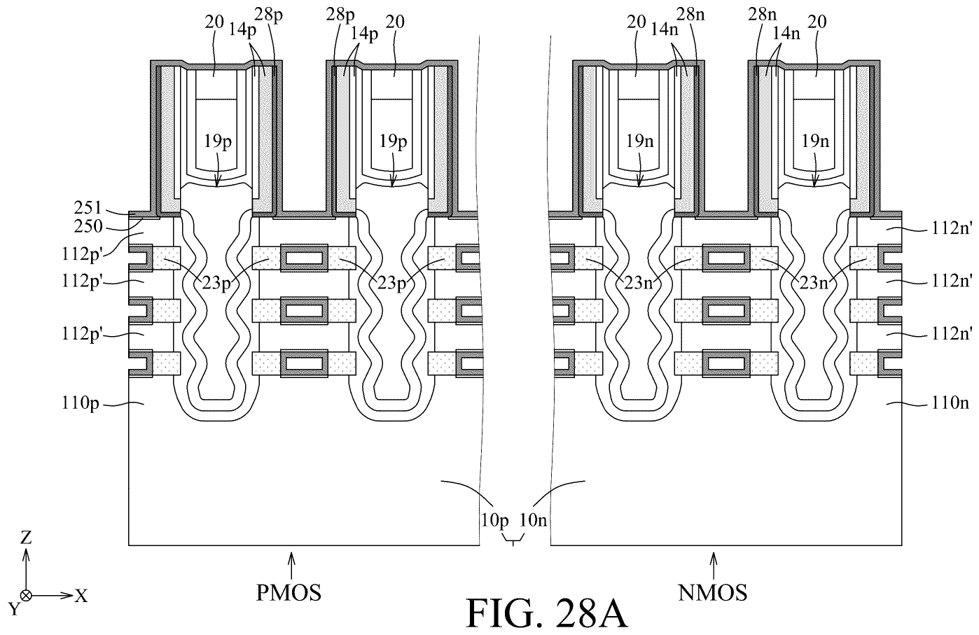

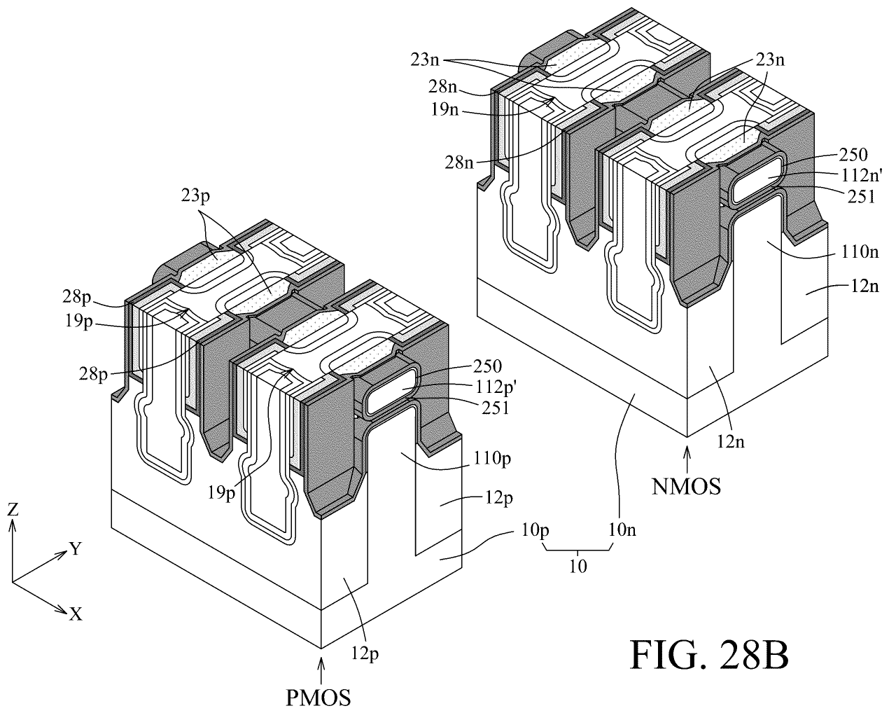

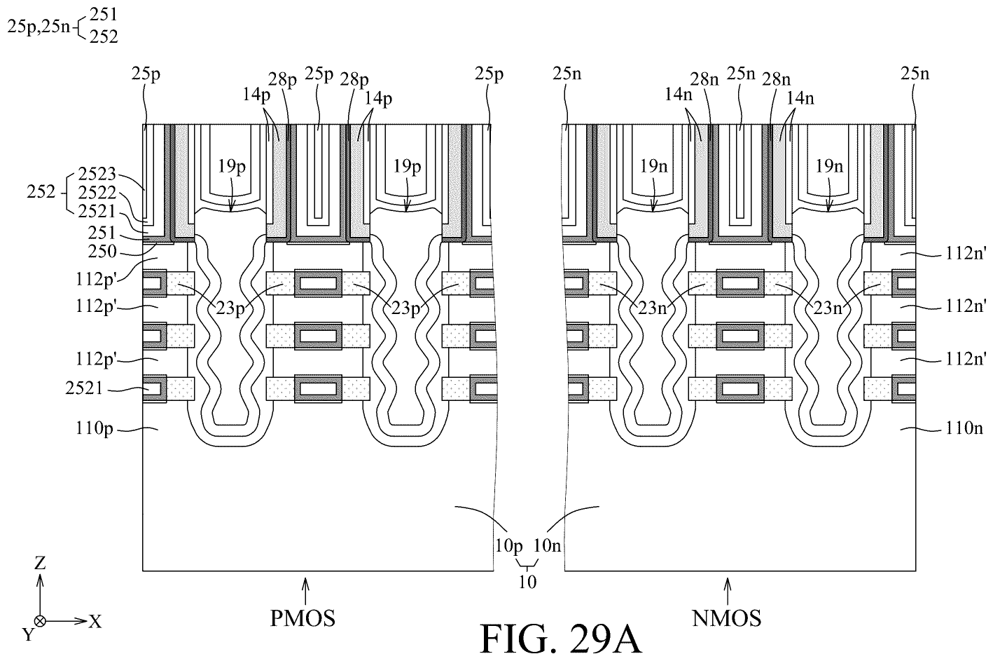

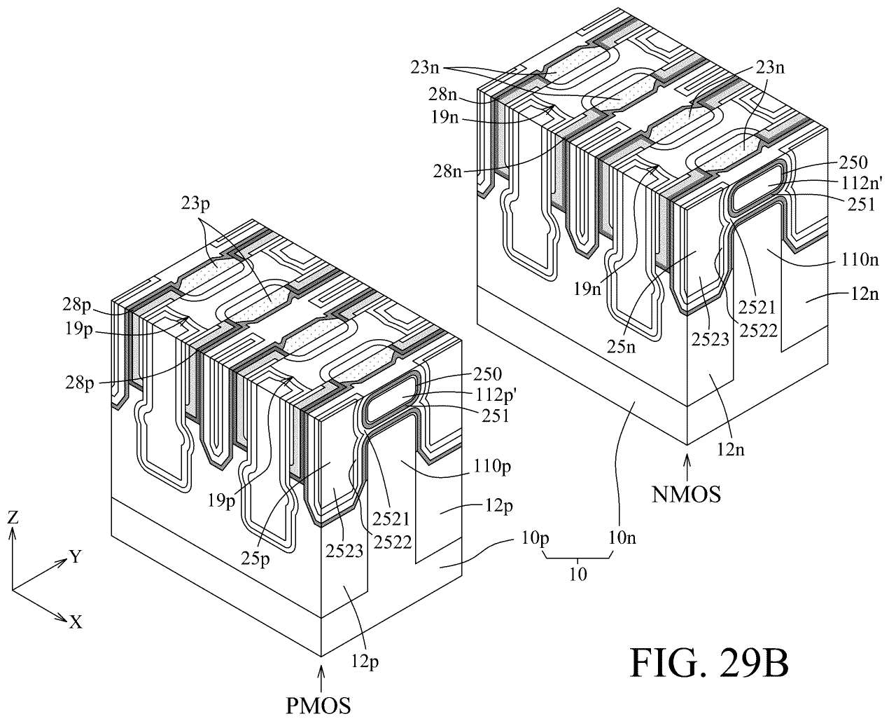

Step S209 (the examples illustrated in FIGS. 25A and 25B and the examples illustrated in FIGS. 26A and 26B), step S210 (the examples illustrated in FIGS. 27A and 27B), step S211 (the examples illustrated in FIGS. 28A and 28B and the examples illustrated in FIGS. 29A and 29B) are respectively similar to steps S109, S110, S111 of the method 1, and thus the same details thereof are not repeated for the sake of brevity.

It is noted that, as shown in FIG. 26B, each of the dielectric spacers 23p, 23n is in direct contact with the extending portion 282 of a corresponding one of the first intermediate layers 28p, 28n.

In step S211, referring to the examples illustrated in FIGS. 29A and 29B, the number of the sub-layers 2521, 2522, 2523 of the gate electrode 252 of each of the gate structures 25p, 25n is exemplarily shown as three, but is not limited thereto.

FIGS. 28A and 28B illustrate one possible intermediate state in step S211 in accordance with some embodiments, where the interfacial layers 250 and the gate dielectric 251 of each of the gate structures 25p, 25n are formed.

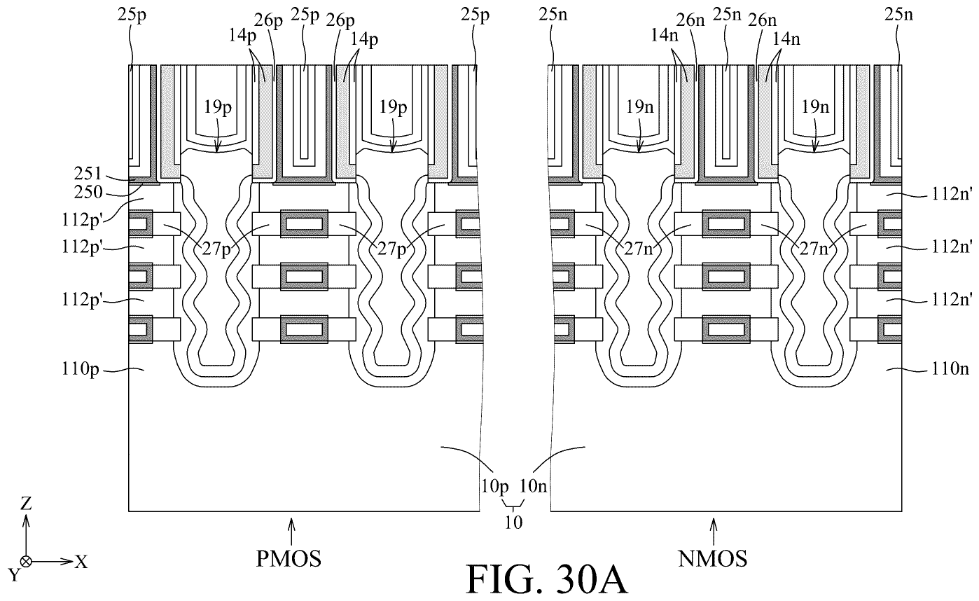

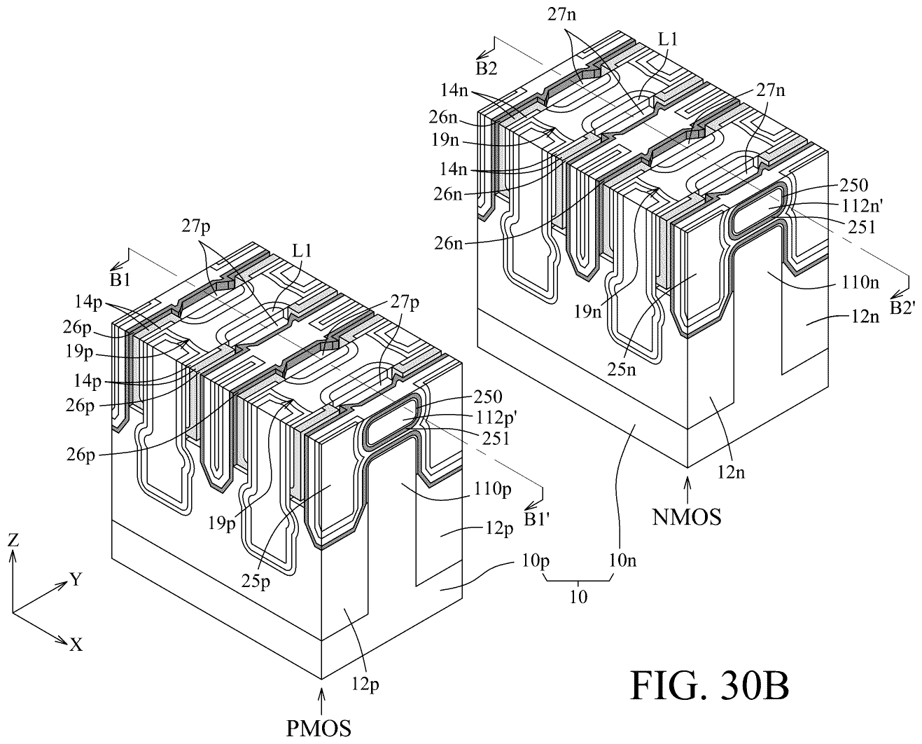

In step S212, referring to the examples illustrated in FIGS. 30A and 30B, the pairs of first clearances 26p, 26n are formed by removing the pairs of first intermediate layers 28p, 28n (see FIGS. 29A and 29B), thereby exposing the pairs of dielectric spacers 23p, 23n (see FIGS. 29A and 29B). Then, the pairs of dielectric spacers 23p, 23n are removed to form the pairs of air spacers 27p, 27n, respectively.

It is noted that the pairs of second intermediate layers 30p, 30n (see FIG. 17B) are also removed along with the removal of the pairs of first intermediate layers 28p, 28n to form second clearances (not shown). Each of the second clearances is located between one of the fin spacers 16p, 16n and a corresponding adjacent one of the source/drain portions 19p, 19n.

The pairs of first intermediate layers 28p, 28n and the pairs of dielectric spacers 23p, 23n are removed by a selective etching process with the use of etchant(s) having a relatively high etching selectivity to the first intermediate layers 28p, 28n and the dielectric spacers 23p, 23n, and thus the elements other than the elements 28p, 28n, 23p, 23n are substantially intact.

In some embodiments, each of the gate structures 25p, 25n has a left side and a right side opposite to the left side in the X direction, and each pair of the gate spacers 14p, 14n are respectively located at the left and right sides of the corresponding one of the gate structures 25p, 25n. Each pair of the first clearances 26p, 26n includes a left clearance and a right clearance which are respectively at the left and right sides of the corresponding one of the gate structures 25p, 25n. In the same stack of the channel films 112p′ or 112n′, the pairs of the air spacers 27p or 27n are grouped into left air spacers and right air spacers. To be specific, in the same stack of the channel films 112p′ or 112n′, the left clearance is located between the left side of the corresponding gate structure 25p or 25n and a left one of the corresponding pair of the gate spacers 14p or 14n to be in spatial communication with the left air spacers 27p or 27n, and the right clearance is located between the right side of the corresponding gate structure 25p or 25n and a right one of the corresponding pair of the gate spacers 14p or 14n to be in spatial communication with the right air spacers 27p or 27n. In the same stack of the channel films 112p′ or 112n′, the second left inner spacers (i.e., the left ones of the dielectric spacers 23p or 23n) formed in step S209 (similar to step S109) are removed through the left clearance, and the second right inner spacers (the right ones of the dielectric spacers 23p or 23n) are removed through the right clearance.

In step S213, referring to the examples illustrated in FIGS. 31A and 31B, a treatment is performed to seal an end of each of the first clearances 26p or 26n, so that the pairs of first clearances 26p or 26n, the pairs of second clearances (not shown), and the pairs of air spacers 27p, 27n are prevented from being refilled in subsequent processes. In some embodiments, the treatment is performed by implanting an upper portion of each of the gate spacers 14p, 14n, such that the upper portion of each of the gate spacers 14p, 14n is caused to expand in volume and is brought into contact with a corresponding adjacent one of the gate structures 25p, 25n. In some embodiments, species used to implant the upper portion of each of the gate spacers 14p, 14n includes xenon, germanium, other suitable elements, or combinations thereof.

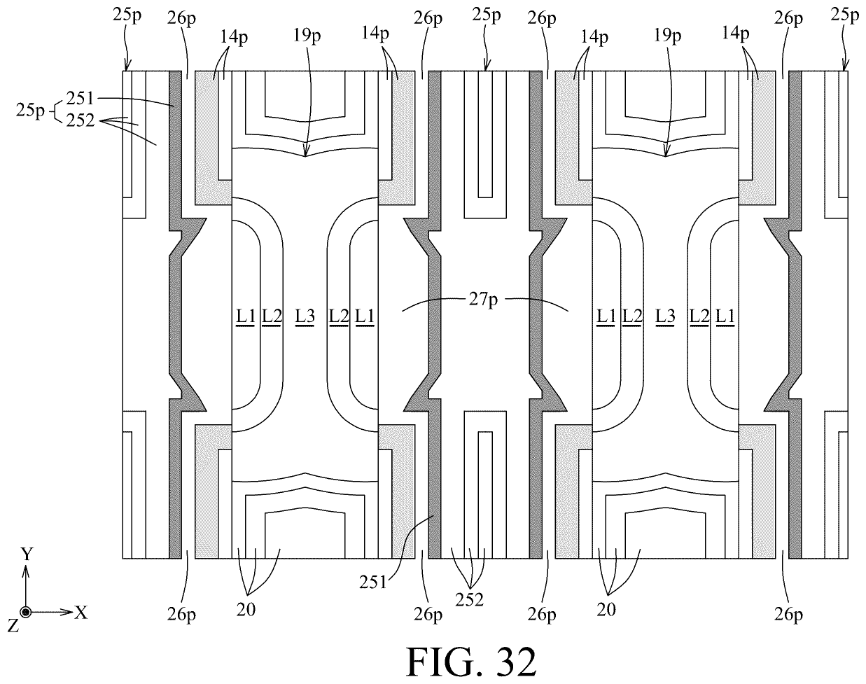

FIG. 32 is a cross-sectional view taken along line B3-B3′ of FIG. 31A in accordance with some embodiments but merely illustrating the device structure 200p shown in FIGS. 31A and 31B. Each of the air spacers 27p is in spatial communication with a corresponding one of the first clearances 26p. Although FIG. 32 merely illustrates the device structure 200p, the device structure 200n also has a similar structure shown in FIG. 32.

Due to the presence of the air spacers 27p, a parasitic capacitance generated between one of the gate structures 25p and a corresponding adjacent one of the source/drain portions 19p can be minimized. Similarly, with the provision of the air gaps 27n a parasitic capacitance generated between one of the gate structures 25n and a corresponding adjacent one of the source/drain portions 19n can be also minimized.

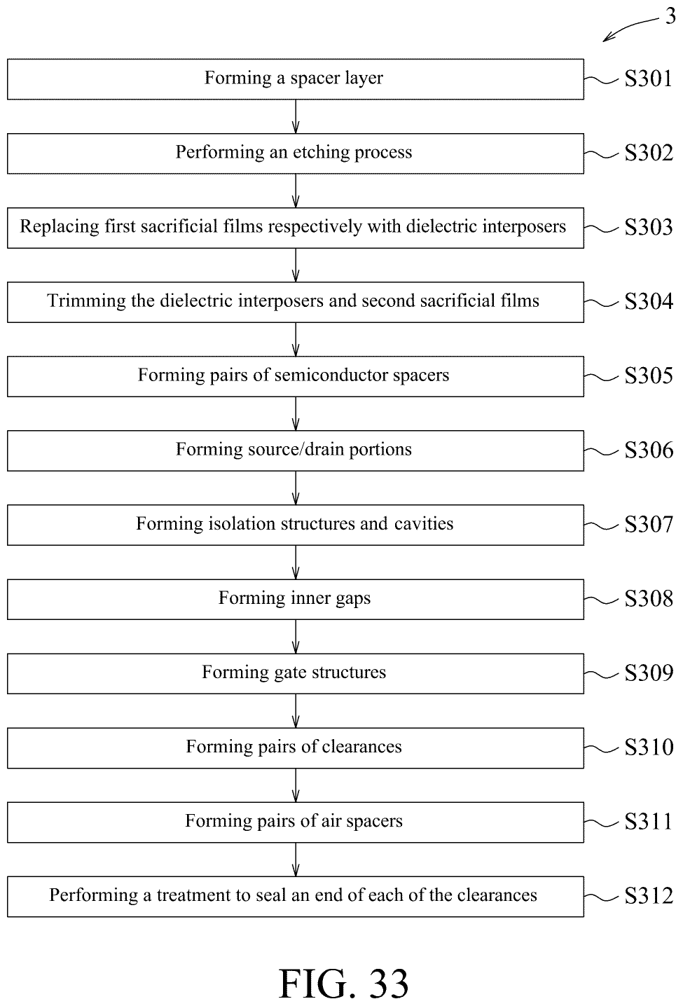

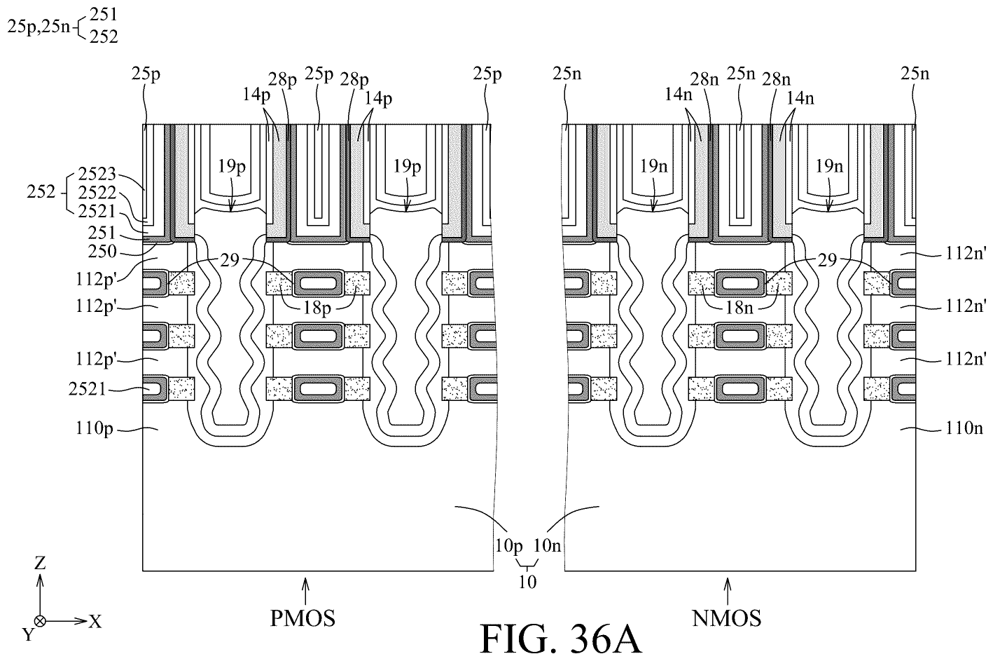

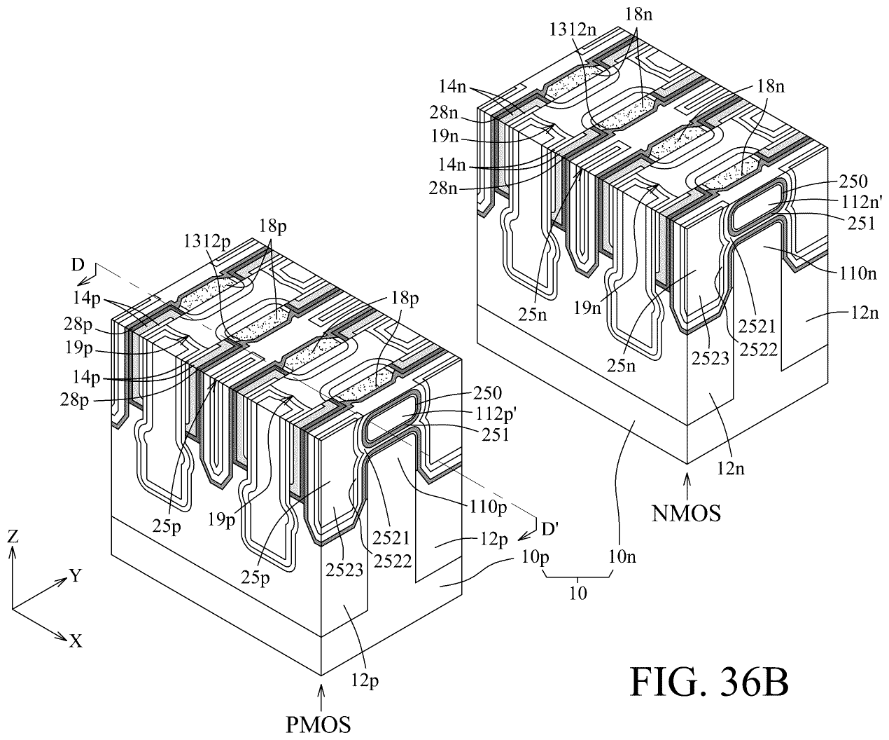

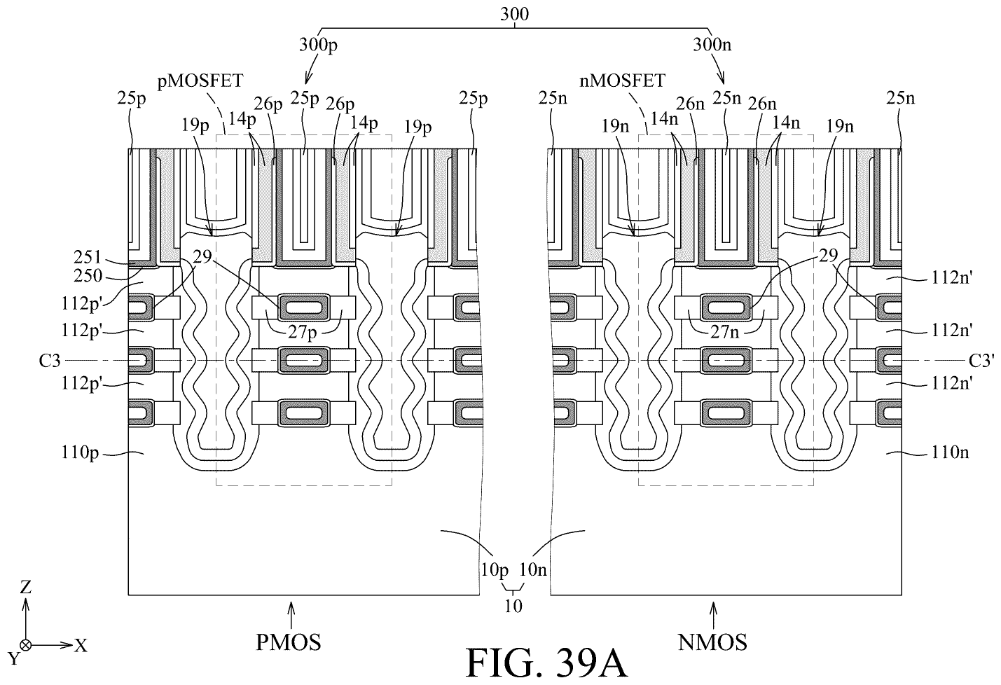

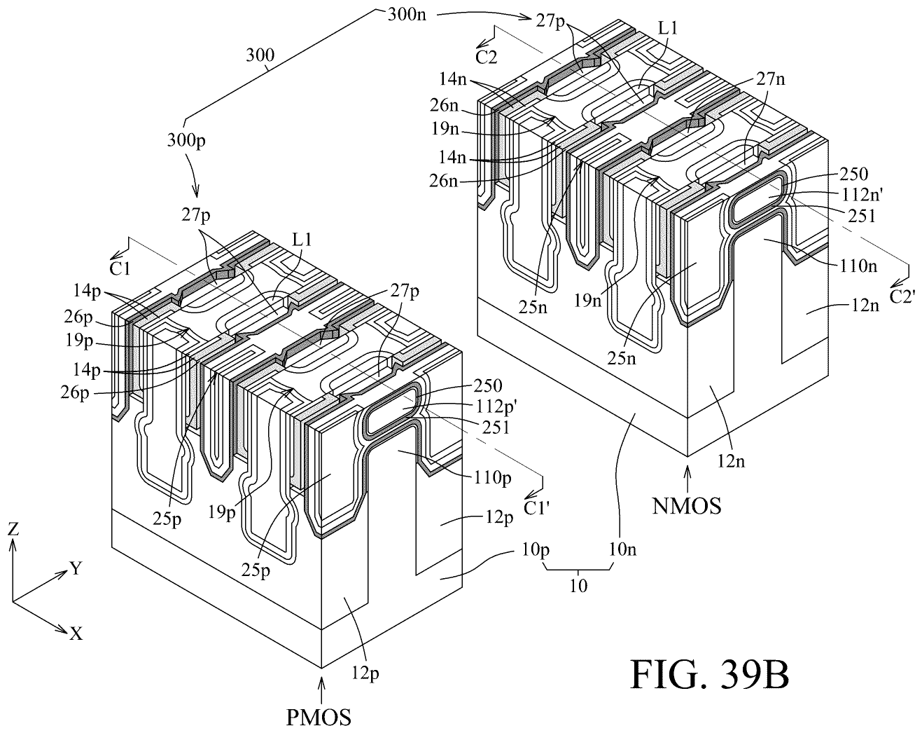

FIG. 33 is a flow diagram illustrating a method 3 for manufacturing a semiconductor structure (for example, but not limited to, a semiconductor structure 300 shown in FIGS. 39A and 39B) in accordance with some embodiments. The semiconductor structure 300 has a structure similar to that of the semiconductor structure 200 shown in FIGS. 31A and 31B, but has the differences in the following. As shown in FIG. 36A, during formation of the interfacial layers 250 respectively disposed on the channel films 112p′, 112n′, a surface portion of each of the semiconductor spacers 18p, 18n is oxidized to form a semiconductor oxide layer 29 at the same time. In some embodiments, when each of the semiconductor spacers 18p, 18n is made of silicon germanium, the semiconductor oxide layer 29 is made of silicon germanium oxide. After the removal of the semiconductor spacers 18p, 18n to form the air spacers 27p, 27n, as shown in FIG. 39A, the semiconductor oxide layer 29 is disposed between the gate dielectric 251 of one of the gate structures 25p, 25n and a corresponding one of the air spacers 27p, 27n.

The method 3 may include steps S301 to S312, in which steps S301 to S307 are respectively similar to steps S201 to S207 of the method 2, and thus the details thereof are omitted for the sake of brevity, whereas the details of steps S308 to S312 will be described in the following.

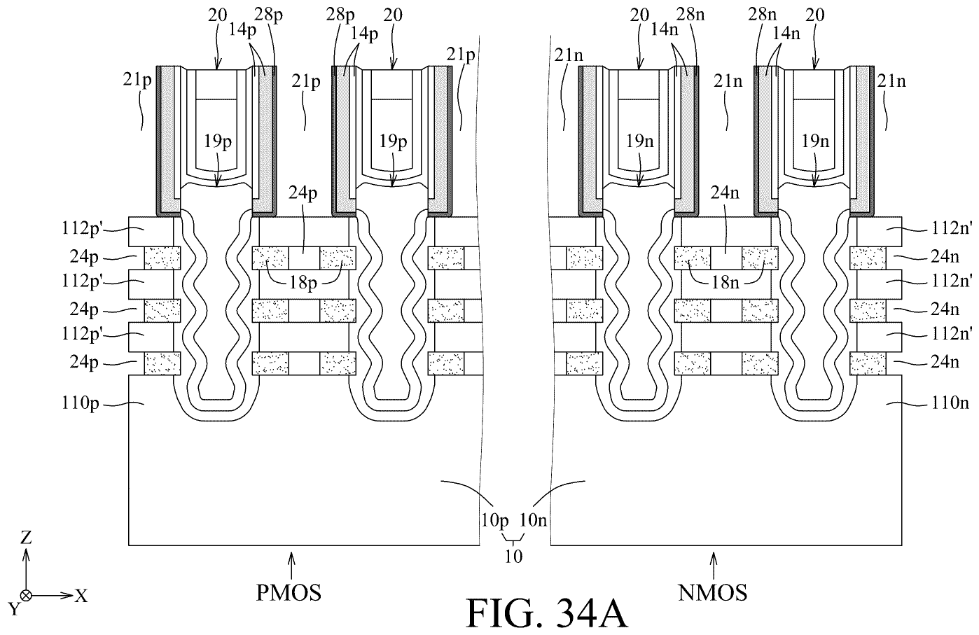

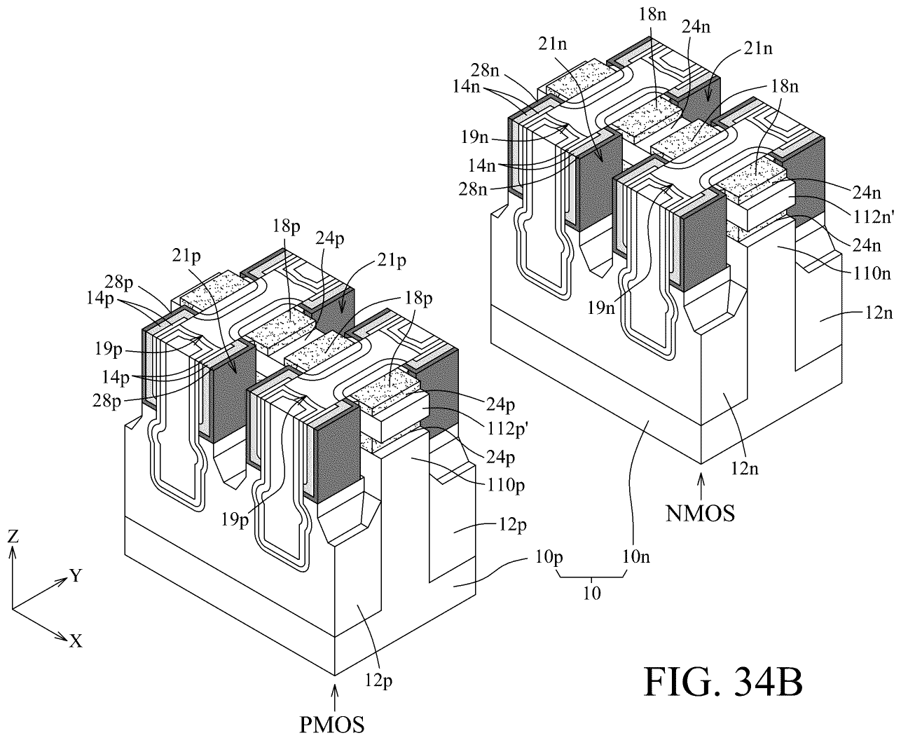

FIGS. 34A to 42 illustrate schematic views of intermediate stages of the method 3 in accordance with some embodiments. FIG. 39A is a schematic sectional view illustrating the device structures 300p, 300n in accordance with some embodiments. FIG. 39B is a fragmentary perspective view illustrating portions of device structures 300p, 300n in the semiconductor structure 300 in accordance with some embodiments. The schematic sectional views of the device structures 300p, 300n shown in FIG. 39A are respectively taken along lines C1-C1′ and C2-C2′ of FIG. 39B, and further illustrate the components that are omitted in FIG. 39B. In other words, the fragmentary perspective view shown in FIG. 39B merely illustrates the components of device structures 300p, 300n positioned below dotted line C3-C3′ of FIG. 39A, but omitting the components of device structures 300p, 300n positioned above dotted line C3-C3′ of FIG. 39A.

FIGS. 34A, 35A, 36A, 37A, and 38A are each a schematic sectional view similar to that of FIG. 39A, and FIGS. 34B, 35B, 36B, 37B, and 38B are each a schematic perspective view similar to that of FIG. 39B, but illustrating formation of the device structures 300p, 300n at different intermediate stages of the method 3.

Referring to FIG. 33 and the examples illustrated in FIGS. 34A and 34B, the method 3 proceeds to step S308, where the recessed dielectric interposers 111d′ (see FIGS. 23A and 23B) are removed to form the inner gaps 24p, and the recessed sacrificial films 111n″ (see FIGS. 23A and 23B) are removed to form the inner gaps 24n. FIGS. 34A and 34B are schematic views respectively similar to those of FIGS. 23A and 23B, but illustrating the structures after step S308.

The recessed dielectric interposers 111d′ and the recessed sacrificial films 111n″ are each removed by a selective etching process with the use of etchant(s) having a relatively high etching selectivity to the recessed dielectric interposers 111d′ (or the recessed sacrificial films 111n″), and thus other elements are substantially intact.

In some embodiments, the removal of the recessed dielectric interposers 111d′ may be performed before or after the removal of the recessed sacrificial films 111n″. To be specific, during the removal of the recessed dielectric interposers 111d′, the structure at the NMOS region will be protected by a protection layer (not shown). During the removal of the sacrificial films 111n″, the structure at the PMOS region will be protected by another protection layer (not shown).

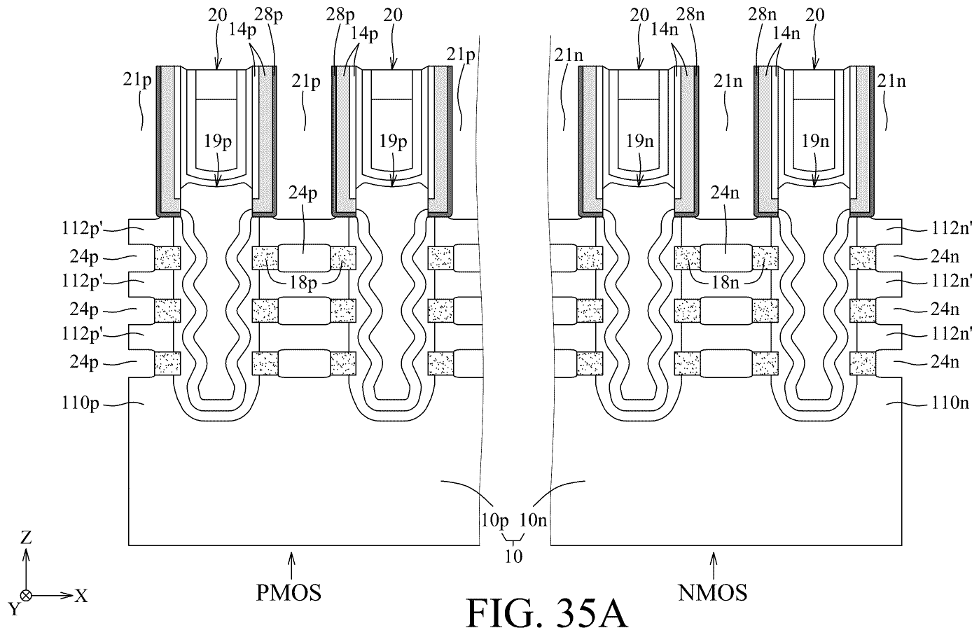

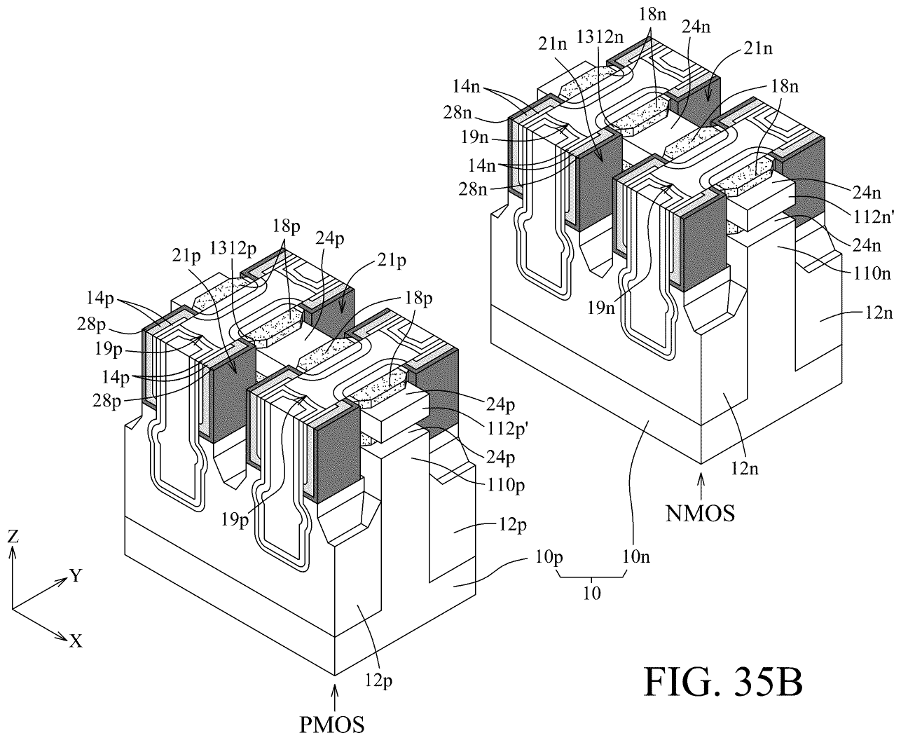

In some embodiments, after the removal of the recessed dielectric interposers 111d′ and the recessed sacrificial films 111n″, each pair of the semiconductor spacers 18p, 18n may be etched back to enlarge a dimension of a respective one of the inner gaps 24p, 24n in the X direction, as shown in FIGS. 35A and 35B.

It is noted that the pairs of semiconductor spacers 18p, 18n in method 2 are respectively replaced with the pairs of dielectric spacers 23p, 23n (see FIGS. 23A and 23B and FIGS. 26A and 26B), but such replacement is not performed in the method 3. Therefore, in some embodiments not shown herein, in method 3, each pair of the grooves 17p, 17n (see FIGS. 19A and 19B) formed in step S304 (which is similar to step S104 or S204) and the corresponding pair of the semiconductor spacers 18p, 18n may not extend over the two edges (E, see FIG. 21B) of the respective one of the dummy gates 132p, 132n, respectively. In such case, when the inner gaps 24p, 24n thus obtained after the removal of the recessed dielectric interposers 111d′ and the recessed sacrificial films 111n″ are large enough, the etching back of each pair of the semiconductor spacers 18p, 18n may be omitted.

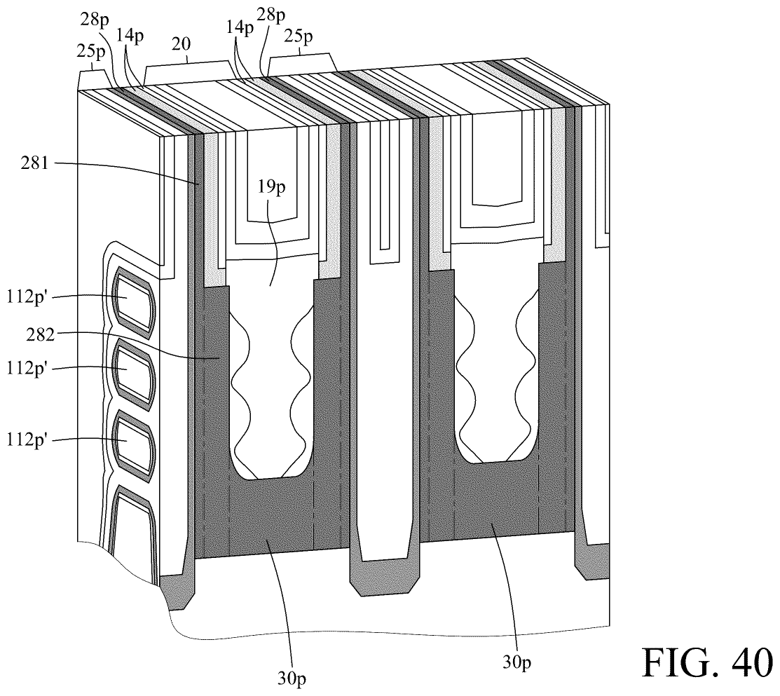

Referring to FIG. 33 and the examples illustrated in FIGS. 36A, 36B and 40, the method 3 proceeds to step S309, where the gate structures 25p are formed in the cavities 21p and the inner gaps 24p (see FIGS. 35A and 35B), and the gate structures 25n are formed in the cavities 21n and the inner gaps 24n (see FIGS. 35A and 35B). FIGS. 36A and 36B are schematic views respectively similar to those of FIGS. 35A and 35B, but illustrating the structures after step S309. FIG. 40 is a fragmentary perspective view illustrating portions of the structure obtained in steps S309, and also illustrates a sectional view taken along line D-D′ of FIG. 36B in accordance with some embodiments. The fragmentary perspective view of FIG. 40 further illustrates the structure that is omitted in FIG. 36B (i.e., the structure above line D-D′ of FIG. 36B). Step S309 is similar to step S211 of the method 2, except that the end parts 1312p, 1312n are still present after formation of the gate structures 25p, 25n.

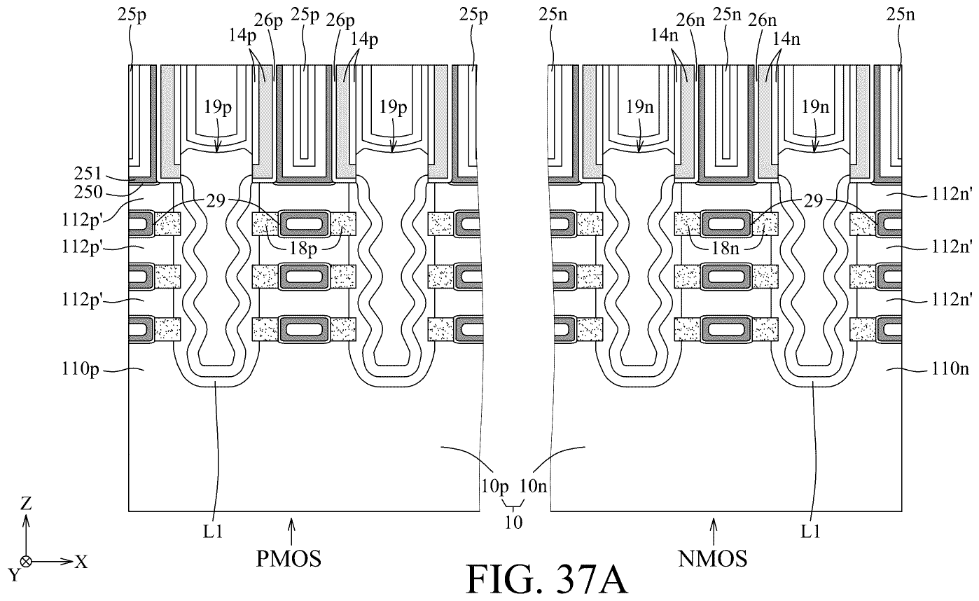

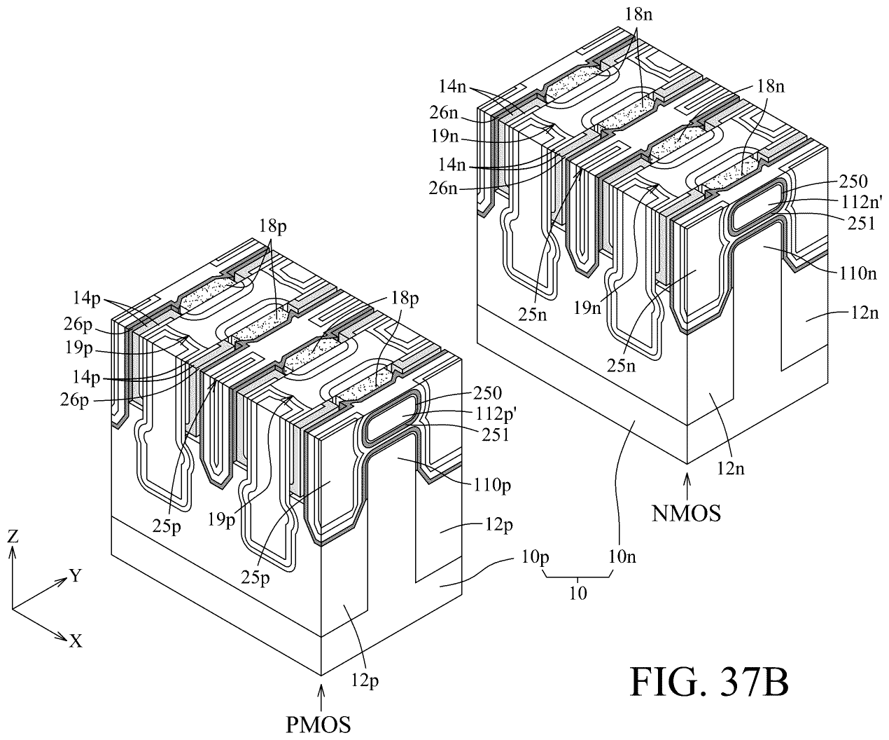

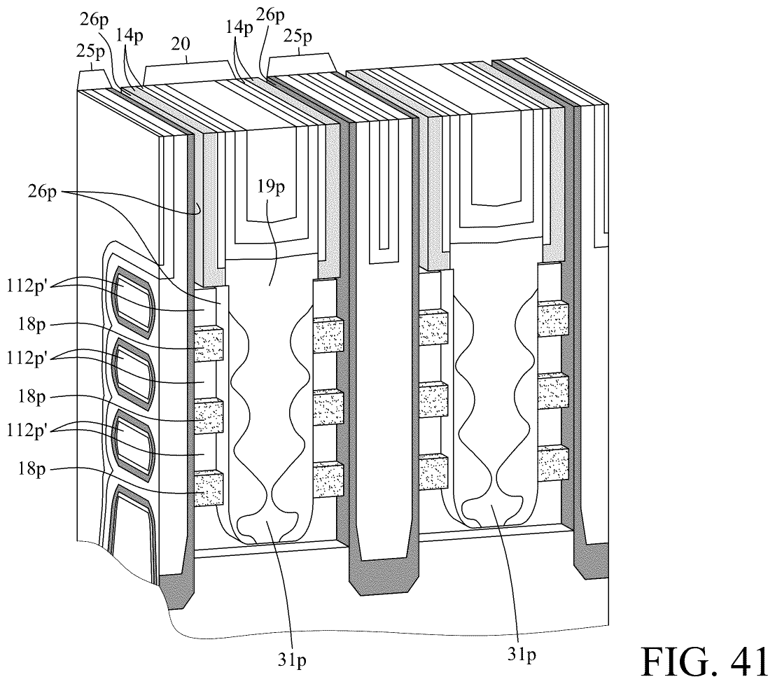

Referring to FIG. 33 and the examples illustrated in FIGS. 37A, 37B and 41, the method 3 proceeds to step S310, where the pairs of first intermediate layers 28p, 28n (see FIGS. 36A and 36B) are removed to respectively form the pairs of first clearances 26p, 26n, and the pairs of second intermediate layers 30p, 30n (only the pairs of second intermediate layers 30p at the PMOS region are shown in FIG. 40) are removed to respectively form the pairs of second clearances (only the pairs of second clearances 31p at the PMOS region are shown in FIG. 41). FIGS. 37A, 37B and 41 are schematic views respectively similar to those of FIGS. 36A, 36B and 40, but illustrating the structures after step S310.

As shown in FIG. 41, each of the second clearances 31p is in spatial communication with two corresponding adjacent ones of the first clearances 26p.

In step S310, each of the end parts 1312p, 1312n disposed on the corresponding second region s2 (see FIGS. 35B and 36B) is also removed by an etching process so as to expose the pairs of semiconductor spacers 18p, 18n.

The pairs of first intermediate layers 28p, 28n, the pairs of second intermediate layers 30p, 30n and the remaining part of the end parts 1312p, 1312n are removed by a selective etching process with the use of etchant(s) having a relatively high etching selectivity to the first intermediate layers 28p, 28n, the second intermediate layers 30p, 30n and the end parts 1312p, 1312n, and thus other elements are substantially intact.

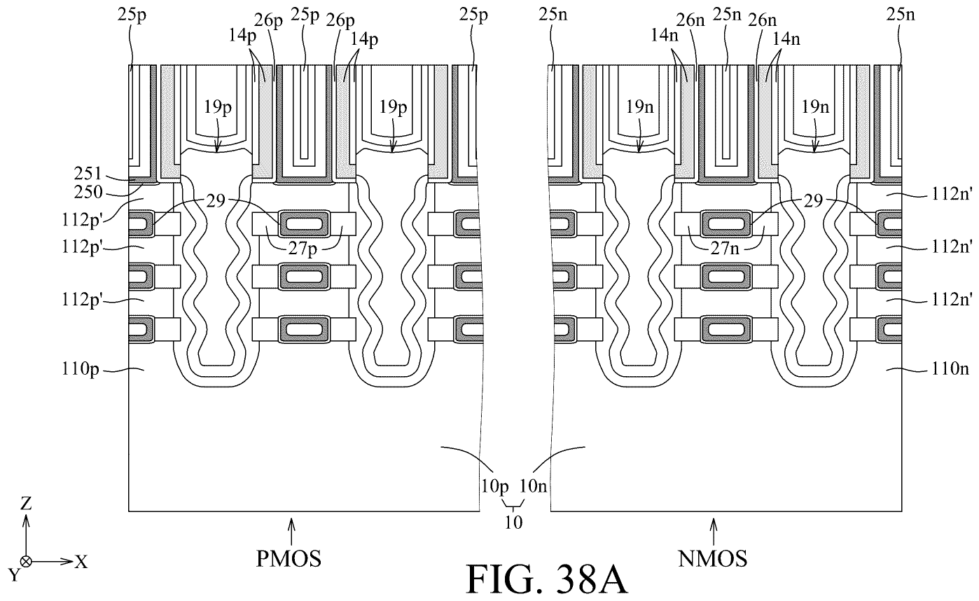

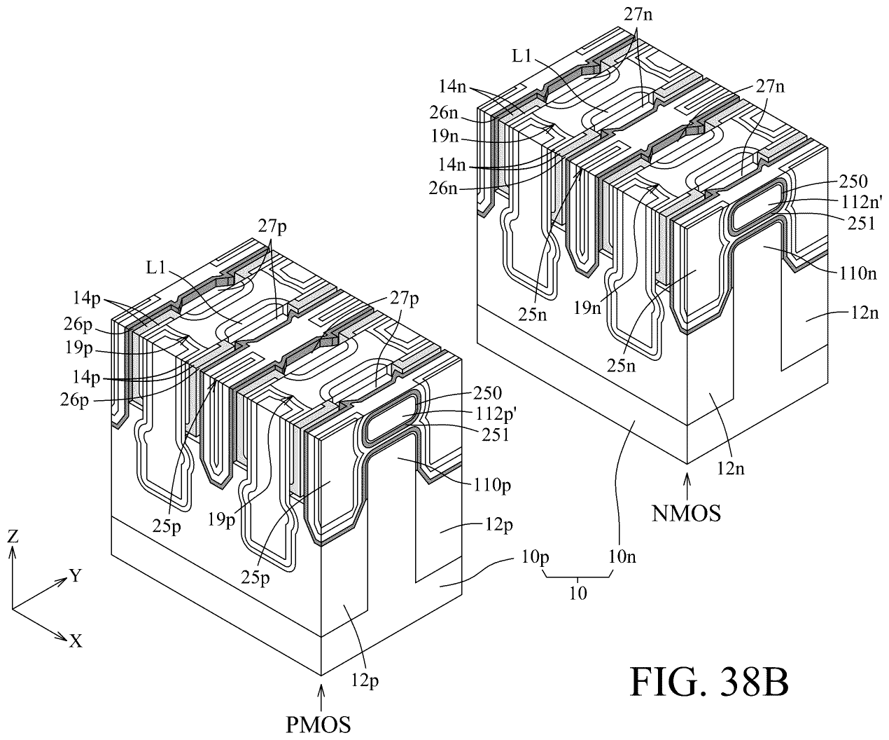

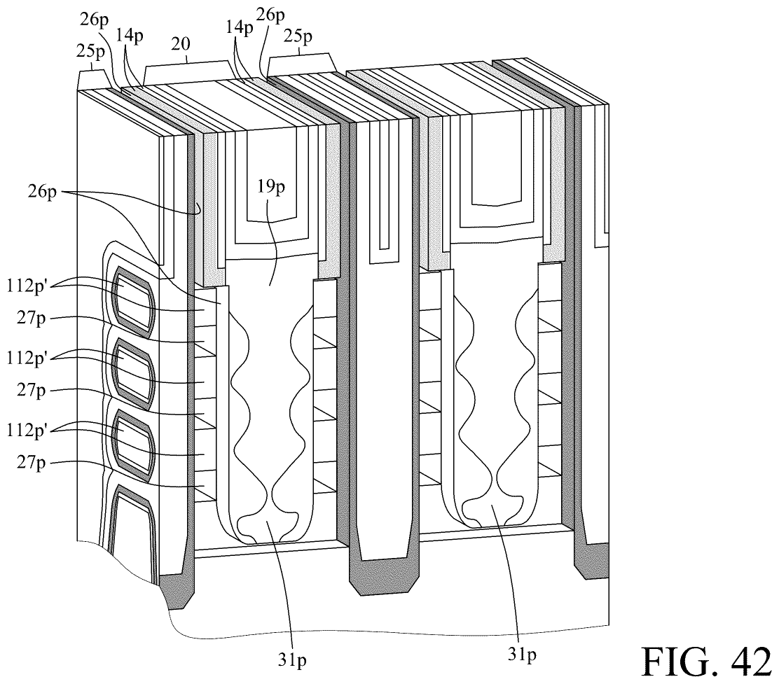

Referring to FIG. 33 and the examples illustrated in FIGS. 38A, 38B and 42, the method 3 proceeds to step S311, where the pairs of semiconductor spacers 18p, 18n (see FIGS. 37A and 37B) are removed to respectively form the pairs of air spacers 27p, 27n. FIGS. 38A, 38B and 42 are schematic views respectively similar to those of FIGS. 37A, 37B and 41, but illustrating the structures after step S311.

The pairs of semiconductor spacers 18p, 18n are removed by a selective etching process with the use of etchant(s) having a relatively high etching selectivity to the semiconductor spacers 18p, 18n, and thus the gate spacers 14p, 14n, the gate structures 25p, 25n, the channel films 112n′, 112p′, and the source/drain portions 19p, 19n are substantially intact. In this step, in the same stack of the channel films 112p′ or 112n′, the first left inner spacers (i.e., the left ones of the semiconductor spacers 18p or 18n) formed in step S305 (similar to steps S205 and S105) are removed through the left clearance, and the first right inner spacers (the right ones of the semiconductor spacers 18p or 18n) are removed through the right clearance.

Referring to FIG. 33 and the examples illustrated in FIGS. 39A and 39B, the method 3 proceeds to step S312, where the treatment is performed to seal the end of each of the first clearances 26p or 26n. FIGS. 39A and 39B are schematic views respectively similar to those of FIGS. 38A and 38B, but illustrating the structures after step S312. Step S312 is similar to step S213 of the method 2, and thus the same details thereof are not repeated for the sake of brevity.

In some embodiments, some steps in each of the methods 1, 2, 3 may be modified, replaced, or eliminated without departure from the spirit and scope of the present disclosure. In some alternative embodiments, each of the semiconductor structures 100, 200, 300 may further include additional features, and/or some features present in each of the semiconductor structures 100, 200, 300 may be modified, replaced, or eliminated without departure from the spirit and scope of the present disclosure.

In summary, each of the source/drain portions 19p, 19n in each of the semiconductor structures 100, 200, 300 is epitaxially formed along the continuous semiconductor surface, and thus has the perfect crystal structure. Due to the perfect crystal structure, a compressive stress applied by the source/drain portions 19p on the channel films 112p′ may be greater, which may be detected by nano-beam diffraction. Furthermore, an active (or effective) doping concentration of each of the source/drain portions 19p, 19n may be also greater. In addition, the position of the pairs of dielectric spacers 23p, 23n (or the pair of air spacers 27p, 27n) are respectively self-aligned with the position of the pairs of semiconductor spacers 18p, 18n. Therefore, the dimension of the pairs of the dielectric spacers 23p, 23n (or the air spacers 27p, 27n) can be easily controlled by the dimension of the pairs of the semiconductor spacers 18, 18p. In the case that the air spacers 27p, 27n and the first clearances 26p, 26n are formed, a parasitic capacitance generated in the semiconductor structure 100, 200 or 300 may be minimized.

In accordance with some embodiments of the present disclosure, a method for manufacturing a semiconductor structure includes: forming a patterned structure which includes a stacking portion that is disposed on a base structure and that includes a first layer disposed on the base structure and a second layer disposed on the first layer opposite to the base structure, the first layer including an inner part and two outer parts respectively located at two opposite sides of the inner part, the two outer parts being made of a first semiconductor material, the second layer being made of a second semiconductor material that is different from the first semiconductor material, the inner part being made of a material that is different from the first semiconductor material and the second semiconductor material, and a dummy structure disposed on the stacking portion; and epitaxially forming two source/drain portions respectively at two opposite sides of the stacking portion so that each of the two source/drain portions is connected to the second layer and a respective one of the two outer parts.

In accordance with some embodiments of the present disclosure, the two source/drain portions are opposite to each other in a first direction, the two outer parts are respectively located at the two opposite sides of the inner part in the first direction, the dummy structure is formed over the stacking portion and elongated in a second direction transverse the first direction to cover two lateral surfaces of the stacking portion which are opposite to each other in the second direction, and the dummy structure includes a dummy gate and two gate spacers respectively disposed at two opposite sides of the dummy gate in the first direction.

In accordance with some embodiments of the present disclosure, each of the two outer parts has two side surfaces which are opposite to each other in the second direction and which are covered by the dummy gate.

In accordance with some embodiments of the present disclosure, after formation of the two source/drain portions, the method further includes: removing the dummy gate to form a cavity which exposes the two side surfaces of each of the two outer parts.

In accordance with some embodiments of the present disclosure, after formation of the cavity, the method further includes: removing the two outer parts to form two outer gaps, each of which is disposed between the inner part and a respective one of the two source/drain portions; forming two dielectric spacers respectively in the two outer gaps; removing the inner part to form an inner gap; and forming a gate structure to fill the cavity and the inner gap so that the gate structure is disposed around the second layer.

In accordance with some embodiments of the present disclosure, prior to forming the gate structure and after removing the inner part, the method further includes: performing a trimming process to enlarge a dimension of the inner gap in the first direction.

In accordance with some embodiments of the present disclosure, a concentration of germanium in the inner part is greater than a concentration of germanium in the first semiconductor material.

In accordance with some embodiments of the present disclosure, the inner part is made of a dielectric material.

In accordance with some embodiments of the present disclosure, a method for manufacturing a semiconductor structure, includes: forming a patterned structure which includes a stacking portion that is disposed on a base structure and that includes a first layer disposed on the base structure and a second layer disposed on the first layer opposite to the base structure, the first layer including an inner part and two outer parts respectively located at two opposite sides of the inner part, the two outer parts being made of a first semiconductor material, the second layer being made of a second semiconductor material that is different from the first semiconductor material, a concentration of germanium in the inner part being different from a concentration of germanium in the first semiconductor material, and a dummy structure disposed on the stacking portion; and epitaxially forming two source/drain portions respectively at two opposite sides of the stacking portion so that each of the two source/drain portions is connected to the second layer and a respective one of the two outer parts.

In accordance with some embodiments of the present disclosure, the two source/drain portions are opposite to each other in a first direction, the two outer parts are respectively located at the two opposite sides of the inner part in the first direction, the dummy structure is formed over the stacking portion and elongated in a second direction transverse the first direction to cover two lateral surfaces of the stacking portion which are opposite to each other in the second direction, and the dummy structure includes a dummy gate, two intermediate layers respectively disposed at two opposite sides of the dummy gate in the first direction, and two gate spacers respectively disposed on the two intermediate layers opposite to the dummy gate.

In accordance with some embodiments of the present disclosure, each of the two intermediate layers has a main portion disposed between the dummy gate and a respective one of the two gate spacers, and an extending portion disposed between the stacking portion and the respective one of the two gate spacers.

In accordance with some embodiments of the present disclosure, each of the two outer parts has two side surfaces which are opposite to each other in the second direction and which are covered by the dummy gate and a respective one of the two intermediate layers.

In accordance with some embodiments of the present disclosure, after formation of the two source/drain portions, the method further includes: removing the dummy gate to form a cavity which exposes the inner part and the two side surfaces of each of the two outer parts; removing the two outer parts to form two outer gaps, each of which is disposed between the inner part and a respective one of the two source/drain portions; forming two dielectric spacers respectively in the two outer gaps; removing the inner part to form an inner gap; forming a gate structure to fill the cavity and the inner gap so that the gate structure is disposed around the second layer; removing the two intermediate layers to form two clearances; and removing the two dielectric spacers respectively through the two clearances to form two air spacers, respectively.

In accordance with some embodiments of the present disclosure, after formation of the two source/drain portions, the method further includes: removing the dummy gate to form a cavity which exposes the inner part; removing the inner part to form an inner gap; forming a gate structure to fill the cavity and the inner gap so that the gate structure is disposed around the second layer; removing the two intermediate layers to form two clearances; and removing the two outer parts respectively through the two clearances to form two air spacers, respectively.

In accordance with some embodiments of the present disclosure, prior to forming the gate structure and after removing the inner part, the method further includes: performing a trimming process to enlarge a dimension of the inner gap in the first direction.

In accordance with some embodiments of the present disclosure, the method further includes: performing a treatment to seal an end of each of the two clearances.

In accordance with some embodiments of the present disclosure, the treatment is performed by implanting upper portions of the two gate spacers.

In accordance with some embodiments of the present disclosure, a semiconductor structure includes: a channel film having a middle region and two end regions respectively located at two opposite sides of the middle region; a gate structure disposed around the middle region of the channel film; two source/drain portions respectively in contact with the two end regions of the channel film, each of the two source/drain portions having a perfect crystal structure; and two inner spacers, each of which is disposed to separate the gate structure from a respective one of the two source/drain portions.

In accordance with some embodiments of the present disclosure, each of the two inner spacers is an air gap.

In accordance with some embodiments of the present disclosure, the gate structure includes a gate electrode, and two gate spacers respectively disposed at two opposite sides of the gate electrode so that two clearances are each formed between the gate electrode and a respective one of the gate spacers, each of the clearances being in spatial communication with the air gap of a respective one of the two inner spacers.

In accordance with some embodiments of the present disclosure, a method for manufacturing a semiconductor structure includes: forming a left clearance and a right clearance, each of which is located between a gate structure and a respective one of two gate spacers, the two gate spacers being located at a left side and a right side of the gate structure, respectively; and removing left inner spacers through the left clearance to form left air gaps, and removing right inner spacers through the right clearance to form right air gaps, each of the left inner spacers being located beneath a left end region of a respective one of channel films, each of the right inner spacers being located beneath a right end region of the respective one of the channel films.

In accordance with some embodiments of the present disclosure, the left inner spacers and the right inner spacers are each made of a dielectric material.

In accordance with some embodiments of the present disclosure, the left inner spacers and the right inner spacers are each made of a semiconductor material.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
forming a patterned structure which includes
a stacking portion disposed on a base structure and including a first layer disposed on the base structure and a second layer disposed on the first layer opposite to the base structure, the first layer including an inner part and two outer parts respectively located at two opposite sides of the inner part, the two outer parts being made of a first semiconductor material, the second layer being made of a second semiconductor material that is different from the first semiconductor material, the inner part being made of a material that is different from the first semiconductor material and the second semiconductor material, and
a dummy structure disposed on the stacking portion; and
epitaxially forming two source/drain portions respectively at two opposite sides of the stacking portion so that each of the two source/drain portions is connected to the second layer and a respective one of the two outer parts.

2. The method as claimed in claim 1, wherein
the two source/drain portions are opposite to each other in a first direction,
the two outer parts are respectively located at the two opposite sides of the inner part in the first direction,
the dummy structure is formed over the stacking portion and elongated in a second direction transverse the first direction to cover two lateral surfaces of the stacking portion which are opposite to each other in the second direction, and
the dummy structure includes a dummy gate and two gate spacers respectively disposed at two opposite sides of the dummy gate in the first direction.

3. The method as claimed in claim 2, wherein each of the two outer parts has two side surfaces which are opposite to each other in the second direction and which are covered by the dummy gate.

4. The method as claimed in claim 3, after formation of the two source/drain portions, further comprising:
removing the dummy gate to form a cavity which exposes the two side surfaces of each of the two outer parts.

5. The method as claimed in claim 4, after formation of the cavity, further comprising:
removing the two outer parts to form two outer gaps, each of which is disposed between the inner part and a respective one of the two source/drain portions;
forming two dielectric spacers respectively in the two outer gaps;
removing the inner part to form an inner gap; and
forming a gate structure to fill the cavity and the inner gap so that the gate structure is disposed around the second layer.

6. The method as claimed in claim 5, further comprising:
prior to forming the gate structure and after removing the inner part, performing a trimming process to enlarge a dimension of the inner gap in the first direction.

7. The method as claimed in claim 1, wherein a concentration of germanium in the inner part is greater than a concentration of germanium in the first semiconductor material.

8. The method as claimed in claim 1, wherein the inner part is made of a dielectric material.

9. A method for manufacturing a semiconductor structure, comprising:
forming a patterned structure which includes
a stacking portion disposed on a base structure and including a first layer disposed on the base structure and a second layer disposed on the first layer opposite to the base structure, the first layer including an inner part and two outer parts respectively located at two opposite sides of the inner part, the two outer parts being made of a first semiconductor material, the second layer being made of a second semiconductor material that is different from the first semiconductor material, a concentration of germanium in the inner part being different from a concentration of germanium in the first semiconductor material, and
a dummy structure disposed on the stacking portion; and
epitaxially forming two source/drain portions respectively at two opposite sides of the stacking portion so that each of the two source/drain portions is connected to the second layer and a respective one of the two outer parts.

10. The method as claimed in claim 9, wherein
the two source/drain portions are opposite to each other in a first direction,
the two outer parts are respectively located at the two opposite sides of the inner part in the first direction,
the dummy structure is formed over the stacking portion and elongated in a second direction transverse the first direction to cover two lateral surfaces of the stacking portion which are opposite to each other in the second direction, and
the dummy structure includes
a dummy gate,
two intermediate layers respectively disposed at two opposite sides of the dummy gate in the first direction, and
two gate spacers respectively disposed on the two intermediate layers opposite to the dummy gate.

11. The method as claimed in claim 10, wherein each of the two intermediate layers has a main portion disposed between the dummy gate and a respective one of the two gate spacers, and an extending portion disposed between the stacking portion and the respective one of the two gate spacers.

12. The method as claimed in claim 11, wherein each of the two outer parts has two side surfaces which are opposite to each other in the second direction and which are covered by the dummy gate and a respective one of the two intermediate layers.

13. The method as claimed in claim 11, after formation of the two source/drain portions, further comprising:
removing the dummy gate to form a cavity which exposes the inner part and the two side surfaces of each of the two outer parts;
removing the two outer parts to form two outer gaps, each of which is disposed between the inner part and a respective one of the two source/drain portions;
forming two dielectric spacers respectively in the two outer gaps;
removing the inner part to form an inner gap;
forming a gate structure to fill the cavity and the inner gap so that the gate structure is disposed around the second layer;
removing the two intermediate layers to form two clearances; and
removing the two dielectric spacers respectively through the two clearances to form two air spacers, respectively.

14. The method as claimed in claim 11, after formation of the two source/drain portions, further comprising:
removing the dummy gate to form a cavity which exposes the inner part;
removing the inner part to form an inner gap;
forming a gate structure to fill the cavity and the inner gap so that the gate structure is disposed around the second layer;
removing the two intermediate layers to form two clearances; and
removing the two outer parts respectively through the two clearances to form two air spacers, respectively.

15. The method as claimed in claim 14, further comprising:
prior to forming the gate structure and after removing the inner part, performing a trimming process to enlarge a dimension of the inner gap in the first direction.

16. The method as claimed in claim 15, further comprising:
performing a treatment to seal an end of each of the two clearances.

17. The method as claimed in claim 16, wherein the treatment is performed by implanting upper portions of the two gate spacers.

18. A semiconductor structure, comprising:
a channel film having a middle region and two end regions respectively located at two opposite sides of the middle region;
a gate structure disposed around the middle region of the channel film;
two source/drain portions respectively in contact with the two end regions of the channel film, each of the two source/drain portions including a first sub-layer and a second sub-layer formed on the first sub-layer; and
two inner spacers, each of which is disposed to separate the gate structure from a respective one of the two source/drain portions, the first sub-layer of each of the two source/drain portions being configured as a continuous layer and in contact with a respective one of the two end regions of the the channel film and a respective one of the two inner spacers.

19. The semiconductor structure as claimed in claim 18, wherein each of the two inner spacers is an air gap.

20. The semiconductor structure as claimed in claim 19, wherein the gate structure includes
a gate electrode, and
two gate spacers respectively disposed at two opposite sides of the gate electrode so that two clearances are each formed between the gate electrode and a respective one of the gate spacers, each of the clearances being in spatial communication with the air gap of a respective one of the two inner spacers.
